(19) United States
(12) Patent Application Publication
(10) Pub. No.: US 2026/0343857 A1
(43) Pub. Date: Oct. 29, 2026

(54) MEMORY DEVICE

(71) Applicant: SEMICONDUCTOR ENERGY LABORATORY CO., LTD., Atsugi-shi, Kanagawa-ken (JP)

(72) Inventors: Hidekazu MIYAIRI, Hadano, Kanagawa (JP); Mitsuhiro MATSUKI, Atsugi, Kanagawa (JP)

(21) Appl. No.: 19/110,156

(22) PCT Filed: Sep. 11, 2023
(86) PCT No.: PCT/IB2023/058969

§ 371 Date: Mar. 10, 2025

(30) Foreign Application Priority Data
Sep. 16, 2022 (JP) 2022-147877

(51) Int. Cl. H10B 12/00; H10B 53/10; H10B 53/20; H10B 53/30; H10B 53/40; H10D 1/68; H10D 30/67; H10W 20/41

(52) U.S. Cl. CPC H10B 12/33; H10D 1/68; H10D 1/716; H10D 30/6728; H10D 30/6731; H10D 30/6755; H10B 12/036; H10B 12/05; H10B 12/50; H10B 53/10; H10B 53/20; H10B 53/30; H10B 53/40; H10D 1/696; H10D 30/6736; H10D 30/6757; H10W 20/435

(57) ABSTRACT

A memory device that can be miniaturized or highly integrated can be provided. The memory device includes a plurality of memory cells, a first insulator, and a second insulator over the first insulator. The memory cell includes a capacitor and a transistor over the capacitor. At least part of the capacitor is placed in a first opening portion provided in the first insulator. At least part of the transistor is placed in a second opening portion provided in the second insulator. The first opening portion includes a region overlapping with the second opening portion. The diameter of the first opening portion is larger than the diameter of the second opening portion. In an adjacent memory cell, an interval at which the capacitors are placed is equal to an interval at which the transistors are placed.

### TECHNICAL FIELD

One embodiment of the present invention relates to a transistor, a semiconductor device, a memory device, and an electronic device. Another embodiment of the present invention relates to a method for manufacturing a memory device or a semiconductor device. Another embodiment of the present invention relates to a semiconductor wafer and a module.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, semiconductor devices have been developed, and LSIs (Large Scale Integrations), CPUs (Central Processing Units), memories, and the like are mainly used as the semiconductor devices. A CPU is an aggregation of semiconductor elements; the CPU includes a semiconductor integrated circuit (including at least a transistor and a capacitor) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique in which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor material applicable to a transistor and an oxide semiconductor has been attracting attention as another material.

It is known that a transistor including an oxide semiconductor has an extremely low leakage current in a non-conduction state. For example, Patent Document 1 discloses a low-power-consumption CPU utilizing a feature of a low leakage current of the transistor including an oxide semiconductor. Furthermore, for example, Patent Document 2 discloses a memory device that can retain stored contents for a long time by utilizing a feature of a low leakage current of the transistor including an oxide semiconductor.

In recent years, demand for an integrated circuit with higher density has risen with reductions in size and weight of electronic devices. Furthermore, the productivity of a semiconductor device including an integrated circuit is desired to be improved. For example, Patent Document 3 and Non-Patent Document 1 disclose a technique for achieving an integrated circuit with higher density by making a plurality of memory cells overlap with each other by stacking a first transistor including an oxide semiconductor film and a second transistor including an oxide semiconductor film.

Furthermore, by employing vertical transistors, an integrated circuit with higher density can be achieved. For example, Patent Document 4 discloses a vertical transistor in which a side surface of an oxide semiconductor is covered with a gate electrode with a gate insulator therebetween.

### REFERENCES

### Patent Documents

[Patent Document 1] Japanese Published Patent Application No. 2012-257187

[Patent Document 2] Japanese Published Patent Application No. 2011-151383

[Patent Document 3] PCT International Publication No. 2021/053473

[Patent Document 4] Japanese Published Patent Application No. 2013-211537

### Non-Patent Document

[Non-Patent Document 1] M. Oota, et al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a memory device that can be miniaturized or highly integrated. Another object is to provide a memory device with high operation speed. Another object is to provide a memory device with favorable electrical characteristics. Another object is to provide a memory device with a small variation in electrical characteristics of transistors. Another object is to provide a memory device with high reliability. Another object is to provide a memory device with a high on-state current. Another object is to provide a memory device with low power consumption. Another object is to provide a novel memory device. Another object is to provide a method for manufacturing a novel memory device.

Note that the description of these objects does not preclude the presence of other objects. One embodiment of the present invention does not necessarily achieve all these objects. Note that other objects will be apparent from and can be derived from the description of the specification, the drawings, the claims, and the like.

### Means for Solving the Problems

One embodiment of the present invention is a memory device including a first memory cell, a second memory cell, a first insulator, and a second insulator over the first insulator. The first memory cell includes a first capacitor and a first transistor over the first capacitor. The second memory cell includes a second capacitor and a second transistor over the second capacitor. An interval between the first capacitor and the second capacitor is equal to an interval between the first transistor and the second transistor. The first insulator includes a first opening portion and a second opening portion. At least part of the first capacitor is placed in the first opening portion. At least part of the second capacitor is placed in the second opening portion. The second insulator includes a third opening portion and a fourth opening portion. At least part of the first transistor is placed in the third opening portion. At least part of the second transistor is placed in the fourth opening portion. The first opening portion includes a region overlapping with the third opening portion. The second opening portion includes a region overlapping with the fourth opening portion. A maximum width of the first opening portion is different from a maximum width of the third opening portion. A maximum width of the second opening portion is different from a maximum width of the fourth opening portion.

In the above memory device, the maximum width of the first opening portion is preferably larger than the maximum width of the third opening portion. The maximum width of the second opening portion is preferably larger than the maximum width of the fourth opening portion.

In the above memory device, a channel length of the first transistor is preferably smaller than a channel width of the first transistor. A channel length of the second transistor is preferably smaller than a channel width of the second transistor.

In the above memory device, each of the first transistor and the second transistor preferably contains an oxide semiconductor in a semiconductor layer. The oxide semiconductor preferably contains one or more selected from In, Ga, and Zn.

In the above memory device, each of the first capacitor and the second capacitor preferably includes a first conductor, a third insulator over the first conductor, and a second conductor over the third insulator. The third insulator preferably includes a first zirconium oxide, an aluminum oxide over the first zirconium oxide, and a second zirconium oxide over the aluminum oxide.

In the above memory device, a plurality of layers each including the first memory cell and the second memory cell are preferably included. The plurality of layers are preferably stacked.

Another embodiment of the present invention is a memory device including a first conductor, a memory cell over the first conductor, a first insulator over the first conductor, and a second insulator. The memory cell includes a capacitor and a transistor over the capacitor. The capacitor includes a second conductor, a third insulator over the second conductor, and a third conductor over the third insulator. A first opening portion reaching the first conductor is provided in the first insulator. At least part of the second conductor, at least part of the third insulator, and at least part of the third conductor are placed in the first opening portion. The second insulator is placed over the second conductor, the third insulator, and the third conductor. The transistor includes the third conductor, a fourth conductor over the second insulator, an oxide semiconductor, a fourth insulator, and a fifth conductor. A second opening portion reaching the third conductor is provided in the second insulator and the fourth conductor. At least part of the oxide semiconductor is placed in the second opening portion. The oxide semiconductor includes a region in contact with a top surface of the third conductor in the second opening portion, a region in contact with a side surface of the fourth conductor in the second opening portion, and a region in contact with at least part of a top surface of the fourth conductor in the second opening portion. The fourth insulator is placed over the oxide semiconductor such that at least part of the fourth insulator is positioned in the second opening portion. The fifth conductor is placed over the fourth insulator such that at least part of the fifth conductor is positioned in the second opening portion. A maximum width of the first opening portion is different from a maximum width of the second opening portion.

In the above memory device, the maximum width of the first opening portion is preferably larger than the maximum width of the second opening portion.

In the above memory device, the second opening portion preferably includes a region overlapping with the first opening portion.

In the above memory device, a channel length of the transistor is preferably smaller than a channel width of the transistor.

In the above memory device, the third insulator preferably contains a material that can have ferroelectricity.

In the above memory device, the third insulator preferably includes a first zirconium oxide, an aluminum oxide over the first zirconium oxide, and a second zirconium oxide over the aluminum oxide.

In the above memory device, the oxide semiconductor preferably contains one or more selected from In, Ga, and Zn.

In the above memory device, the first insulator preferably includes a stack. The stack preferably includes a first layer and a second layer over the first layer. The first layer preferably contains silicon and nitrogen, and the second layer preferably contains silicon and oxygen.

In the above memory device, a fifth insulator is preferably provided between a side surface of the first insulator in the first opening portion and the second conductor. The fifth insulator preferably contains silicon and nitrogen.

In the above memory device, the fifth conductor is preferably provided to extend in a first direction. The fourth conductor is preferably provided to extend in a second direction. The first direction and the second direction are preferably orthogonal to each other.

In the above memory device, a plurality of layers each including the memory cell are preferably included. The plurality of layers are preferably stacked.

### Effect of the Invention

According to one embodiment of the present invention, a memory device that can be miniaturized or highly integrated can be provided. A memory device with high operation speed can be provided. A memory device with high reliability can be provided. A memory device with a small variation in electrical characteristics of transistors can be provided. A memory device with favorable electrical characteristics can be provided. A memory device with a high on-state current can be provided. A memory device with low power consumption can be provided. A novel memory device can be provided. A method for manufacturing a novel memory device can be provided.

Note that the description of these effects does not preclude the presence of other effects. Note that one embodiment of the present invention does not need to have all of these effects. Other effects will be apparent from and can be derived from the description of the specification, the drawings, the claims, and the like.

### BRIEF DESCRIPTION OF THE DRAWINGS

FIG. 1A is a plan view illustrating an example of a memory device. FIG. 1B and FIG. 1C are cross-sectional views illustrating the example of the memory device. FIG. 1D is a circuit diagram illustrating a structure example of the memory device.

FIG. 2A is a plan view illustrating an example of a memory device. FIG. 2B and FIG. 2C are cross-sectional views illustrating the example of the memory device.

FIG. 3A is a plan view illustrating an example of a memory device. FIG. 3B and FIG. 3C are cross-sectional views illustrating the example of the memory device.

FIG. 4A and FIG. 4B are plan views illustrating an example of a memory device.

FIG. 5A is a plan view illustrating an example of a memory device. FIG. 5B and FIG. 5C are cross-sectional views illustrating the example of the memory device.

FIG. 6A to FIG. 6D are cross-sectional views illustrating examples of a memory device.

FIG. 7A is a plan view illustrating an example of a memory device. FIG. 7B and FIG. 7C are cross-sectional views illustrating the example of the memory device.

FIG. 8A is a plan view illustrating an example of a memory device. FIG. 8B and FIG. 8C are cross-sectional views illustrating the example of the memory device.

FIG. 9A is a plan view illustrating an example of a memory device. FIG. 9B and FIG. 9C are cross-sectional views illustrating the example of the memory device.

FIG. 10A is a plan view illustrating an example of a memory device. FIG. 10B and FIG. 10C are cross-sectional views illustrating the example of the memory device.

FIG. 11A is a plan view illustrating an example of a memory device. FIG. 11B and FIG. 11C are cross-sectional views illustrating the example of the memory device.

FIG. 12A to FIG. 12D are cross-sectional views illustrating examples of memory devices.

FIG. 13A is a cross-sectional view illustrating an example of a memory device. FIG. 13B is a cross-sectional view illustrating the example of the memory device.

FIG. 14A to FIG. 14D are cross-sectional views illustrating examples of a memory device.

FIG. 15A is a plan view illustrating an example of a memory device. FIG. 15B and FIG. 15C are cross-sectional views illustrating the example of the memory device.

FIG. 16A and FIG. 16B are cross-sectional views illustrating an example of a memory device.

FIG. 17A to FIG. 17D are cross-sectional views illustrating examples of a memory device.

FIG. 18A and FIG. 18B are cross-sectional views illustrating an example of a memory device.

FIG. 19A is a plan view illustrating an example of a memory device. FIG. 19B and FIG. 19C are cross-sectional views illustrating the example of the memory device.

FIG. 20A is a plan view illustrating an example of a memory device. FIG. 20B and FIG. 20C are cross-sectional views illustrating the example of the memory device.

FIG. 21A is a plan view illustrating an example of a memory device. FIG. 21B and FIG. 21C are cross-sectional views illustrating the example of the memory device.

FIG. 22A is a plan view illustrating an example of a method for manufacturing a memory device. FIG. 22B and FIG. 22C are cross-sectional views illustrating the example of the method for manufacturing the memory device.

FIG. 23A is a plan view illustrating an example of a method for manufacturing a memory device. FIG. 23B and FIG. 23C are cross-sectional views illustrating the example of the method for manufacturing the memory device.

FIG. 24A is a plan view illustrating an example of a method for manufacturing a memory device. FIG. 24B and FIG. 24C are cross-sectional views illustrating the example of the method for manufacturing the memory device.

FIG. 25A is a plan view illustrating an example of a method for manufacturing a memory device. FIG. 25B and FIG. 25C are cross-sectional views illustrating the example of the method for manufacturing the memory device.

FIG. 26A is a plan view illustrating an example of a method for manufacturing a memory device. FIG. 26B and FIG. 26C are cross-sectional views illustrating the example of the method for manufacturing the memory device.

FIG. 27A is a plan view illustrating an example of a method for manufacturing a memory device. FIG. 27B and FIG. 27C are cross-sectional views illustrating the example of the method for manufacturing the memory device.

FIG. 28A is a plan view illustrating an example of a method for manufacturing a memory device. FIG. 28B and FIG. 28C are cross-sectional views illustrating the example of the method for manufacturing the memory device.

FIG. 29A is a plan view illustrating an example of a method for manufacturing a memory device. FIG. 29B and FIG. 29C are cross-sectional views illustrating the example of the method for manufacturing the memory device.

FIG. 30A is a plan view illustrating an example of a method for manufacturing a memory device. FIG. 30B and FIG. 30C are cross-sectional views illustrating the example of the method for manufacturing the memory device.

FIG. 31A is a plan view illustrating an example of a method for manufacturing a memory device. FIG. 31B and FIG. 31C are cross-sectional views illustrating the example of the method for manufacturing the memory device.

FIG. 32A is a plan view illustrating an example of a method for manufacturing a memory device. FIG. 32B and FIG. 32C are cross-sectional views illustrating the example of the method for manufacturing the memory device.

FIG. 33A is a plan view illustrating an example of a method for manufacturing a memory device. FIG. 33B and FIG. 33C are cross-sectional views illustrating the example of the method for manufacturing the memory device.

FIG. 34A is a plan view illustrating an example of a method for manufacturing a memory device. FIG. 34B and FIG. 34C are cross-sectional views illustrating the example of the method for manufacturing the memory device.

FIG. 35A is a plan view illustrating an example of a method for manufacturing a memory device. FIG. 35B and FIG. 35C are cross-sectional views illustrating the example of the method for manufacturing the memory device.

FIG. 36A is a plan view illustrating an example of a method for manufacturing a memory device. FIG. 36B and FIG. 36C are cross-sectional views illustrating the example of the method for manufacturing the memory device.

FIG. 37A is a plan view illustrating an example of a method for manufacturing a memory device. FIG. 37B and FIG. 37C are cross-sectional views illustrating the example of the method for manufacturing the memory device.

FIG. 38A is a plan view illustrating an example of a method for manufacturing a memory device. FIG. 38B and FIG. 38C are cross-sectional views illustrating the example of the method for manufacturing the memory device.

FIG. 39A is a plan view illustrating an example of a memory device. FIG. 39B is a cross-sectional view illustrating the example of the memory device.

FIG. 40A is a plan view illustrating an example of a memory device. FIG. 40B is a cross-sectional view illustrating the example of the memory device.

FIG. 41A is a plan view illustrating an example of a memory device. FIG. 41B is a cross-sectional view illustrating the example of the memory device.

FIG. 42A to FIG. 42C are planar layouts illustrating examples of a memory device.

FIG. 43A to FIG. 43C are planar layouts illustrating examples of a memory device.

FIG. 44 is a cross-sectional view illustrating an example of a memory device.

FIG. 45 is a block diagram illustrating an example of a memory device.

FIG. 46A and FIG. 46B are schematic views illustrating an example of a memory device.

FIG. 47A to FIG. 47D are circuit diagrams illustrating an example of a memory device.

FIG. 48 is a circuit diagram illustrating an example of a memory device.

FIG. 49A and FIG. 49B are diagrams illustrating examples of electronic components.

FIG. 50A and FIG. 50B are diagrams illustrating examples of electronic devices. FIG. 50C to FIG. 50E are diagrams illustrating an example of a large computer.

FIG. 51 is a diagram illustrating an example of space equipment.

FIG. 52 is a diagram illustrating an example of a storage system that can be used in a data center.

### MODE FOR CARRYING OUT THE INVENTION

Embodiments are described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for the sake of clarity in some cases. Thus, the size, the layer thickness, or the region is not limited to the illustrated scale. Note that the drawings schematically show ideal examples, and embodiments of the present invention are not limited to shapes or values shown in the drawings. For example, in the actual manufacturing process, a layer, a resist mask, or the like might be unintentionally reduced in size by treatment such as etching, which is not be reflected in the drawings for easy understanding in some cases. Furthermore, in the drawings, the same reference numerals are used in common for the same portions or portions having similar functions in different drawings, and repeated description thereof is omitted in some cases. The same hatching pattern is used to show portions having similar functions, and the portions are not especially denoted by reference numerals in some cases.

Furthermore, especially in a plan view (also referred to as a “top view”), a perspective view, or the like, the description of some components is omitted for easy understanding of the invention in some cases. The description of some hidden lines is also omitted in some cases.

The ordinal numbers such as “first” and “second” in this specification and the like are used for convenience and do not denote the order of steps or the stacking order of layers. Thus, for example, the term “first” can be replaced with the term “second,” “third,” or the like as appropriate. In addition, the ordinal numbers in this specification and the like do not correspond to the ordinal numbers that are used to specify one embodiment of the present invention in some cases.

Moreover, in this specification and the like, terms for describing arrangement, such as “over” and “under”, are used for convenience for describing the positional relationship between components with reference to drawings. The positional relationship between components changes as appropriate in accordance with the direction in which the components are described. Thus, without limitation to terms described in this specification, the description can be changed appropriately depending on the situation.

In this specification and the like, for example, the expression “X and Y are connected” means the case where X and Y are electrically connected. Here, the expression “X and Y are electrically connected” means connection that enables electrical signal transmission between X and Y in the case where an object (that refers to an element such as a switch, a transistor element, or a diode, a circuit including the element and a wiring, or the like) is present between X and Y. Note that the case where X and Y are electrically connected includes the case where X and Y are directly connected. Here, the expression “X and Y are directly connected” means connection that enables electrical signal transmission between X and Y through a wiring (or an electrode) or the like, not through the above object. In other words, direct connection refers to connection that can be regarded as the same circuit diagram when represented by an equivalent circuit.

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, the channel formation region refers to a region through which a current mainly flows.

Furthermore, functions of a source and a drain are sometimes interchanged with each other when transistors having opposite polarity are used or when the direction of a current is changed in a circuit operation, for example. Thus, the terms “source” and “drain” can sometimes be interchanged with each other in this specification and the like.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, an oxygen vacancy (also referred to as V_{O}) is formed in an oxide semiconductor in some cases by entry of impurities, for example.

Note that in this specification and the like, an oxynitride is a material that contains more oxygen than nitrogen in its composition. Examples of oxynitride include silicon oxynitride, aluminum oxynitride, and hafnium oxynitride. Moreover, a nitride oxide is a material that contains more nitrogen than oxygen in its composition. Examples of nitride oxide include silicon nitride oxide, aluminum nitride oxide, and hafnium nitride oxide.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and with a change in the reference potential, a potential supplied to a wiring, a potential applied to a circuit or the like, and a potential or the like output from a circuit or the like change as well.

In this specification and the like, when a plurality of components are denoted with the same reference numeral, and in particular need to be distinguished from each other, an identification sign such as “_1”, “[n]”, or “[m,n]” is sometimes added to the reference numeral.

Note that in this specification and the like, the expression “the levels are the same” is used to describe a structure in which heights from a reference plane (e.g., a flat surface such as a substrate surface) are at the same level in a cross-sectional view. For example, in a manufacturing process of a memory device, planarization treatment (typically, chemical mechanical polishing (CMP) treatment) is performed, whereby the surface of a single layer or the surfaces of a plurality of layers is/are exposed in some cases. In this case, the surfaces on which the CMP treatment is performed are at the same level from a reference plane. Note that the plurality of layers are at different levels in some cases, depending on a treatment apparatus, a treatment method, or a material of the treated surfaces at the time when the CMP treatment is performed. This case is also described with the expression “the levels are the same” in this specification and the like. For example, the expression “the levels are the same” is also used to describe the case where two layers (here, a first layer and a second layer) having heights from a reference plane are provided to have a difference less than or equal to 20 nm between the top-surface level of the first layer and the top-surface level of the second layer.

Note that in this specification and the like, the expression “end portions are aligned” means that outlines of stacked layers at least partly overlap with each other in a plan view. For example, the case of processing an upper layer and a lower layer with the use of the same mask pattern or mask patterns that are partly the same is included. Note that in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned”.

In general, it is difficult to clearly differentiate “perfectly aligned” from “substantially aligned”. Thus, in this specification and the like, the expression “aligned” includes both “perfectly aligned” and “substantially aligned”.

Note that in this specification and the like, “normally-on characteristics” means a state where a channel is formed without application of a potential to a gate and a current flows through the transistor. Furthermore, “normally-off characteristics” mean a state where a current does not flow through a transistor when no potential or a ground potential is applied to a gate.

Furthermore, in this specification and the like, a leakage current sometimes expresses the same meaning as an off-state current. Furthermore, in this specification and the like, the off-state current sometimes refers to a current that flows between a source and a drain of a transistor in an off state, for example.

### EMBODIMENT 1

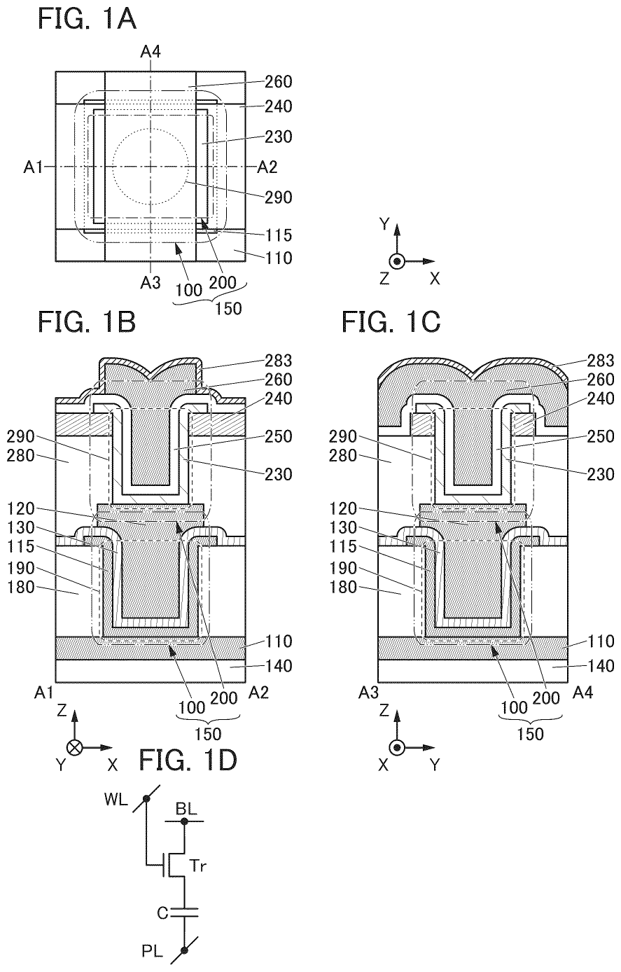

In this embodiment, examples of a memory device of one embodiment of the present invention and a manufacturing method thereof are described with reference to FIG. 1 to FIG. 44. The memory device of one embodiment of the present invention includes one or more memory cells. The memory cell includes a transistor and a capacitor.

### <Structure Example of Memory Device>

A structure of the memory device of one embodiment of the present invention is described with reference to FIG. 1. FIG. 1A to FIG. 1C are a plan view and cross-sectional views of a memory device including a memory cell 150. FIG. 1A is a plan view of the memory device. FIG. 1B and FIG. 1C are cross-sectional views of the memory device. Here, FIG. 1B is a cross-sectional view of a portion indicated by the dashed-dotted line A1-A2 in FIG. 1A. FIG. 1C is a cross-sectional view of a portion indicated by the dashed-dotted line A3-A4 in FIG. 1A. Note that for the sake of clarity of the drawing, some components are omitted in the plan view of FIG. 1A.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The memory device illustrated in FIG. 1A to FIG. 1C includes an insulator 140 over a substrate (not illustrated), a conductor 110 over the insulator 140, the memory cell 150 over the conductor 110, an insulator 180 over the conductor 110, an insulator 280 over the insulator 180, and an insulator 283 over the memory cell 150. The insulator 140, the insulator 180, the insulator 280, and the insulator 283 each function as an interlayer film. The conductor 110 functions as a wiring.

The memory cell 150 includes a capacitor 100 over the conductor 110 and a transistor 200 over the capacitor 100.

The capacitor 100 includes a conductor 115 over the conductor 110, an insulator 130 over the conductor 115, and a conductor 120 over the insulator 130. The conductor 120 functions as one of a pair of electrodes (sometimes referred to as an upper electrode), the conductor 115 functions as the other of the pair of electrodes (sometimes referred to as a lower electrode), and the insulator 130 functions as a dielectric. That is, the capacitor 100 forms a MIM (Metal-Insulator-Metal) capacitor.

As illustrated in FIG. 1B and FIG. 1C, an opening portion 190 reaching the conductor 110 is provided in the insulator 180. At least part of the capacitor 100 is placed in the opening portion 190. Specifically, at least part of the conductor 115, at least part of the insulator 130, and at least part of the conductor 120 are placed in the opening portion 190. Note that the conductor 115 includes a region in contact with the top surface of the conductor 110 in the opening portion 190, a region in contact with the side surface of the insulator 180 in the opening portion 190, and a region in contact with at least part of the top surface of the insulator 180. In addition, the conductor 120 is preferably provided to fill the opening portion 190 as illustrated in FIG. 1B and FIG. 1C.

The capacitor 100 has a structure in which the upper electrode and the lower electrode face each other with the dielectric therebetween on the side surface as well as on the bottom surface of the opening portion 190; thus, the capacitance per unit area can be increased. Thus, the deeper the opening portion 190 is, the higher the capacitance of the capacitor 100 can be. Increasing the capacitance per unit area of the capacitor 100 in this manner enables a stable reading operation of the memory device. This also allows further miniaturization or high integration of the memory device.

Note that the sidewall of the opening portion 190 is preferably perpendicular to the top surface of the conductor 110. In that case, the opening portion 190 has a cylindrical shape. With the structure, the memory device can be miniaturized or highly integrated.

Although this embodiment describes the example where the opening portion 190 has a circular shape in the plan view, the present invention is not limited thereto. For example, the opening portion 190 in the plan view may have a substantially circular shape such as an elliptical shape, a polygonal shape such as a quadrangular shape, or a polygonal shape such as a quadrangular shape with rounded corners. In that case, the maximum width of the opening portion 190 is calculated as appropriate in accordance with the shape of the uppermost portion of the opening portion 190. For example, in the case where the opening portion 190 is quadrangular in the plan view, the maximum width of the opening portion 190 is preferably a length of the diagonal line of the uppermost portion of the opening portion 190.

Portions of the conductor 115, the insulator 130, and the conductor 120 that are placed in the opening portion 190 reflect the shape of the opening portion 190. Therefore, the conductor 115 is provided so as to cover the bottom portion and the sidewall of the opening portion 190, the insulator 130 is provided to cover the conductor 115, and the conductor 120 is provided so as to fill a depressed portion of the insulator 130 reflecting the shape of the opening portion 190.

The conductor 115 and the insulator 130 are stacked along the sidewall of the opening portion 190 and the top surface of the conductor 110. The conductor 120 is provided over the insulator 130 to fill the opening portion 190. The capacitor 100 having such a structure may be referred to as a trench-type capacitor or a trench capacitor.

The insulator 280 is placed over the capacitor 100. That is, the insulator 280 is placed over the conductor 115, the insulator 130, and the conductor 120. In other words, the conductor 120 is placed under the insulator 280.

The transistor 200 includes the conductor 120, a conductor 240 over the insulator 280, an oxide semiconductor 230, an insulator 250 over the oxide semiconductor 230, and a conductor 260 over the insulator 250. The oxide semiconductor 230 functions as a semiconductor layer, the conductor 260 functions as a gate electrode, the insulator 250 functions as a gate insulator, the conductor 120 functions as one of a source electrode and a drain electrode, and the conductor 240 functions as the other of the source electrode and the drain electrode.

As illustrated in FIG. 1B and FIG. 1C, an opening portion 290 reaching the conductor 120 is formed in the insulator 280 and the conductor 240. That is, the opening portion 290 is composed of an opening portion provided in the insulator 280 and an opening portion provided in the conductor 240. In that case, the side end portion of the opening portion provided in the insulator 280 and the side end portion of the opening portion provided in the conductor 240 are preferably aligned with each other.

At least part of the oxide semiconductor 230 is placed in the opening portion 290. The oxide semiconductor 230 includes a region in contact with the top surface of the conductor 120 in the opening portion 290, a region in contact with the side surface of the conductor 240 in the opening portion 290, and a region in contact with at least part of the top surface of the conductor 240. The insulator 250 is placed such that at least part of the insulator 250 is positioned in the opening portion 290. The conductor 260 is placed such that at least part of the conductor 260 is positioned in the opening portion 290. In addition, the conductor 260 is preferably provided to fill the opening portion 290 as illustrated in FIG. 1B and FIG. 1C.

The oxide semiconductor 230 includes a region in contact with the side surface of the conductor 240 in the opening portion 290 and a region in contact with part of the top surface of the conductor 240. When the oxide semiconductor 230 is in contact with not only the side surface but also the top surface of the conductor 240 in this manner, the area where the oxide semiconductor 230 and the conductor 240 are in contact with each other can be increased.

As illustrated in FIG. 1A to FIG. 1C, the transistor 200 is provided to overlap with the capacitor 100. The opening portion 290 where part of the structure of the transistor 200 is provided includes a region overlapping with the opening portion 190 where part of the structure of the capacitor 100 is provided. Since the conductor 120 has a function of one of a source electrode and a drain electrode of the transistor 200 and a function of the upper electrode of the capacitor 100, the transistor 200 and the capacitor 100 partly share the structure. With such a structure, the transistor 200 and the capacitor 100 can be provided without a great increase in the occupation area in the plan view. Thus, the occupation area of the memory cell 150 can be reduced, so that the memory cells 150 can be arranged densely and the memory capacity of the memory device can be increased. In other words, the memory device can be highly integrated.

FIG. 1D is a circuit diagram of the memory device described in this embodiment. As illustrated in FIG. 1D, the structure illustrated in FIG. 1A to FIG. 1C functions as a memory cell of the memory device. The memory cell includes a transistor Tr and a capacitor C. In this case, the transistor Tr and the capacitor C correspond to the transistor 200 and the capacitor 100, respectively.

One of a source and a drain of the transistor Tr is electrically connected to one of a pair of electrodes of the capacitor C. The other of the source and the drain of the transistor Tr is connected to a wiring BL. A gate of the transistor Tr is connected to a wiring WL. The other of the pair of electrodes of the capacitor C is connected to a wiring PL.

Here, the wiring BL corresponds to the conductor 240, the wiring WL corresponds to the conductor 260, and the wiring PL corresponds to the conductor 110. As illustrated in FIG. 1A to FIG. 1C, it is preferable that the conductor 260 be provided to extend in the Y direction and the conductor 240 be provided to extend in the X direction. In this structure, the wiring BL and the wiring WL are provided to intersect with each other. When the wiring BL and the wiring WL intersect with each other, the area of a region where the wiring BL and the wiring WL overlap with each other becomes small, so that parasitic capacitance generated between the wiring BL and the wiring WL can be reduced. Although the wiring PL (the conductor 110) is provided in a plane shape in FIG. 1A, the present invention is not limited thereto. For example, the wiring PL may be provided in parallel with the wiring WL (the conductor 260) or may be provided in parallel with the wiring BL (the conductor 240).

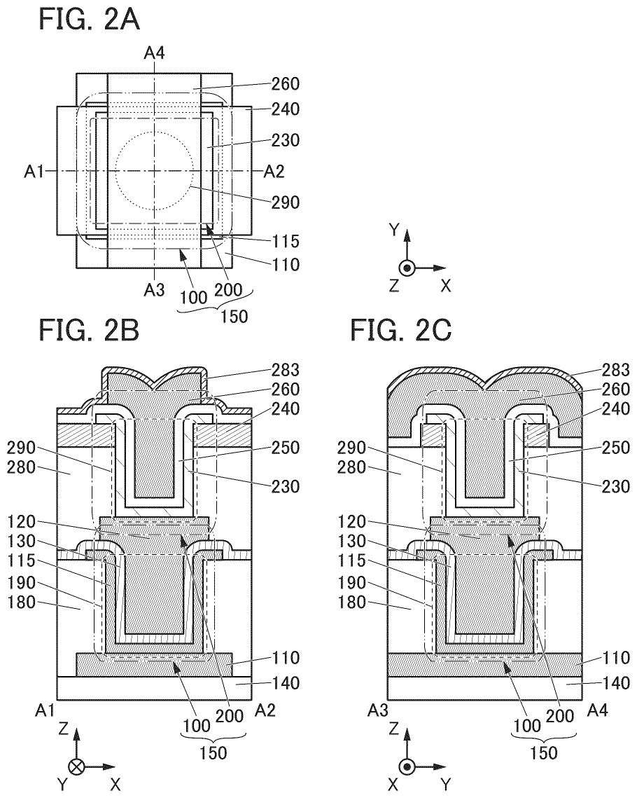

FIG. 2A to FIG. 2C illustrate a structure in which the conductor 110 is provided to extend in the Y direction. At this time, the conductor 110 is provided parallel to the conductor 260. The conductor 110 is orthogonal to the conductor 240.

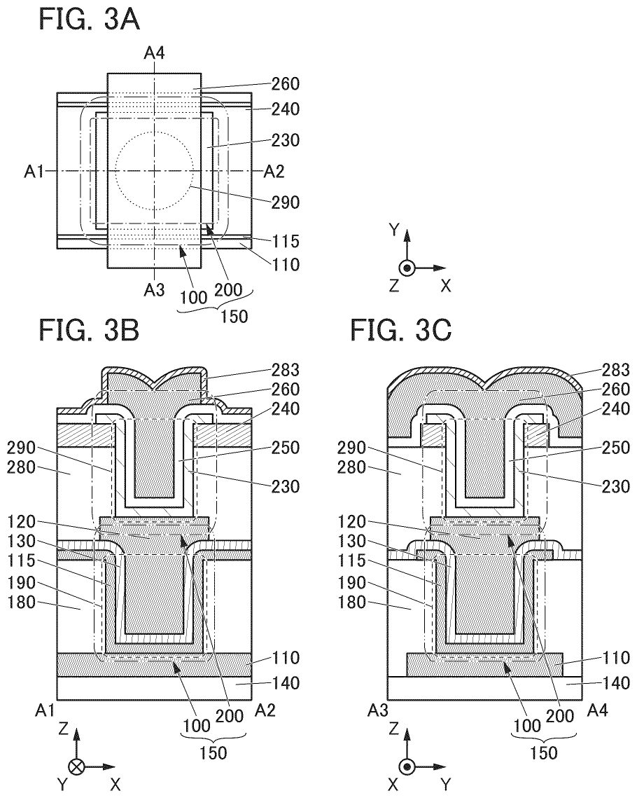

FIG. 3A to FIG. 3C illustrate a structure in which the conductor 110 is provided to extend in the X direction. At this time, the conductor 110 is provided parallel to the conductor 240. The conductor 110 is orthogonal to the conductor 260.

Although FIG. 1B illustrates the structure in which the conductor 115 is separated in the X direction, the present invention is not limited thereto. For example, as illustrated in FIG. 3A and FIG. 3B, the conductor 115 may be provided to extend in the X direction. In the structure where the conductor 110 is provided in a plane shape, the conductor 115 may be provided to extend in the X direction and the Y direction.

The memory cell will be described in detail in a later embodiment.

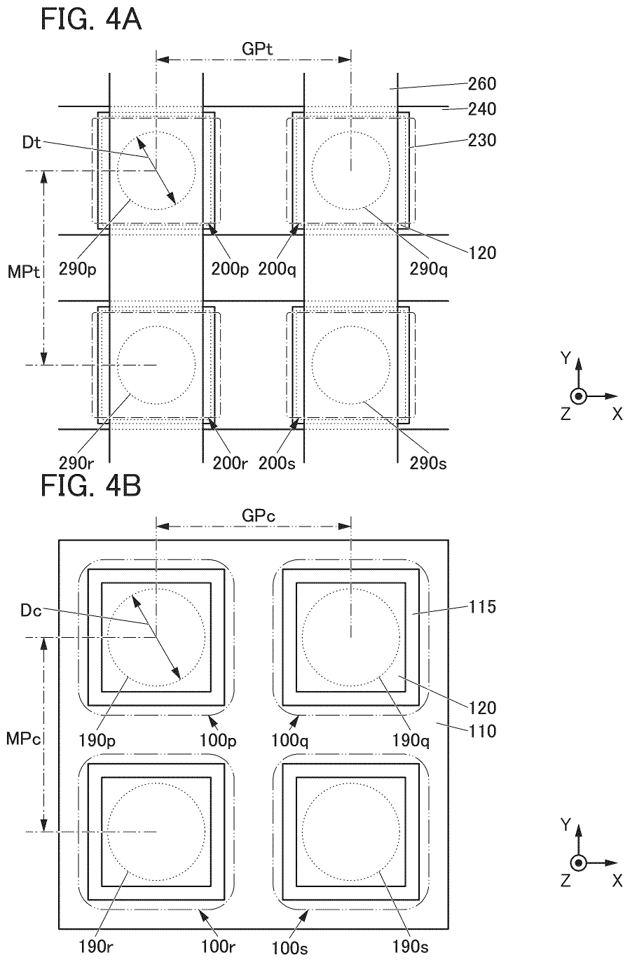

Note that the memory device of one embodiment of the present invention preferably includes a plurality of memory cells 150 arranged in a matrix. FIG. 4A and FIG. 4B illustrate an example of a memory device in which 2 x 2 memory cells 150 are arranged in a matrix in the X direction and the Y direction.

FIG. 4A is a plan view of a region including four transistors (a transistor 200p to a transistor 200s). Note that FIG. 4A selectively illustrates the conductor 120, the oxide semiconductor 230, the conductor 240, the conductor 260, and the opening portion 290 included in each transistor. The opening portion 290 provided in the insulator 280 and the conductor 240 is indicated by a dotted line. In addition, the insulator 280 is not illustrated in FIG. 4A.

In FIG. 4A, the conductor 240 and the insulator 280 include an opening portion 290p, an opening portion 290q, an opening portion 290r, and an opening portion 290s. At least part of the transistor 200p is placed in the opening portion 290p, at least part of the transistor 200q is placed in the opening portion 290q, at least part of the transistor 200r is placed in the opening portion 290r, and at least part of the transistor 200s is placed in the opening portion 290s.

FIG. 4B is a plan view of a region including four capacitors (a capacitor 100p to a capacitor 100s). Note that FIG. 4B selectively illustrates the conductor 110, the conductor 115, the conductor 120, and the opening portion 190 included in each capacitor. Note that the opening portions 190 provided in the insulator 180 are indicated by a dotted line. In addition, the insulator 180 is not illustrated in FIG. 4B.

In FIG. 4B, the insulator 180 includes an opening portion 190p, an opening portion 190q, an opening portion 190r, and an opening portion 190s. At least part of the capacitor 100p is placed in the opening portion 190p, at least part of the capacitor 100q is placed in the opening portion 190q, at least part of the capacitor 100r is placed in the opening portion 190r, and at least part of the capacitor 100s is placed in the opening portion 190s.

One memory cell is formed of the transistor 200p and the capacitor 100p, one memory cell is formed of the transistor 200q and the capacitor 100q, one memory cell is formed of the transistor 200r and the capacitor 100r, and one memory cell is formed of the transistor 200s and the capacitor 100s. The opening portion 190p includes a region overlapping with the opening portion 290p, the opening portion 190q includes a region overlapping with the opening portion 290q, the opening portion 190r includes a region overlapping with the opening portion 290r, and the opening portion 190s includes a region overlapping with the opening portion 290s.

For the structure of the transistor 200p to the transistor 200s, the above description of the transistor 200 can be referred to. For the structure of the capacitor 100p to the capacitor 100s, the above description of the capacitor 100 can be referred to. Matters common to the opening portion 190p to the opening portion 190s are described using the term “the opening portion 190” in some cases. Matters common to the opening portion 290p to the opening portion 290s are described using the term “the opening portion 290” in some cases.

In FIG. 4A, a maximum width Dt of the opening portion 290 is indicated by a solid double-headed arrow. Note that in the case where the opening portion is circular in the plan view, the maximum width of the opening portion can be rephrased as the maximum diameter of the opening portion. In FIG. 4B, a maximum width Dc of the opening portion 190 is indicated by a solid double-headed arrow.

In FIG. 4A, a distance GPt between adjacent transistors in the X direction is indicated by a dashed double-dotted double-headed arrow. For example, the distance GPt is an interval at which the transistors 200 are placed in the X direction. The distance GPt is a distance between the transistor 200p and the transistor 200q. Here, it can be said that the distance GPt is the distance between centers of the opening portions 290 adjacent in the X direction. It can be said that the distance GPt is an interval at which the conductors 260 functioning as the wirings WL are placed. Thus, the distance GPt can be rephrased as a gate pitch. In FIG. 4B, a distance GPc between adjacent capacitors in the X direction is indicated by a dashed double-dotted double-headed arrow. For example, the distance GPc is an interval at which the capacitors 100 are placed in the X direction. The distance GPc is an interval between the capacitor 100p and the capacitor 100q. Here, it can be said that the distance GPc is the distance between centers of the opening portions 190 adjacent in the X direction.

In FIG. 4A, a distance MPt between adjacent transistors in the Y direction is indicated by a dashed-dotted double-headed arrow. For example, the distance MPt is an interval at which the transistors 200 are placed in the Y direction. The distance MPt is an interval between the transistor 200p and the transistor 200r. Here, it can be said that the distance MPt is the distance between centers of the opening portions 290 adjacent in the Y direction. It can be said that the distance MPt is an interval at which the conductors 240 functioning as the wirings BL are placed. Thus, the distance MPt can be rephrased as a metal pitch. In FIG. 4B, a distance MPc between the capacitors adjacent in the Y direction is indicated by a dashed-dotted double-headed arrow. For example, the distance MPc is an interval at which the capacitors 100 are placed in the Y direction. The distance MPc is an interval between the capacitor 100p and the capacitor 100r. Here, it can be said that the distance MPc is the distance between centers of the opening portions 190 adjacent in the Y direction.

As illustrated in FIG. 4A, the opening portion 290 is provided to overlap with the conductor 120. As illustrated in FIG. 4B, the opening portion 190 is provided to overlap with the conductor 110.

The maximum width of the opening portion 190 is preferably different from that of the opening portion 290. Specifically, the maximum width Dc of the opening portion 190 is preferably different from the maximum width Dt of the opening portion 290. In particular, the maximum width Dc of the opening portion 190 is preferably larger than the maximum width Dt of the opening portion 290. With such a structure, the capacitance of the capacitor 100 can be increased. By increasing the maximum width Dc of the opening portion 190, the conductor 115, the insulator 130, and the conductor 120 can be surely embedded in the opening portion 190, so that a highly reliable memory device can be provided. Furthermore, the area of the conductor 120 in the plan view can be increased, so that the alignment accuracy of the opening portion 290 can be relaxed. Thus, the degree of difficulty in forming a minute memory cell can be reduced.

In addition to the above, the distance GPc is preferably equal to the distance GPt. The distance MPc is preferably equal to the distance MPt. With such a structure, the capacitance of the memory cell can be increased without increasing the occupied area. Thus, the reading operation of the memory device can be stabilized. In addition, a memory device that can be miniaturized or highly integrated can be provided.

Note that in this specification and the like, the expression “the distance A and the distance B are equal to each other” means that the value obtained by dividing the absolute value of the difference between the distance A and the distance B by the distance A is less than or equal to 0.1. Alternatively, the value obtained by dividing the absolute value of the difference between the distance A and the distance B by the distance B is less than or equal to 0.1.

Note that the distance GPc is equal to the distance GPt, the distance MPc is equal to the distance MPt, and the distance GPc is not necessarily equal to the distance MPc. Similarly, the distance GPt is not necessarily equal to the distance MPt.

The conductor 260 is a continuous film provided to be shared by the transistors 200 arranged in the Y direction, for example. The conductor 240 is a continuous film provided to be shared by the transistors 200 arranged in the X direction, for example.

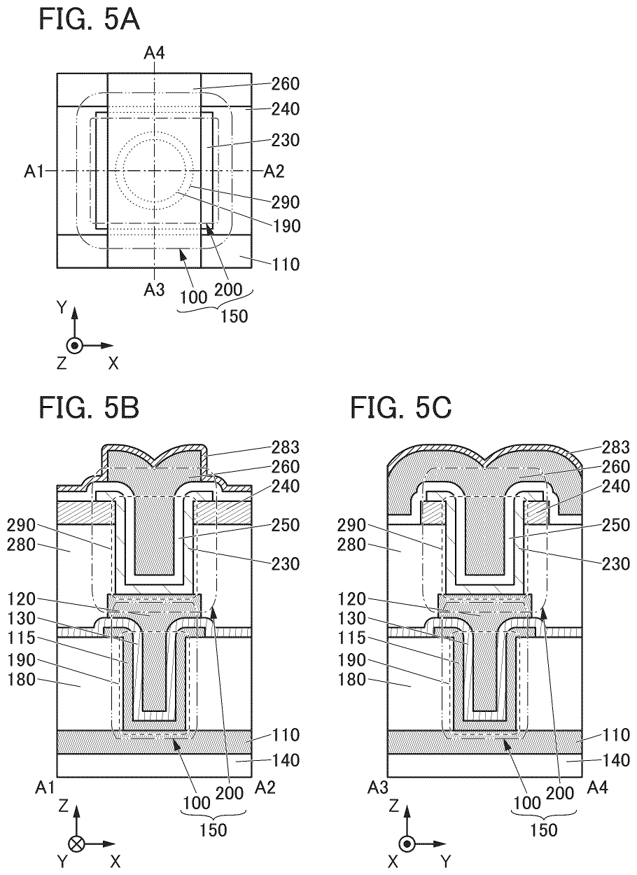

The case where the maximum width of the opening portion 190 is larger than the maximum width of the opening portion 290 is described above as an example. Note that in one embodiment of the present invention, the maximum width of the opening portion 190 is preferably different from the maximum width of the opening portion 290; thus, the maximum width of the opening portion 190 may be smaller than the maximum width of the opening portion 290 in some cases. In other words, the maximum width of the opening portion 290 may be larger than the maximum width of the opening portion 190 in some cases. FIG. 5A to FIG. 5C illustrate an example in which the maximum width of the opening portion 290 is larger than the maximum width of the opening portion 190. By increasing the maximum width of the opening portion 290, the channel width per unit area can be increased and the on-state current can be increased. Accordingly, the read speed and the write speed of the memory cell 150 can be increased; accordingly, a memory device with a high operation speed can be provided.

### [Capacitor 100]

The capacitor 100 includes the conductor 115, the insulator 130, and the conductor 120. The conductor 110 is provided below the conductor 115. The conductor 115 includes a region in contact with the conductor 110.

The conductor 110 is provided over the insulator 140. The conductor 110 functions as the wiring PL and can be provided in a plane shape, for example. As the conductor 110, a single layer or stacked layers of any of conductors described in a later-described section [Conductor] can be used. For example, a conductive material with high conductivity such as tungsten can be used for the conductor 110. With the use of a conductive material with high conductivity, the conductor 110 can have improved conductivity and can work well as the wiring PL.

A single layer or stacked-layer containing a conductive material that is less likely to be oxidized, a conductive material having a function of inhibiting diffusion of oxygen, or the like is preferably used for the conductor 115. For example, titanium nitride, indium tin oxide to which silicon is added, or the like may be used. A structure in which titanium nitride is stacked over tungsten may be used, for example. Alternatively, for example, a structure in which tungsten is stacked over a first titanium nitride and a second titanium nitride is stacked over the tungsten may be used. With this structure, in the case of using an oxide insulator for the insulator 130, oxidation of the conductor 110 due to the insulator 130 can be inhibited. In the case of using an oxide insulator for the insulator 180, oxidation of the conductor 110 due to the insulator 180 can be inhibited.

The insulator 130 is provided over the conductor 115. The insulator 130 can be provided to be in contact with the top surface and the side surface of the conductor 115. That is, the insulator 130 preferably covers the side end portion of the conductor 110. This can prevent a short circuit between the conductor 115 and the conductor 120.

For the insulator 130, any of materials with high relative permittivity, that is, high-k materials, described in a later-described section [Insulator] is preferably used. Using such a high-k material for the insulator 130 allows the insulator 130 to be thick enough to inhibit a leakage current and the capacitor 100 to have a sufficiently high capacitance.

It is preferable for the insulator 130 to use stacked insulating layers formed of any of the high-k materials, and it is preferable to use a stacked-layer structure of a high relative permittivity (high-k) material and a material having a higher dielectric strength than the high-k material. As the insulator 130, an insulating film in which zirconium oxide, aluminum oxide, and zirconium oxide are stacked in this order can be used, for example. An insulating film in which zirconium oxide, aluminum oxide, zirconium oxide, and aluminum oxide are stacked in this order can be used, for example. As another example, an insulating film in which hafnium zirconium oxide, aluminum oxide, hafnium zirconium oxide, and aluminum oxide are stacked in this order can be used. The use of stacked insulators with relatively high dielectric strength, such as aluminum oxide, can increase the dielectric strength and inhibit electrostatic breakdown of the capacitor 100.

Alternatively, a material that can have ferroelectricity may be used for the insulator 130. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or in the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO₃ with a k-alumina-type structure, and the like.

Note that although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator 130 can have a stacked-layer structure of a plurality of materials selected from the above-listed materials. Note that the crystal structures (properties) of the above-listed materials and the like can be changed depending on the processes as well as the film formation conditions; thus, a material that exhibits ferroelectricity is referred to not only as a ferroelectric but also as a material that can have ferroelectricity in this specification and the like.

A metal oxide containing one or both of hafnium and zirconium is preferable because the metal oxide can have ferroelectricity even when being processed into a thin film of several nanometers. Here, the thickness of the insulator 130 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The thickness is preferably greater than or equal to 8 nm and less than or equal to 12 nm, for example. When a ferroelectric layer that can be thinned is used, the capacitor 100 can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can have ferroelectricity even with a minute area. For example, a ferroelectric layer can have ferroelectricity even with an area (occupation area) in a top view less than or equal to 100 μm², less than or equal to 10 μm², less than or equal to 1 μm², or less than or equal to 0.1 μm². Furthermore, even a ferroelectric layer with an area of less than or equal to 10000 nm² or less than or equal to 1000 nm² can have ferroelectricity in some cases. With a small-area ferroelectric layer, the occupation area of the capacitor 100 can be reduced.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory has a structure which includes a transistor and a ferroelectric capacitor and in which one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

It is considered that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulator 130 can exhibit ferroelectricity, the insulator 130 needs to include a crystal. It is particularly preferable for the insulator 130 to include a crystal having an orthorhombic crystal structure to exhibit ferroelectricity. Incidentally, a crystal included in the insulator 130 may have one or more selected from cubic, tetragonal, orthorhombic, monoclinic, hexagonal crystal structures. Alternatively, the insulator 130 may have an amorphous structure. In that case, the insulator 130 may have a composite structure including an amorphous structure and a crystal structure.

The conductor 120 is provided in contact with part of the top surface of the insulator 130. As illustrated in FIG. 4B, the side end portion of the conductor 120 is preferably positioned inward from the side end portion of the conductor 115 in both the X direction and the Y direction. In addition, in the structure where the insulator 130 covers the side end portion of the conductor 115, the side end portion of the conductor 120 may be positioned outward from the side end portion of the conductor 115.

As the conductor 120, a single layer or stacked layers of any of conductors described in the later-described section [Conductor] can be used. In addition, a conductive material that is less likely to be oxidized, a conductive material having a function of inhibiting diffusion of oxygen, or the like is preferably used for the conductor 120. For example, titanium nitride, tantalum nitride, or the like can be used. For example, a structure in which tantalum nitride is stacked over titanium nitride may be used. In that case, titanium nitride is in contact with the insulator 130 and tantalum nitride is in contact with the oxide semiconductor 230. This structure can inhibit excessive oxidation of the conductor 120 due to the oxide semiconductor 230. In the case of using an oxide insulator for the insulator 130, excessive oxidation of the conductor 120 due to the insulator 130 can be inhibited. Alternatively, a structure in which tungsten is stacked over titanium nitride may be used as the conductor 120, for example.

The conductor 120 includes a region in contact with the oxide semiconductor 230 and thus is preferably formed using a conductive material containing oxygen described in the later-described section [Conductor]. When a conductive material containing oxygen is used for the conductor 120, the conductor 120 can maintain its conductivity even when absorbing oxygen. In addition, also in the case of using an insulator containing oxygen, e.g., zirconium oxide, as the insulator 130, the conductor 120 can maintain its conductivity, which is preferable. As the conductor 120, a single layer or stacked layers of indium tin oxide (also referred to as ITO), indium tin oxide to which silicon is added (also referred to as ITSO), indium zinc oxide (IZO (registered trademark)), or the like can be used, for example.

The insulator 180, which functions as an interlayer film, preferably has low relative permittivity. When a material with low relative permittivity is used for an interlayer film, parasitic capacitance generated between wirings can be reduced. As the insulator 180, a single layer or stacked layers of any of insulators each containing a material with low relative permittivity described in the later-described section [Insulator] can be used. In particular, silicon oxide and silicon oxynitride are preferable because they are thermally stable. At this time, an insulator 180b contains at least silicon and oxygen.

Although FIG. 1B and FIG. 1C show that the insulator 180 is a single layer, the present invention is not limited thereto. The insulator 180 may have a stacked-layer structure.

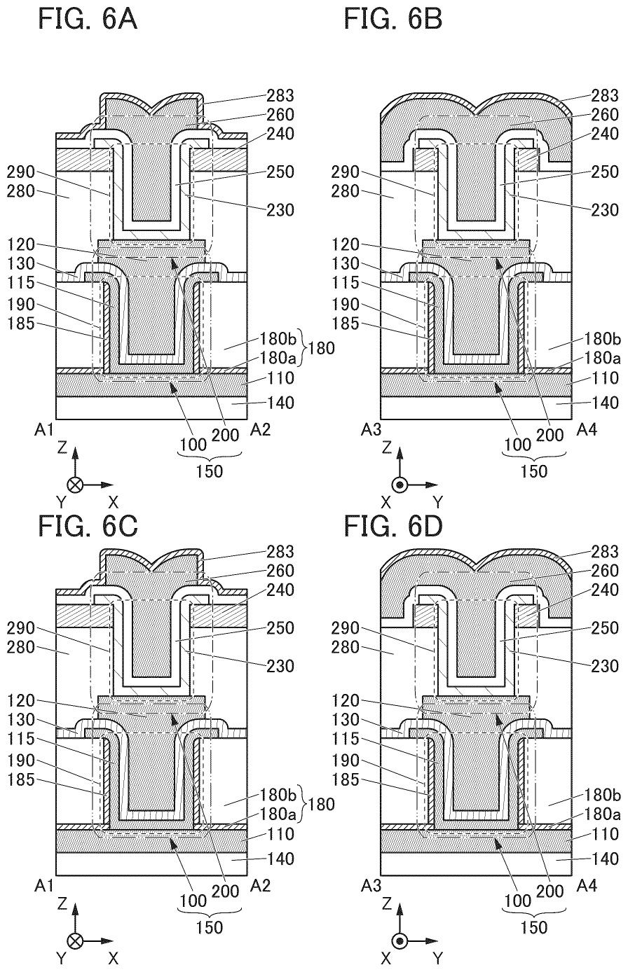

For example, as illustrated in FIG. 6A and FIG. 6B, the insulator 180 may have a stacked-layer structure of an insulator 180a and the insulator 180b over the insulator 180a.

The insulator 180b is preferably formed using an insulating material usable for the insulator 180 described above.

For the insulator 180a, any of insulators having a barrier property against oxygen described in the later-described section [Insulator] is preferably used. The conductor 110 is oxidized by oxygen contained in the insulator 180b and has high resistance in some cases. Providing the insulator 180a between the insulator 180b and the conductor 110 can inhibit the conductor 110 from being oxidized and having high resistance.

Entry of impurities such as hydrogen into the insulator 130 may increase the leakage current generated between the upper electrode and the lower electrode. In the case where a material that can have ferroelectricity is used for the insulator 130, entry of impurities such as hydrogen into the material that can have ferroelectricity may decrease the crystallinity of the material that can have ferroelectricity. In view of this, entry of impurities such as hydrogen into the insulator 130 is preferably inhibited.

For the insulator 180a, any of insulators having a barrier property against hydrogen described in the later-described section [Insulator] is preferably used. This can inhibit diffusion of hydrogen into the insulator 130 from below the capacitor 100 through the insulator 180b. Silicon nitride and silicon nitride oxide can be suitably used for the insulator 180a because the silicon nitride and the silicon nitride oxide release fewer impurities (e.g., water and hydrogen) and are less likely to transmit oxygen and hydrogen. In this case, the insulator 180a contains at least silicon and nitrogen.

For the insulator 180a, any of insulators having a function of capturing or fixing hydrogen described in the later-described section [Insulator] below is preferably used. With this structure, hydrogen in the insulator 130 can be captured or fixed, whereby the hydrogen concentration in the insulator 130 can be reduced. For the insulator 180a, magnesium oxide, aluminum oxide, hafnium oxide, or the like can be used. Alternatively, for example, a stacked-layer film of aluminum oxide and silicon nitride over the aluminum oxide may be used as the insulator 180a.

Although FIG. 6A and FIG. 6B each illustrate a structure in which the insulator 180 has a stacked-layer structure of two layers, one embodiment of the present invention is not limited thereto. The insulator 180 may have a stacked-layer structure of three or more layers.

For example, in the case where the insulator 180 has a stacked-layer structure of three layers, an insulator is preferably provided between the insulator 180b and the conductor 115 and the insulator 130 in addition to the insulator 180a and the insulator 180b. As the insulator, an insulator usable as the insulator 180a can be used. This can inhibit diffusion of hydrogen into the insulator 130 through the insulator 180b.

As illustrated in FIG. 6A and FIG. 6B, an insulator 185 is preferably provided between the conductor 115 and the insulator 180. The insulator 185 is preferably provided in contact with the side surface of the insulator 180 in the opening portion 190. That is, the insulator 185 is preferably provided between the conductor 115 and the side surface of the insulator 180 in the opening portion 190.

As the insulator 185, any of insulators having a barrier property against hydrogen described in the later-described section [Insulator] is preferably used. This can inhibit diffusion of hydrogen into the insulator 130 from the outside of the capacitor 100 through the insulator 180. For example, silicon nitride or silicon nitride oxide can be used as the insulator 185. In this case, the insulator 185 contains at least silicon and nitrogen.

As the insulator 185, any of insulators having a function of capturing or fixing hydrogen described in the later-described section [Insulator] is preferably used. With this structure, hydrogen in the insulator 130 can be captured or fixed, whereby the hydrogen concentration in the insulator 130 can be reduced. As the insulator 185, magnesium oxide, aluminum oxide, hafnium oxide, or the like can be used. Alternatively, for example, a stacked-layer film of aluminum oxide and silicon nitride over the aluminum oxide may be used as the insulator 185.

Although the insulator 185 is provided in contact with the side surface of the insulator 180a in the opening portion 190 and the side surface of the insulator 180b in the opening portion 190 in FIG. 6A and FIG. 6B, the present invention is not limited thereto. For example, as illustrated in FIG. 6C and FIG. 6D, the insulator 185 may be provided in contact with the side surface of the insulator 180b in the opening portion 190 and part of the top surface of the insulator 180a.

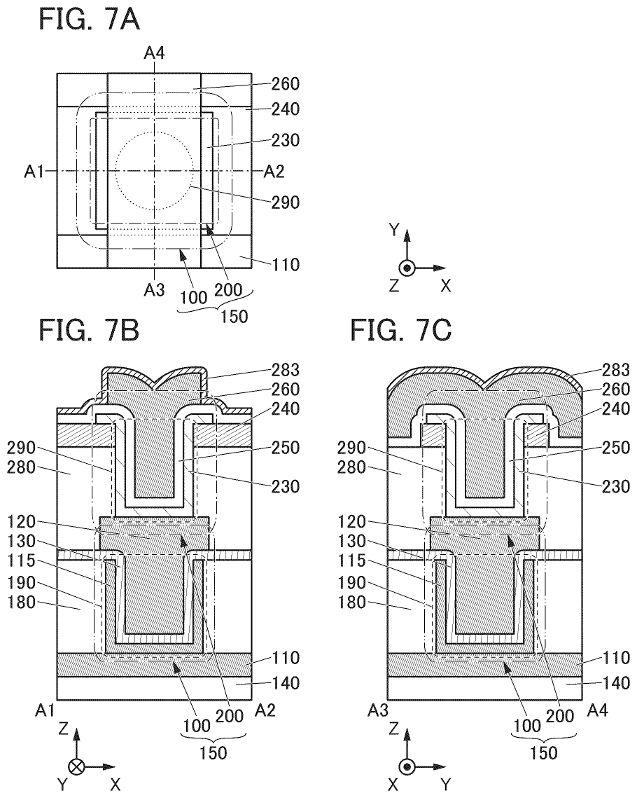

Although FIG. 1B and FIG. 1C illustrate a structure including a region where the conductor 115 is in contact with the top surface of the insulator 180, the present invention is not limited thereto. For example, as illustrated in FIG. 7B and FIG. 7C, the top surface of the conductor 115 may be level with the top surface of the insulator 180. In that case, the side end portion of the conductor 120 may be positioned outward from the side end portion of the conductor 115 as illustrated in FIG. 7A to FIG. 7C. Note that the side end portion of the conductor 120 may be aligned with the side end portion of the conductor 115 or positioned inside the side end portion of the conductor 115.

Although FIG. 7A to FIG. 7C illustrate a structure in which the top surface of the conductor 120 is higher than the top surface of the insulator 130, the present invention is not limited thereto. For example, the top surface of the conductor 120 may be level with the top surface of the insulator 130 or lower than the top surface of the insulator 130.

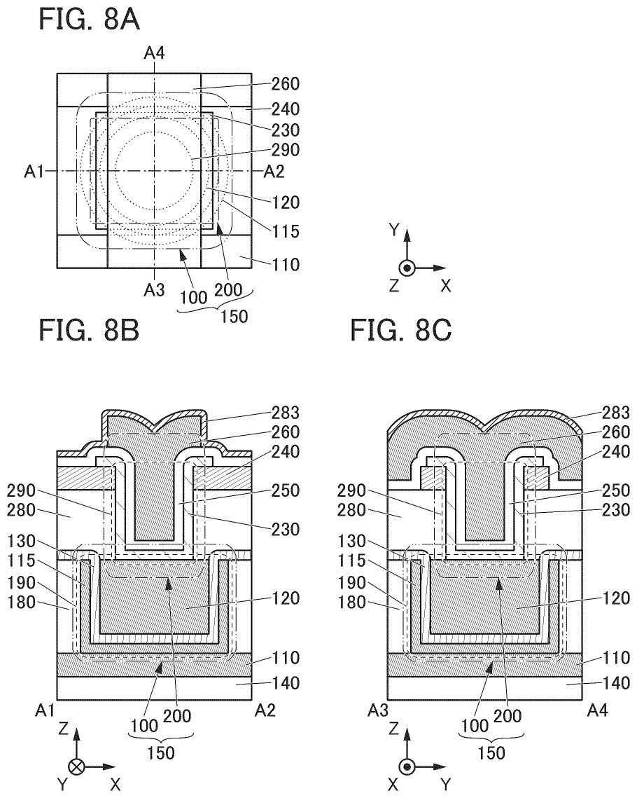

FIG. 8A to FIG. 8C illustrate an example of a memory device having a structure different from that illustrated in FIG. 7A to FIG. 7C. FIG. 8A is a plan view illustrating an example of the memory device. FIG. 8B and FIG. 8C are cross-sectional views of the memory device. Here, FIG. 8B is a cross-sectional view of a portion indicated by the dashed-dotted line A1-A2 in FIG. 8A. FIG. 8C is a cross-sectional view of a portion indicated by the dashed-dotted line A3-A4 in FIG. 8A. Note that some components are omitted in the plan view of FIG. 8A for clarity of the drawing.

The memory device illustrated in FIG. 8A to FIG. 8C is different from the memory device illustrated in FIG. 7A to FIG. 7C mainly in the shape of the conductor 120.

In the memory device illustrated in FIG. 7A to FIG. 7C, as the maximum width of the opening portion 190 increases, the distance between the side surfaces of adjacent conductors 120 decreases. As this distance becomes shorter, it becomes more difficult to separate the adjacent conductors 120. In the case where the adjacent conductors 120 are provided not to be separated from each other and thus to be shared between the adjacent capacitors 100, a leakage current flows between the capacitors 100.

In view of the above, the structure where the level of the top surface of the conductor 120 is lower than the level of the top surface of the insulator 130 is employed as illustrated in FIG. 8B and FIG. 8C. Accordingly, the adjacent conductors 120 can be surely separated. Thus, a leakage current between the capacitors 100 can be inhibited even with a large maximum width of the opening portion 190.

Note that the level of the top surface of the conductor 120 is preferably lower than the level of the top surface of the insulator 130 and equal to the level of the top surface of the conductor 115 or its vicinity. Such a structure can inhibit a reduction in the capacitance of the capacitor 100.

Although FIG. 8A to FIG. 8C illustrate a structure including a region where the conductor 120 and the bottom surface of the oxide semiconductor 230 are in contact with each other, the present invention is not limited thereto. For example, a conductor may be provided between the conductor 120 and the oxide semiconductor 230.

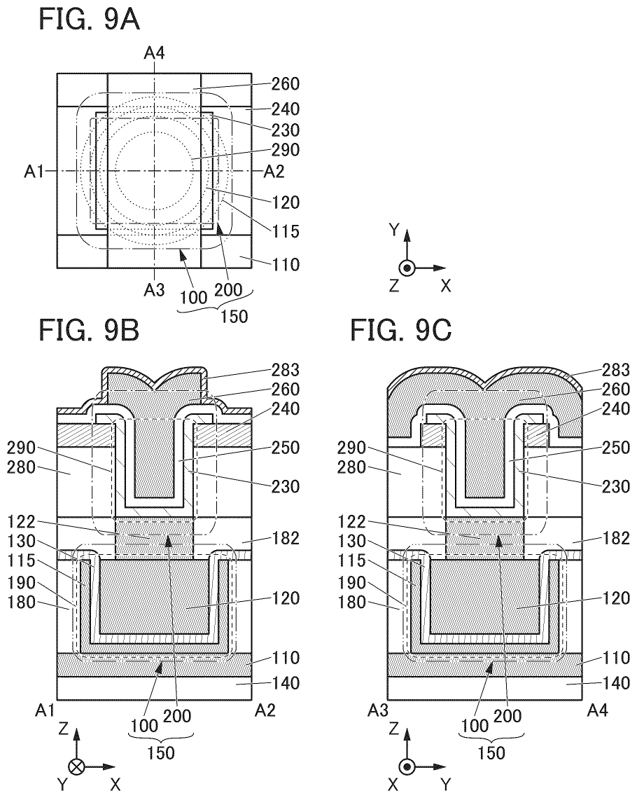

FIG. 9A to FIG. 9C illustrate a structure in which a conductor 122 is provided between the conductor 120 and the oxide semiconductor 230. That is, a memory device illustrated in FIG. 9A to FIG. 9C is different from the memory device illustrated in FIG. 8A to FIG. 8C mainly in including the conductor 122.

The conductor 122 is provided over the conductor 120, and the oxide semiconductor 230 is provided over the conductor 122. The conductor 122 includes a region in contact with at least part of the top surface of the conductor 120 and a region in contact with at least part of the bottom surface of the oxide semiconductor 230. Furthermore, as illustrated in FIG. 9B and FIG. 9C, the conductor 122 is preferably provided to be embedded in an insulator 182. In this case, the top surface of the conductor 122 and the top surface of the insulator 182 are level with each other.

As illustrated in FIG. 9B and FIG. 9C, the width of the conductor 122 is preferably smaller than the maximum width of the opening portion 190 in the cross-sectional view. With such a structure, the distance between the adjacent conductors 122 can be increased, so that the parasitic capacitance between the adjacent conductors 122 can be inhibited.

Furthermore, the width of the conductor 122 is preferably equal to the maximum width of the opening portion 290 or larger than the maximum width of the opening portion 290 in the cross-sectional view. For example, in the case where the width of the conductor 122 is equal to the maximum width of the opening portion 290 in the cross-sectional view, the same mask can be used in the anisotropic etching performed at the time of forming the opening portion 290 and an opening portion in which the conductor 122 is provided. Thus, the number of masks can be reduced, and the cost of the memory device can be reduced. Furthermore, in the case where the width of the conductor 122 is larger than the maximum width of the opening portion 290 in the cross-sectional view, the alignment accuracy of the opening portion 290 is relaxed, for example. Thus, the degree of difficulty in forming a minute memory cell can be reduced.

The conductor 122 includes a region that electrically connects the capacitor 100 and the transistor 200 to function as a plug. In addition, the conductor 122 includes a region functioning as one of the source electrode and the drain electrode of the transistor 200.

With the above structure, the transistor 200 can be favorably formed over the capacitor 100 even in the case where the top surface of the conductor 120 is not sufficiently planarized.

As the conductor 122, a single layer or stacked layers of any of conductors described in the later-described section [Conductor] can be used. In addition, a conductive material that is less likely to be oxidized, a conductive material having a function of inhibiting diffusion of oxygen, or the like is preferably used for the conductor 122. For example, titanium nitride, tantalum nitride, or the like can be used. For example, a structure in which tantalum nitride is stacked over titanium nitride may be used. In that case, titanium nitride is in contact with the conductor 120 and the insulator 182, and tantalum nitride is in contact with the oxide semiconductor 230. This structure can inhibit excessive oxidation of the conductor 122 due to the oxide semiconductor 230. Excessive oxidation of the conductor 122 by the insulator 182 can also be inhibited. Alternatively, the conductor 122 may have a structure in which tungsten is stacked over titanium nitride, for example.

The insulator 182, which functions as an interlayer film, preferably has low relative permittivity. When a material with low relative permittivity is used for an interlayer film, parasitic capacitance generated between wirings can be reduced. As the insulator 182, an insulator usable for the insulator 180 can be used.

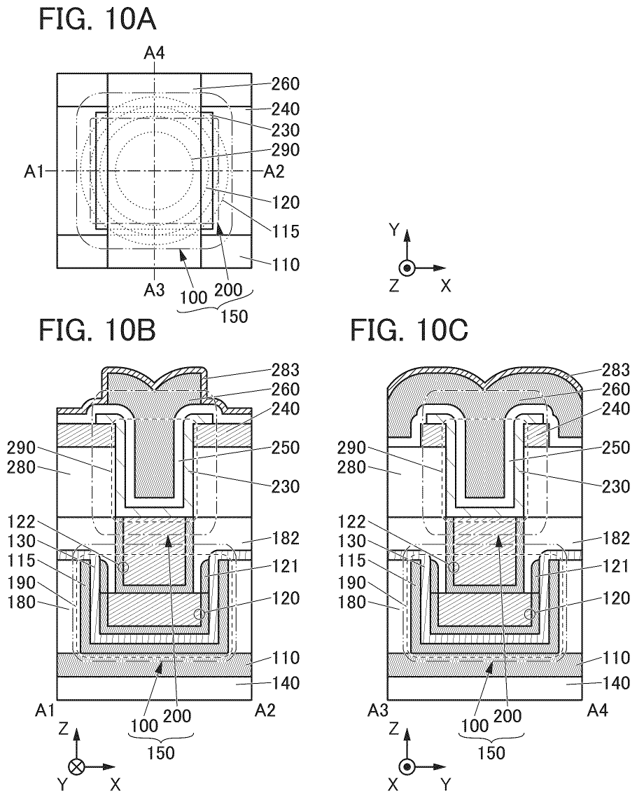

Although the conductor 120 and the conductor 122 each have a single-layer structure in FIG. 9B and FIG. 9C, the conductor 120 and the conductor 122 may each have a stacked-layer structure. For example, as illustrated in FIG. 10A to FIG. 10C, the conductor 120 and the conductor 122 may have a stacked-layer structure of two layers.

As described above, each of the conductor 120 and the conductor 122 may have a structure in which tantalum nitride is stacked over titanium nitride, for example. Alternatively, a structure in which tungsten is stacked over titanium nitride may be employed, for example.

Note that as illustrated in FIG. 10A to FIG. 10C, a conductor 121 may be provided over the conductor 120. The conductor 121 includes a region in contact with part of the top surface of the conductor 120 and a region in contact with part of a side surface of the insulator 130. Furthermore, the conductor 121 includes a region facing the conductor 115 with the insulator 130 therebetween. In this case, each of the conductor 120 and the conductor 121 functions as one of a pair of electrodes of the capacitor 100. That is, in the structures illustrated in FIG. 10A to FIG. 10C, the capacitor 100 includes the conductor 121 in addition to the conductor 115, the insulator 130, and the conductor 120.

With the above structure, the capacitance of the capacitor 100 can be sufficiently ensured even when the top surface of the conductor 120 is lower than the top surface of the conductor 115.

Although FIG. 9A to FIG. 9C illustrate a structure in which the conductor 122 is provided between the conductor 120 and the oxide semiconductor 230, the present invention is not limited thereto. For example, a conductor may be further provided between the conductor 122 and the oxide semiconductor 230.

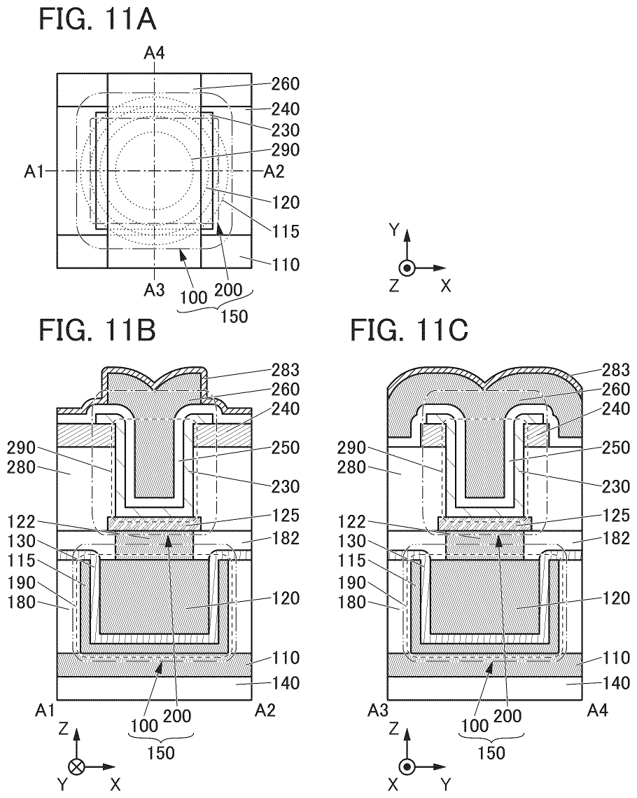

FIG. 11A to FIG. 11C illustrate a structure in which a conductor 125 is provided between the conductor 122 and the oxide semiconductor 230. That is, a memory device illustrated in FIG. 11A to FIG. 11C is different from the memory device illustrated in FIG. 9A to FIG. 9C mainly in including the conductor 125. In addition, the memory device illustrated in FIG. 11A to FIG. 11C is different from the memory device illustrated in FIG. 8A to FIG. 8C mainly in including the conductor 122 and the conductor 125.

The conductor 125 is provided over the conductor 122, and the oxide semiconductor 230 is provided over the conductor 125. The conductor 125 includes a region in contact with the top surface of the conductor 122 and a region in contact with at least part of the bottom surface of the oxide semiconductor 230.

The conductor 122 includes a region that electrically connects the capacitor 100 and the transistor 200 to function as a plug. The conductor 125 includes a region functioning as one of the source electrode and the drain electrode of the transistor 200. Materials and the like that can be used for the conductor 125 will be described later.

As illustrated in FIG. 11B and FIG. 11C, the width of the conductor 125 is preferably larger than the width of the conductor 122 in a cross-sectional view. The width of the conductor 125 is preferably larger than the maximum width of the opening portion 290 in the cross-sectional view. Such a structure relaxes the alignment accuracy of the opening portion 290. Thus, the degree of difficulty in forming a minute memory cell can be reduced.

Although the conductor 120 is positioned inward from the conductor 115 with the insulator 130 therebetween in FIG. 1B and FIG. 1C, the present invention is not limited thereto. For example, the conductor 120 may be positioned outward from the conductor 115 with the insulator 130 therebetween.

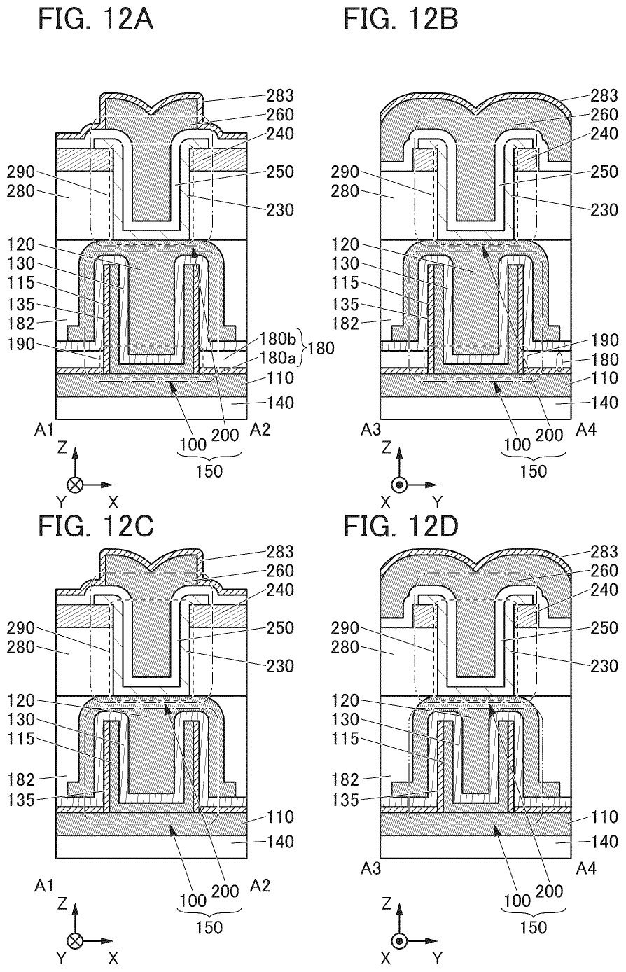

For example, as illustrated in FIG. 12A and FIG. 12B, the insulator 130 includes a region positioned on the outer side surface side of the conductor 115, in addition to a region in contact with the inner side of a depressed portion of the conductor 115 and a region in contact with the top surface of the conductor 115.

The conductor 120 is provided to fill the depressed portion of the conductor 115 with the insulator 130 therebetween. Furthermore, the conductor 120 includes a region facing the part of the outer side surface of the conductor 115 with the insulator 130 therebetween.

With the above structure, the capacitance per unit area can be further increased.

As illustrated in FIG. 12A and FIG. 12B, an insulator 135 may be provided between the outer side surface of the conductor 115 and the insulator 130 and the insulator 180.

The insulator 182 may be provided over the conductor 120 and the insulator 130. The insulator 182 is preferably subjected to planarization treatment so that the top surface of the conductor 120 is exposed. The planarization treatment for the insulator 182 allows the transistor 200 to be suitably formed over the capacitor 100.

The insulator 182, which functions as an interlayer film, preferably has low relative permittivity. When a material with low relative permittivity is used for an interlayer film, parasitic capacitance generated between wirings can be reduced. As the insulator 182, an insulator usable for the insulator 180 can be used.

As long as sufficient capacitance of the memory cell can be obtained by providing the conductor 120 so as to face the inner side and the outer side of the conductor 115 as illustrated in FIG. 12A and FIG. 12B, a structure in which the insulator 180b is not provided may be employed.

A memory device illustrated in FIG. 12C and FIG. 12D is different from the memory device illustrated in FIG. 12A and FIG. 12B in not including the insulator 180b. When the insulator 180b is not provided, the manufacturing process of the memory device can be simplified.

### [Transistor 200]

As illustrated in FIG. 1A to FIG. 1C, the transistor 200 can have a structure including the conductor 120; the conductor 240 over the insulator 280; the oxide semiconductor 230 provided in contact with the top surface of the conductor 120, which is exposed in the opening portion 290, the side surface of the insulator 280 in the opening portion 290, the side surface of the conductor 240 in the opening portion 290, and at least part of the top surface of the conductor 240; the insulator 250 provided in contact with the top surface of the oxide semiconductor 230; and the conductor 260 provided in contact with the top surface of the insulator 250.

At least part of the components of the transistor 200 is placed in the opening portion 290. Here, the bottom portion of the opening portion 290 is the top surface of the conductor 120, and the sidewall of the opening portion 290 is the side surface of the insulator 280 and the side surface of the conductor 240.

Note that the sidewall of the opening portion 290 is preferably perpendicular to the top surface of the conductor 120. At this time, the opening portion 290 has a cylindrical shape. With the structure, the memory device can be miniaturized or highly integrated.

Although this embodiment describes the example where the opening portion 290 has a circular shape in the plan view, the present invention is not limited thereto. For example, the opening portion 290 in the plan view may have a substantially circular shape such as an elliptical shape, a polygonal shape such as a quadrangular shape, or a polygonal shape such as a quadrangular shape with rounded corners. In that case, the maximum width of the opening portion 290 is calculated as appropriate in accordance with the shape of the uppermost portion of the opening portion 290. For example, in the case where the opening portion 290 is quadrangular in the plan view, the maximum width of the opening portion 290 is preferably a length of the diagonal line of the uppermost portion of the opening portion 290.

Portions of the oxide semiconductor 230, the insulator 250, and the conductor 260 that are placed in the opening portion 290 reflect the shape of the opening portion 290. Thus, the oxide semiconductor 230 is provided so as to cover the bottom portion and the sidewall of the opening portion 290, the insulator 250 is provided to cover the oxide semiconductor 230, and the conductor 260 is provided so as to fill a depressed portion of the insulator 250 reflecting the shape of the opening portion 290.

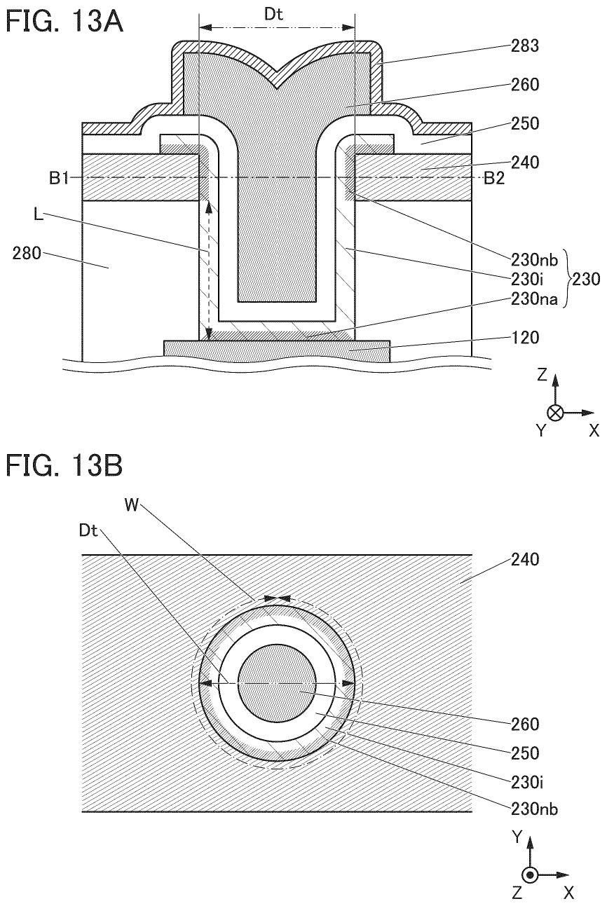

FIG. 13A is an enlarged view of the oxide semiconductor 230 and its vicinity in FIG. 1B. FIG. 13B is a cross-sectional view of a portion indicated by the dashed-dotted line B1-B2 in FIG. 13A, and is a cross-sectional view along the XY plane including the conductor 240.

As illustrated in FIG. 13A, the oxide semiconductor 230 includes a region 230i, and a region 230na, and a region 230nb.

The region 230na is a region in contact with the conductor 120 in the oxide semiconductor 230. At least part of the region 230na functions as one of the source region and the drain region of the transistor 200. The region 230nb is a region in contact with the conductor 240 in the oxide semiconductor 230. At least part of the region 230nb functions as the other of the source region and the drain region of the transistor 200. As illustrated in FIG. 13B, the conductor 240 is in contact with all the outer circumference of the oxide semiconductor 230. Thus, the other of the source region and the drain region of the transistor 200 can be formed in all the outer circumference of a portion of the oxide semiconductor 230 that is formed in the same layer as the conductor 240.

At least part of the region 230i is positioned between the region 230na and the region 230nb of the oxide semiconductor 230. At least part of the region 230i functions as a channel formation region of the transistor 200. In other words, the channel formation region of the transistor 200 is positioned in a region of the oxide semiconductor 230 between the conductor 120 and the conductor 240. It can be said that the channel formation region of the transistor 200 is positioned in a region of the oxide semiconductor 230 that is in contact with the insulator 280 or a region in the vicinity thereof.

It is preferable that the channel formation region of the transistor including oxide semiconductor as a semiconductor layer contain fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen enters (hereinafter sometimes referred to as VoH), which generates an electron serving as a carrier. Thus, it is preferable that VoH be also decreased in the channel formation region. Thus, the channel formation region of the transistor is a high-resistance region having a low carrier concentration. Thus, the channel formation region of the transistor can be regarded as being i-type (intrinsic) or substantially i-type.

Meanwhile, the source region and the drain region of the transistor including oxide semiconductor as a semiconductor layer include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the transistor are n-type regions that have a higher carrier concentration and a lower resistance than the channel formation region.

Although the details will be described later, in the case where an insulator containing oxygen that is released by heating (hereinafter, sometimes referred to as excess oxygen) is used as the insulator 280, oxygen can be supplied from the insulator 280 to a region of the oxide semiconductor 230 that is in contact with the insulator 280 by heat treatment, and oxide vacancies and VoH in the region can be reduced. Furthermore, oxygen contained in the insulator 280 is supplied to a region of the oxide semiconductor 230 that is in contact with the insulator 250 through the insulator 250, so that oxygen vacancies and V_{O}H in the region can be reduced. Thus, as illustrated in FIG. 13A and FIG. 13B, the region 230i including a smaller amount of oxygen vacancies than the region 230na and the region 230nb is positioned in the vicinity of the insulator 280 and the insulator 250.

When the oxide semiconductor 230 and the conductor 120 are in contact with each other, a metal compound is formed or oxygen vacancies are formed, so that the resistance of the region 230na in the oxide semiconductor 230 is reduced. The reduction in the resistance of the oxide semiconductor 230 in contact with the conductor 120 can reduce the contact resistance between the oxide semiconductor 230 and the conductor 120. Similarly, when the oxide semiconductor 230 and the conductor 240 are in contact with each other, the resistance of the region 230nb in the oxide semiconductor 230 is reduced. Accordingly, the contact resistance between the oxide semiconductor 230 and the conductor 240 can be reduced.

Note that the range of the region 230na and the region 230nb is changed depending on the degree of reduction in the resistance of the region 230na and the region 230nb and the amount of oxygen supplied from the insulator 280 through the insulator 250. For example, in the case where the degree of reduction in the resistance of the region 230na and the region 230nb is high, or in the case where the amount of oxygen supplied from the insulator 280 through the insulator 250 is small, the region 230na and the region 230nb may extend to the interface with the insulator 250.

The channel length of the transistor 200 is a distance between the source and the drain. In other words, the channel length of the transistor 200 is determined by the thickness of the insulator 280 over the conductor 120. In FIG. 13A, a channel length L of the transistor 200 is indicated by a dashed double-headed arrow. In the cross-sectional view, the channel length L is a distance between an end portion of the region where the oxide semiconductor 230 is in contact with the conductor 120 and an end portion of the region where the oxide semiconductor 230 is in contact with the conductor 240. That is, the channel length L corresponds to the length of the side surface of the insulator 280 on the opening portion 290 side in the cross-sectional view.

In a planar transistor, the channel length is determined by the light exposure limit of photolithography. However, in the present invention, the channel length can be determined by the thickness of the insulator 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 200 can have a higher on-state current and improved frequency characteristics. Accordingly, the read speed and the write speed of the memory cell 150 can be increased; accordingly, a memory device with a high operation speed can be provided.

In addition, as described above, the channel formation region, the source region, and the drain region can be formed in the oxide semiconductor 230 in the opening portion 290. Thus, the occupation area of the transistor 200 can be reduced as compared with a planar transistor in which a channel formation region, a source region, and a drain region are provided separately on the XY plane. This allows high integration of the memory device; thus, the memory capacity per unit area can be increased.

Furthermore, in the XY plane including the channel formation region of the oxide semiconductor 230, as in FIG. 13B, the oxide semiconductor 230, the insulator 250, and the conductor 260 are provided concentrically. Thus, the side surface of the conductor 260 provided at the center faces the side surface of the oxide semiconductor 230 with the insulator 250 therebetween. That is, in the plan view, all the circumference of the oxide semiconductor 230 serves as the channel formation region. In this case, for example, the channel width of the transistor 200 is determined by the length of the outer circumference of the oxide semiconductor 230. In other words, the channel width of the transistor 200 is determined by the maximum width of the opening portion 290 (the maximum diameter in the case where the opening portion 290 is circular in the plan view). In FIG. 13A and FIG. 13B, the maximum width Dt of the opening portion 290 is indicated by a dashed double-dotted double-headed arrow. In FIG. 13B, a channel width W of the transistor 200 is indicated by a dashed-dotted double-headed arrow. By increasing the maximum width Dt of the opening portion 290, the channel width per unit area can be increased and the on-state current can be increased.

In the case where the opening portion 290 is formed by a photolithography method, the maximum width Dt of the opening portion 290 is determined by the light exposure limit of photolithography. In addition, the maximum width Dt of the opening portion 290 is determined by the thicknesses of the oxide semiconductor 230, the insulator 250, and the conductor 260 provided in the opening portion 290. The maximum width Dt of the opening portion 290 is preferably, for example, greater than or equal to 1 nm, greater than or equal to 5 nm, or greater than or equal to 10 nm and less than or equal to 100 nm, less than or equal to 60 nm, less than or equal to 50 nm, less than or equal to 40 nm, less than or equal to 30 nm, or less than or equal to 20 nm. In the case where the opening portion 290 is circular in the plan view, the maximum width Dt of the opening portion 290 corresponds to the diameter of the opening portion 290, and the channel width W can be “D×π”.

In the memory device of one embodiment of the present invention, the channel length L of the transistor 200 is preferably shorter than at least the channel width W of the transistor 200. The channel length L of the transistor 200 in one embodiment of the present invention is greater than or equal to 0.1 times and less than or equal to 0.99 times, preferably greater than or equal to 0.5 times and less than or equal to 0.8 times the channel width W of the transistor 200. This structure enables a transistor with favorable electrical characteristics and high reliability.

In the case where the opening portion 290 is formed to be circular in the plan view, the oxide semiconductor 230, the insulator 250, and the conductor 260 are formed concentrically. This makes the distance between the conductor 260 and the oxide semiconductor 230 substantially uniform, so that a gate electric field can be substantially uniformly applied to the oxide semiconductor 230.

The distance between the interface between the conductor 240 and the oxide semiconductor 230 in the opening portion 290 and the side end portion of the conductor 240 in the Y direction is preferably small. The distance is preferably greater than or equal to 1 nm, greater than or equal to 1.5 nm, or greater than or equal to 2 nm, and less than or equal to 20 nm, less than or equal to 10 nm, less than or equal to 5 nm, or less than or equal to 3 nm. With such a structure, the width of the conductor 240 in the Y direction can be small, and an interval at which the conductors 240 are placed can be small. Thus, miniaturization and high integration of the memory device can be achieved.

Although the opening portion 290 is provided such that the sidewall of the opening portion 290 is substantially perpendicular to the top surface of the conductor 110 in FIG. 1B and FIG. 1C, the present invention is not limited thereto. The sidewall of the opening portion 290 may have a tapered shape, for example.

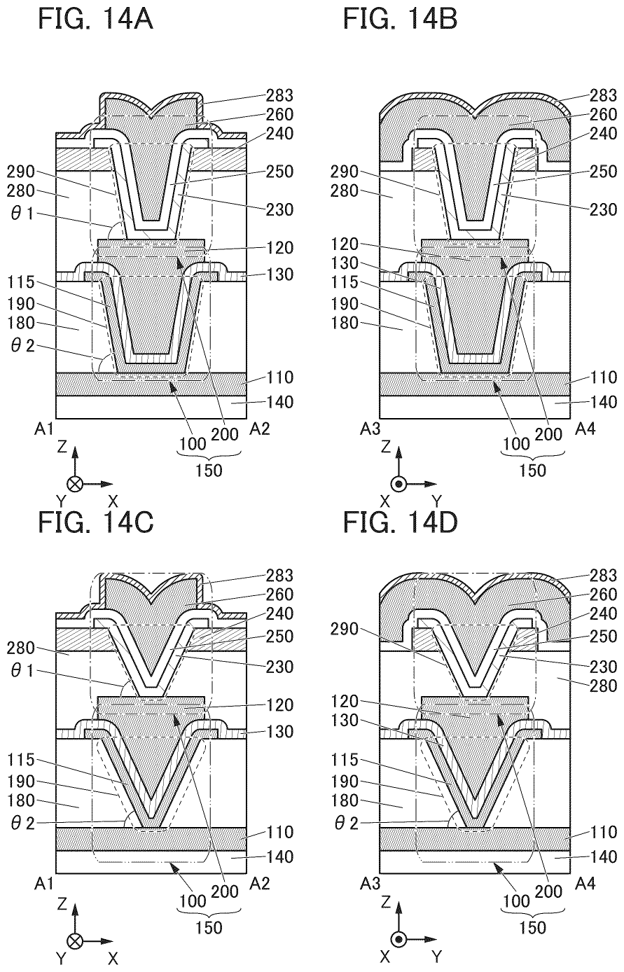

A memory device illustrated in FIG. 14A and FIG. 14B has a structure in which the sidewall of the opening portion 290 is tapered. FIG. 1A can be referred to for the plan view of the memory device illustrated in FIG. 14A and FIG. 14B.

When the sidewall of the opening portion 290 has a tapered shape, the coverage with the oxide semiconductor 230, the insulator 250, or the like can be improved, so that defects such as voids can be reduced. For example, the angle subtended between the side surface of the insulator 280 in the opening portion 290 and the top surface of the conductor 120 (an angle θ1 illustrated in FIG. 14A) is preferably greater than or equal to 45° and less than 90°. Alternatively, it is preferably greater than or equal to 45° and less than or equal to 75°. Alternatively, it is preferably greater than or equal to 45° and less than or equal to 65°.

Note that in this specification and the like, the tapered shape refers to a shape in which at least part of the side surface of a component is inclined to a substrate surface or a formation surface. For example, there is a region where the angle subtended between the inclined side surface and the substrate surface (hereinafter, the angle is sometimes referred to as a taper angle) is less than 90°. Note that the side surface of the component and the substrate surface are not necessarily completely flat and may be substantially planar with a slight curvature or substantially planar with slight unevenness.

The opening portion 290 illustrated in FIG. 14A and FIG. 14B has a frusto-conical shape. In this case, the opening portion 290 is circular in the plan view and the opening portion 290 is trapezoidal in the cross-sectional view. The area of the upper base plane of the frusto-conical shape (e.g., the opening portion provided in the conductor 240) is larger than the area of the lower base plane of the frusto-conical shape (the top surface of the conductor 120 exposed in the opening portion 290). In this case, the maximum diameter of the opening portion 290 is preferably calculated from the upper base plane of the frusto-conical shape.

In the case where the sidewall of the opening portion 290 has a tapered shape, the channel length can be set by the thickness of the insulator 280 and the angle 01 subtended between the side surface of the insulator 280 in the opening portion 290 and the top surface of the conductor 120. The length of the outer perimeter of the oxide semiconductor 230 is preferably obtained at a position in a region facing the conductor 240 or at a position corresponding to the half of the thickness of the insulator 280, for example. In addition, the length of the circumference of the opening portion 290 at an arbitrary position may be regarded as the channel width of the transistor 200 as necessary. For example, the length of the circumference at the lowest portion of the opening portion 290 may be regarded as the channel width, or the length of the circumference at the uppermost portion of the opening portion 290 may be regarded as the channel width.

Although FIG. 14A and FIG. 14B illustrate a structure in which the side surface of the conductor 240 in the opening portion 290 is aligned with the side surface of the insulator 280 in the opening portion 290, the present invention is not limited to the structure. For example, the side surface of the conductor 240 in the opening portion 290 and the side surface of the insulator 280 in the opening portion 290 may be discontinuous. The inclination of the side surface of the conductor 240 in the opening portion 290 and the inclination of the side surface of the insulator 280 in the opening portion 290 may be different from each other. For example, the angle subtended between the side surface of the conductor 240 in the opening portion 290 and the top surface of the conductor 120 is preferably smaller than the angle 01. With such a structure, the coverage of the side surface of the conductor 240 with the oxide semiconductor 230 in the opening portion 290 is improved, so that defects such as voids can be reduced.

As illustrated in FIG. 14A and FIG. 14B, the bottom portion of the conductor 260 positioned in the opening portion 290 includes a flat region. Note that the bottom portion of the conductor 260 positioned in the opening portion 290 includes no flat region in some cases depending on the maximum width of the opening portion 290 (or the maximum diameter in the case where the opening portion 290 is circular in the plan view), the thickness of the insulator 280 (corresponding to the depth of the opening portion 290), the thickness of the oxide semiconductor 230, the thickness of the insulator 250, and the like. For example, as illustrated in FIG. 14C and FIG. 14D, the shape of the bottom portion of the conductor 260 positioned in the opening portion 290 is a needle-like shape in some cases. FIG. 1A can be referred to for a plan view of the memory device illustrated in FIG. 14C and FIG. 14D.

Here, the needle-like shape refers to a shape tapering off toward the tip (at a position closer to the bottom portion of the conductor 260 positioned in the opening portion 290). Note that the needle-like tip may have an acute angle or a downward-convex curved surface shape. In addition, among the needle-like shapes, a shape whose tip has an acute angle may be referred to as a V shape.

A region of the conductor 260 positioned in the opening portion 290 that faces the oxide semiconductor 230 with the insulator 250 therebetween functions as a gate electrode. Thus, the conductor 260 that fills the opening portion 290 and has a needle-like bottom portion may be referred to as a needle-like gate. Furthermore, as illustrated in FIG. 14A and FIG. 14B, the conductor 260 whose bottom portion has a flat region may be referred to as a needle-like gate in some cases.

Although the opening portion 190 is provided such that the sidewall of the opening portion 190 is perpendicular to the top surface of the conductor 110 in FIG. 1B and FIG. 1C, the present invention is not limited thereto. For example, the opening portion 190 may have a tapered shape sidewall like the opening portion 290, or may have an inverse tapered shape sidewall.

When the sidewall of the opening portion 190 has a tapered shape, the coverage with the conductor 115, the insulator 130, or the like can be improved, so that defects such as voids can be reduced. For example, the angle subtended between the side surface of the insulator 180 in the opening portion 190 and the top surface of the conductor 110 (an angle θ2 illustrated in FIG. 14A) is preferably greater than or equal to 45° and less than 90°. Alternatively, it is preferably greater than or equal to 45° and less than or equal to 75°. Alternatively, it is preferably greater than or equal to 45° and less than or equal to 65°.

As illustrated in FIG. 14A and FIG. 14B, the bottom portion of the conductor 120 positioned in the opening portion 190 includes a flat region. In some cases, the bottom portion of the conductor 120 positioned in the opening portion 190 does not include a flat region depending on the maximum width of the opening portion 190 (the maximum diameter in the case where the opening portion 190 is circular in the plan view), the thickness of the insulator 180 (corresponding to the depth of the opening portion 190), the thickness of the conductor 115, the thickness of the insulator 130, and the like. For example, as illustrated in FIG. 14C and FIG. 14D, the shape of the bottom portion of the conductor 120 positioned in the opening portion 190 is a needle-like shape in some cases. FIG. 1A can be referred to for a plan view of the memory device illustrated in FIG. 14C and FIG. 14D.

In the case where the insulator 180 and the insulator 280 are formed using the same material, the angle θ1 and the angle θ2 are the same or substantially the same. Note that the angle θ1 and the angle θ2 may be different from each other depending on a material used for each of the insulator 180 and the insulator 280, a method for forming each of the opening portion 190 and the opening portion 290, or the like. For example, the angle θ1 may be larger than the angle θ2 or smaller than the angle θ2. One of the angle θ1 and the angle θ2 may be 90° or an approximate value thereof.

Alternatively, for example, one or both of the sidewall of the opening portion 290 and the sidewall of the opening portion 190 may have an inverse tapered shape.

Here, the inverse tapered shape refers to a shape in which a side portion or an upper portion extends beyond a bottom portion in the direction parallel to a substrate. In this case, the opening portion 290 has a frusto-conical shape. In this case, the opening portion 290 is circular in the plan view and the opening portion 290 is trapezoidal in the cross-sectional view. The area of the upper base plane of the frusto-conical shape (e.g., the opening portion provided in the conductor 240) is larger than the area of the lower base plane of the frusto-conical shape (the top surface of the conductor 120 exposed in the opening portion 290). This structure can increase the area where the oxide semiconductor 230 and the conductor 120 are in contact with each other.

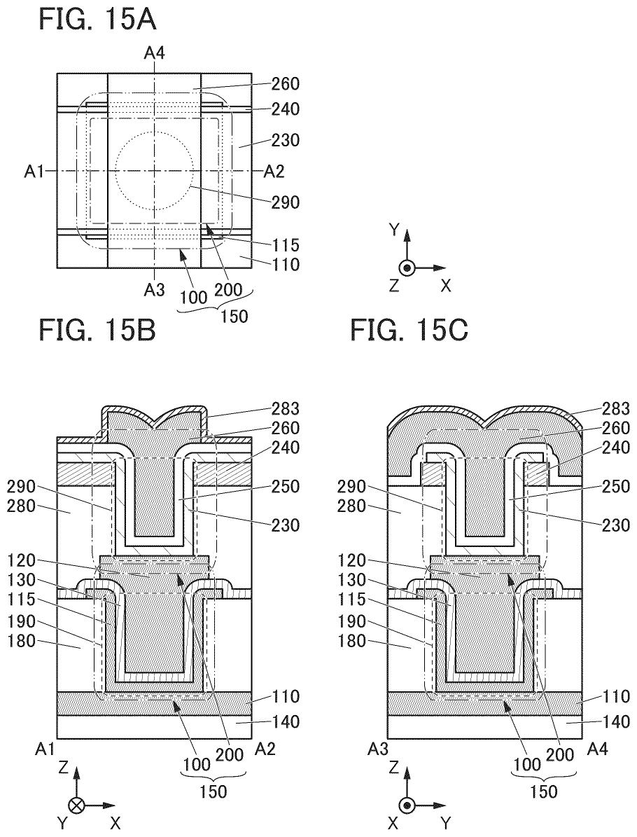

As illustrated in FIG. 1B and FIG. 1C, part of the oxide semiconductor 230 is positioned outside the opening portion 290, that is, over the conductor 240. Although FIG. 1B illustrates the structure in which the oxide semiconductor 230 is separated in the X direction, the present invention is not limited thereto. For example, as illustrated in FIG. 15A and FIG. 15B, the oxide semiconductor 230 may be provided to extend in the X direction. Also in the structure illustrated in FIG. 15A and FIG. 15B, the oxide semiconductor 230 is separated in the Y direction (see FIG. 15C).

FIG. 1C illustrates a structure in which the side end portion of the oxide semiconductor 230 is positioned inward from the side end portion of the conductor 240. Note that the present invention is not limited thereto. For example, a structure may be employed in which the side end portion of the oxide semiconductor 230 and the side end portion of the conductor 240 may be substantially aligned with each other in the Y direction. Alternatively, the side end portion of the oxide semiconductor 230 may be positioned outward from the side end portion of the conductor 240.

The band gap of the metal oxide used as the oxide semiconductor 230 is preferably greater than or equal to 2 eV, further preferably greater than or equal to 2.5 eV. With the use of a metal oxide having a wide band gap as the oxide semiconductor 230, the off-state current of the transistor can be reduced. Using the transistor having a low off-state current in the memory cell enables long-period retention of stored contents. In other words, such a memory device does not require refresh operation or has extremely low frequency of the refresh operation, which leads to a sufficient reduction in power consumption of the memory device. The frequency of refresh operation in a general DRAM is approximately once per 60 msec, whereas the frequency of refresh operation in the memory device of one embodiment of the present invention can be approximately once per 10 sec, which is greater than or equal to 10 times or greater than or equal to 100 times that of the general DRAM. In the memory device of one embodiment of the present invention, the frequency of refresh operation can be once per period of more than or equal to 1 sec and less than or equal to 100 sec, preferably once per period of more than or equal to 5 sec and less than or equal to 50 sec.

As the oxide semiconductor 230, a single layer or stacked layers of any of metal oxides described in a later-described section [Metal oxide] can be used.

As the oxide semiconductor 230, specifically, a metal oxide with a composition of In: M:Zn=1:3:2 [atomic ratio] or in the neighborhood thereof, a metal oxide with a composition of In:M:Zn=1:3:4 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:2 [atomic ratio] or in the neighborhood thereof, or a metal oxide with a composition of In:M:Zn=4:2:3 [atomic ratio] or in the neighborhood thereof may be used. Note that a composition in the neighborhood includes the range of ±30 % of an intended atomic ratio. Gallium is preferably used as the element M.

When the metal oxide is deposited by a sputtering method, the above atomic ratio is not limited to the atomic ratio of the deposited metal oxide and may be the atomic ratio of a sputtering target used for depositing the metal oxide.

As an analysis method of the composition of a metal oxide used for the oxide semiconductor 230, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, some of the analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used for forming a film of the metal oxide. In the case where the metal oxide is deposited by a sputtering method, the composition of the deposited metal oxide may be different from the composition of a sputtering target. In particular, the content percentage of zinc in the deposited metal oxide may be reduced to approximately 50% of that of the sputtering target.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide semiconductor 230, the CAAC-OS or the nc-OS is preferably used, and the CAAC-OS is particularly preferably used.

CAAC-OS preferably includes a plurality of layered crystal regions and a c-axis is preferably aligned in a normal direction of a surface where the CAAC-OS is formed. For example, the oxide semiconductor 230 preferably includes a layered crystal that is substantially parallel to the sidewall of the opening portion 290, particularly the side surface of the insulator 280. With this structure, the layered crystals of the oxide semiconductor 230 are formed substantially in parallel with the channel length direction of the transistor 200, so that the on-state current of the transistor can be increased.

The CAAC-OS is a metal oxide having a dense structure with high crystallinity and a small number of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide containing the CAAC-OS is physically stable. Therefore, the metal oxide containing the CAAC-OS is resistant to heat and has high reliability.

When an oxide having crystallinity, such as CAAC-OS, is used as the oxide semiconductor 230, oxygen extraction from the oxide semiconductor 230 by the source electrode or the drain electrode can be inhibited. This can inhibit oxygen extraction from the oxide semiconductor 230 even when heat treatment is performed; thus, the transistor 200 is stable with respect to high temperatures in a manufacturing process (what is called thermal budget).

The crystallinity of the oxide semiconductor 230 can be analyzed with X-ray diffraction (XRD), a transmission electron microscope (TEM), or electron diffraction (ED), for example. Alternatively, some of the analysis methods may be performed in combination.

Although a single layer of the oxide semiconductor 230 is illustrated in FIG. 1B and FIG. 1C, the present invention is not limited thereto. The oxide semiconductor 230 may have a stacked-layer structure of a plurality of oxide layers with different chemical compositions. For example, a structure in which a plurality of kinds of metal oxides selected from the above-described metal oxides are stacked as appropriate may be used.

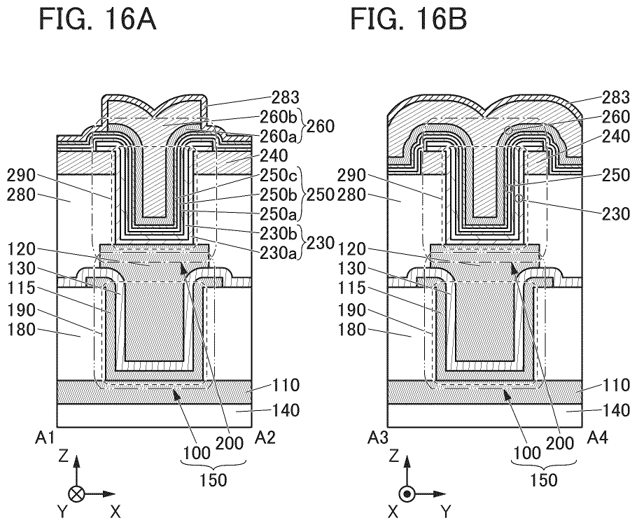

For example, as illustrated in FIG. 16A and FIG. 16B, the oxide semiconductor 230 may have a stacked-layer structure of an oxide semiconductor 230a and an oxide semiconductor 230b over the oxide semiconductor 230a.

The conductivity of a material used for the oxide semiconductor 230a is preferably different from the conductivity of a material used for the oxide semiconductor 230b.

For example, a material having higher conductivity than a material for the oxide semiconductor 230b can be used for the oxide semiconductor 230a. The use of the material having high conductivity for the oxide semiconductor 230a, which is in contact with the conductor 120 and the conductor 240 functioning as the source electrode and the drain electrode, can reduce the contact resistance between the oxide semiconductor 230 and the conductor 120 and the contact resistance between the oxide semiconductor 230 and the conductor 240, and thus the transistor can have a high on-state current.

Here, in the case where a material having high conductivity is used for the oxide semiconductor 230b provided on the side of the conductor 260 functioning as the gate electrode, the threshold voltage of the transistor is shifted and a drain current flowing when the gate voltage is 0 V (hereinafter also referred to as a cutoff current) becomes large in some cases. Specifically, the threshold voltage may be low when the transistor 200 is an n-channel transistor. Thus, a material having lower conductivity than a material for the oxide semiconductor 230a is preferably used for the oxide semiconductor 230b. Accordingly, the transistor 200 can have high threshold voltage in the case where the transistor 200 is an n-channel transistor, in which case the transistor 200 can have a low cut-off current. Note that the low cut-off current is sometimes referred to as normally-off.

When the oxide semiconductor 230 has a stacked-layer structure and the material having higher conductivity than the material for the oxide semiconductor 230b is used for the oxide semiconductor 230a as described above, the transistor can have normally-off characteristics and a high on-state current. Consequently, the memory device can have both low power consumption and high performance.

The carrier concentration of the oxide semiconductor 230a is preferably higher than the carrier concentration of the oxide semiconductor 230b. Increasing the carrier concentration of the oxide semiconductor 230a results in higher conductivity thereof, which can reduce the contact resistance between the oxide semiconductor 230 and the conductor 120 and the contact resistance between the oxide semiconductor 230 and the conductor 240, and thus the transistor can have a high on-state current. When the carrier concentration of the oxide semiconductor 230b is reduced, the conductivity is reduced, and thus the transistor can have normally-off characteristics.

Although the example in which a material having higher conductivity than a material for the oxide semiconductor 230b is used for the oxide semiconductor 230a is described here, one embodiment of the present invention is not limited to the example. A material having lower conductivity than a material for the oxide semiconductor 230b may be used for the oxide semiconductor 230a. The carrier concentration of the oxide semiconductor 230a can be lower than that of the oxide semiconductor 230b.

The band gap of a first metal oxide used for the oxide semiconductor 230a and the band gap of a second metal oxide used for the oxide semiconductor 230b are preferably different from each other. For example, a difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide semiconductor 230a can be smaller than the band gap of the second metal oxide used for the oxide semiconductor 230b. Thus, the contact resistance between the oxide semiconductor 230 and the conductor 120 and the contact resistance between the oxide semiconductor 230 and the conductor 240 can be reduced, and thus the transistor can have a high on-state current. Furthermore, the transistor 200 can have a high threshold voltage in the case where the transistor is an n-channel transistor; accordingly, the transistor 200 can be a normally-off transistor.

Although the example in which the band gap of the first metal oxide is smaller than that of the second metal oxide is described here, one embodiment of the present invention is not limited to the example. The band gap of the first metal oxide can be larger than that of the second metal oxide.

As described above, the band gap of the first metal oxide used for the oxide semiconductor 230a can be smaller than the band gap of the second metal oxide used for the oxide semiconductor 230b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second metal oxide are each an In-M-Zn oxide, the first metal oxide can have an atomic ratio of In:M:Zn=1:1:1 or a composition in the neighborhood thereof, and the second metal oxide can have an atomic ratio of In:M:Zn=1:3:2 or a composition in the neighborhood thereof. It is particularly preferable to use one or more of gallium, aluminum, and tin as the element M.

The first metal oxide may have a composition not including the element M. For example, the first metal oxide used for the oxide semiconductor 230a can be an In-Zn oxide, and the second metal oxide used for the oxide semiconductor 230b can be an In—M—Zn oxide. Specifically, the first metal oxide can be an In—Zn oxide, and the second metal oxide can be an In—Ga—Zn oxide. More specifically, the first metal oxide can have an atomic ratio of In:Zn=1:1 or a composition in the neighborhood thereof or an atomic ratio of In:Zn=4:1 or a composition in the neighborhood thereof and the second metal oxide can have an atomic ratio of In:Ga:Zn=1:1:1 or a composition in the neighborhood thereof.

Although the example in which the content percentage of the element M in the first metal oxide is lower than that of the element M in the second metal oxide is described here, one embodiment of the present invention is not limited to the example. The content percentage of the element M in the first metal oxide may be higher than that of the element M in the second metal oxide. As long as the compositions of the first metal oxide and the second metal oxide are different from each other, the content percentages of elements other than the element M may be different from each other.

The thickness of the oxide semiconductor 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thicknesses of the layers included in the oxide semiconductor 230 (here, the oxide semiconductor 230a and the oxide semiconductor 230b) are determined such that the thickness of the oxide semiconductor 230 is within the above-described range. The thickness of the oxide semiconductor 230a can be determined such that the contact resistance between the oxide semiconductor 230a and the conductor 120 and the contact resistance between the oxide semiconductor 230a and the conductor 240 are within required ranges. The thickness of the oxide semiconductor 230b can be determined such that the threshold voltage of the transistor is within a required range. Note that the thickness of the oxide semiconductor 230a may be the same as or different from the thickness of the oxide semiconductor 230b.

Although FIG. 16A and FIG. 16B illustrate the structure in which the oxide semiconductor 230 has a stacked-layer structure of two layers, the oxide semiconductor 230a and the oxide semiconductor 230b, the present invention is not limited to the structure. The metal the oxide semiconductor 230 may have a stacked-layer structure of three or more layers.

In the case where the oxide semiconductor 230 has a three-layer structure, the oxide semiconductor 230 may have a structure in which a metal oxide with a composition of In:Ga:Zn=1:1:1 [atomic ratio] or in the neighborhood thereof, a metal oxide with a composition of In:Zn=1:1 [atomic ratio] or in the neighborhood thereof or with a composition of In:Zn=4:1 [atomic ratio] or in the neighborhood thereof, and a metal oxide with a composition of In:Ga:Zn=1:1:1 [atomic ratio] or in the neighborhood thereof are provided in order from the conductor 120 side. With this structure, the on-state current of the transistor 200 can be increased, and the transistor can have high reliability with small variations.

As the insulator 250, a single layer or stacked layers of any of insulators described in the later-described section [Insulator] can be used. For example, an insulator that easily transmits oxygen is preferably used as the insulator 250. With such a structure, oxygen contained in the insulator 280 can be supplied to the region 230i through the insulator 250. An insulator containing excess oxygen may also be used as the insulator 250. With such a structure, oxygen contained in the insulator 250 can be supplied to the region 230i. For the insulator 250, silicon oxide or silicon oxynitride can be used, for example. Silicon oxide and silicon oxynitride, which are thermally stable, are preferable.

As the insulator 250, any of materials each having high relative permittivity, that is, high-k materials, described in the later-described section [Insulator] may be used. For example, hafnium oxide, aluminum oxide, or the like may be used.

The thickness of the insulator 250 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulator 250 preferably has a region with the above-described thickness.

The concentration of impurities such as water and hydrogen in the insulator 250 is preferably reduced. This can inhibit entry of impurities such as water and hydrogen into the channel formation region of the oxide semiconductor 230.

As illustrated in FIG. 1B and FIG. 1C, part of the insulator 250 is positioned outside the opening portion 290, that is, over the conductor 240 and the insulator 280. In this case, the insulator 250 preferably covers the side end portion of the oxide semiconductor 230. This can prevent a short circuit between the conductor 260 and the oxide semiconductor 230. The insulator 250 preferably covers the side end portion of the conductor 240. This can prevent a short circuit between the conductor 260 and the conductor 240.

Although the insulator 250 has a single layer in FIG. 1B and FIG. 1C, the present invention is not limited thereto. The insulator 250 may have a stacked-layer structure.

For example, as illustrated in FIG. 16A and FIG. 16B, the insulator 250 may have a stacked-layer structure of an insulator 250a, an insulator 250b over the insulator 250a, and an insulator 250c over the insulator 250b.

For the insulator 250b, any of materials each having low relative permittivity described in the later-described section [Insulator] is preferably used. In particular, silicon oxide and silicon oxynitride, which are thermally stable, are preferable. The insulator 250b in this case contains at least oxygen and silicon. With such a structure, parasitic capacitance between the conductor 260 and the conductor 240 can be reduced. Furthermore, the concentration of impurities such as water and hydrogen in the insulator 250b is preferably reduced.

For the insulator 250a, any of insulators having a barrier property against oxygen described in the later-described section [Insulator] is preferably used. The insulator 250a includes a region in contact with the oxide semiconductor 230. When the insulator 250a has a barrier property against oxygen, release of oxygen from the oxide semiconductor 230 at the time of performing heat treatment or the like can be inhibited. This can inhibit formation of oxygen vacancies in the oxide semiconductor 230. Accordingly, the transistor 200 can have favorable electrical characteristics and higher reliability. As the insulator 250a, aluminum oxide is preferably used, for instance. In this case, the insulator 250a contains at least oxygen and aluminum.

For the insulator 250c, any of insulators having a barrier property against hydrogen described in the later-described section [Insulator] is preferably used. In that case, diffusion of impurities contained in the conductor 260 into the oxide semiconductor 230 can be inhibited. In particular, silicon nitride is suitably used for the insulator 250c because of its high hydrogen barrier property. In this case, the insulator 250c contains at least nitrogen and silicon.

The insulator 250c may further have a barrier property against oxygen. The insulator 250c is provided between the insulator 250b and the conductor 260. Thus, diffusion of oxygen contained in the insulator 250b into the conductor 260 can be prevented, so that oxidation of the conductor 260 can be inhibited. A reduction in the amount of oxygen supplied to the region 230i can be inhibited.

An insulator may be provided between the insulator 250b and the insulator 250c. For the insulator, any of insulators having a function of capturing or fixing hydrogen described in the later-described section [Insulator] is preferably used. With the insulator, hydrogen contained in the oxide semiconductor 230 can be captured or fixed more effectively. Thus, the hydrogen concentration in the oxide semiconductor 230 can be lowered. As the insulator, for example, hafnium oxide is preferably used. In this case, the above insulator contains at least oxygen and hafnium. Alternatively, the insulator may have an amorphous structure.

The thicknesses of the insulator 250a to the insulator 250c are preferably small for miniaturization of the transistor 200, and are preferably within the above-described ranges. Typically, the thicknesses of the insulator 250a, the insulator 250b, the insulator having a function of capturing or fixing hydrogen, and the insulator 250c are 1 nm, 2 nm, 2 nm, and 1 nm, respectively. This structure enables the transistor 200 to have favorable electrical characteristics even when the transistor 200 is miniaturized or highly integrated.

Although FIG. 16A and FIG. 16B illustrate the structure in which the insulator 250 has a stacked-layer structure of three layers, the insulator 250a to the insulator 250c, the present invention is not limited thereto. The insulator 250 may have a stacked-layer structure of two layers or four or more layers. In that case, the layers included in the insulator 250 are preferably selected as appropriate from the insulator 250a to the insulator 250c and the insulator having a function of capturing or fixing hydrogen.

As the conductor 260, a single layer or stacked layers of any of conductors described in the later-described section [Conductor] can be used. For example, a conductive material with high conductivity such as tungsten can be used for the conductor 260, for example.

In addition, a conductive material that is less likely to be oxidized, a conductive material having a function of inhibiting diffusion of oxygen, or the like is preferably used as the conductor 260. Examples of the conductive material include a conductive material containing nitrogen (e.g., titanium nitride or tantalum nitride) and a conductive material containing oxygen (e.g., ruthenium oxide). This can inhibit a decrease in the conductivity of the conductor 260.

Although FIG. 1B and FIG. 1C illustrates the conductor 260 having the single-layer structure, the present invention is not limited thereto. The conductor 260 may have a stacked-layer structure. For example, as illustrated in FIG. 16A and FIG. 16B, the conductor 260 may have a stacked-layer structure of a conductor 260a and a conductor 260b over the conductor 260a. In this case, titanium nitride may be used as the conductor 260a, and tungsten may be used as the conductor 260b, for example. When tungsten is stacked in this manner, the conductivity of the conductor 260 can be improved and can serve well as the wiring WL.

Although FIG. 16A and FIG. 16B illustrate the structure in which the conductor 260 has the stacked-layer structure of two layers of the conductor 260a and the conductor 260b, the present invention is not limited to the structure. The conductor 260 may have a stacked-layer structure of three or more layers.

Although the conductor 260 is provided to fill the opening portion 290 in FIG. 1B and FIG. 1C, the present invention is not limited thereto. For example, a depressed portion reflecting the shape of the opening portion 290 is formed in a center portion of the conductor 260 and part of the depressed portion is positioned in the opening portion 290 in some cases. In this case, the depressed portion may be filled with an inorganic insulating material or the like.

As illustrated in FIG. 1B and FIG. 1C, part of the conductor 260 is positioned outside the opening portion 290, that is, over the conductor 240 and the insulator 280. In this case, the side end portion of the conductor 260 is preferably positioned inward from the side end portion of the oxide semiconductor 230 as illustrated in FIG. 1B. This can prevent a short circuit between the conductor 260 and the oxide semiconductor 230. The side end portion of the conductor 260 may be aligned with the side end portion of the oxide semiconductor 230 or positioned outward from the side end portion of the oxide semiconductor 230.

The conductor 120 can be provided as described in the section [Capacitor 100].

Although FIG. 1B and FIG. 1C illustrate a structure in which the top surface of the conductor 120 is flat, the present invention is not limited to the structure. For example, a depressed portion overlapping with the opening portion 290 may be formed in the top surface of the conductor 120. When at least parts of the oxide semiconductor 230, the insulator 250, and the conductor 260 are formed to fill the depressed portion, the gate electric field of the conductor 260 can be easily applied to a portion of the oxide semiconductor 230 close to the conductor 120.

As the conductor 240, a single layer or stacked layers of any of conductors described in the later-described section [Conductor] can be used. Moreover, a conductive material with high conductivity such as tungsten can be used for the conductor 240, for example.

A conductive material that is less likely to be oxidized, a conductive material having a function of inhibiting diffusion of oxygen, or the like is preferably used for the conductor 240 like the conductor 260. For example, titanium nitride, tantalum nitride, or the like can be used. Such a structure can reduce excessive oxidation of the conductor 240 due to the oxide semiconductor 230.

In addition, a structure in which tungsten is stacked over titanium nitride may be used, for example. When tungsten is stacked in this manner, the conductivity of the conductor 240 can be improved and can serve well as the wiring BL.

In the case where the conductor 240 has a structure where a first conductor and a second conductor are stacked, the first conductor may be formed using a conductive material with high conductivity and the second conductor may be formed using a conductive material containing oxygen, for example. When a conductive material containing oxygen is used as the second conductor of the conductor 240 that is in contact with the insulator 250, oxygen in the insulator 250 can be inhibited from diffusing into the first conductor of the conductor 240. For example, tungsten is preferably used as the first conductor of the conductor 240, and indium tin oxide to which silicon is added is preferably used as the second conductor of the conductor 240.

The insulator 140 and the insulator 280 function as interlayer films and thus preferably have low relative permittivity. When a material with low relative permittivity is used for an interlayer film, parasitic capacitance generated between wirings can be reduced. As the insulator 140 and the insulator 280, a single layer or stacked layers of any of insulators each containing a material with low relative permittivity described in the later-described section [Insulator] can be used. In particular, silicon oxide and silicon oxynitride are preferable because they are thermally stable.

The concentration of impurities such as water and hydrogen in the insulator 140 and the insulator 280 is preferably reduced. This can inhibit entry of impurities such as water and hydrogen into the channel formation region of the oxide semiconductor 230.

As the insulator 280 placed in the vicinity of the channel formation region, an insulator containing excess oxygen is preferably used. By performing heat treatment on the insulator 280 containing excess oxygen, oxygen can be supplied from the insulator 280 to the channel formation region of the oxide semiconductor 230 and oxygen vacancies and VoH can be reduced. Thus, the transistor 200 can have stable electrical characteristics and increased reliability.

As the insulator 280, any of insulators having a function of capturing or fixing hydrogen described in the later-described [Insulator] may be used. With this structure, hydrogen in the oxide semiconductor 230 can be captured or fixed, so that the concentration of hydrogen in the oxide semiconductor 230 can be reduced. For the insulator 280, magnesium oxide, aluminum oxide, or the like can be used.

Although FIG. 1B and FIG. 1C show a single-layer of the insulator 280, the present invention is not limited thereto. The insulator 280 may have a stacked-layer structure.

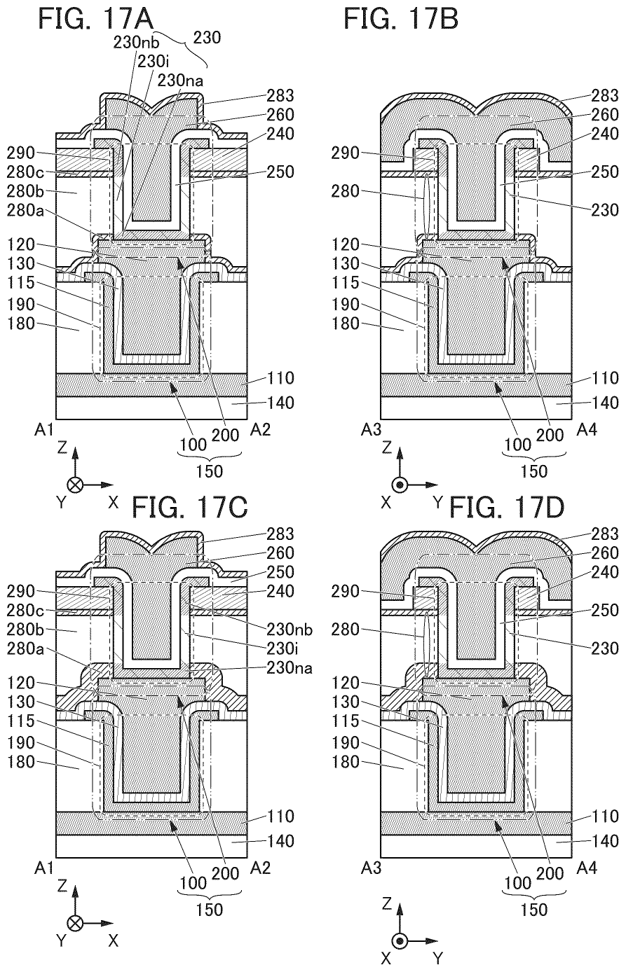

For example, as illustrated in FIG. 17A and FIG. 17B, the insulator 280 may have a stacked-layer structure of an insulator 280a, an insulator 280b over the insulator 280a, and an insulator 280c over the insulator 280b.

An insulator containing oxygen is preferably used as the insulator 280b. The insulator 280b preferably includes a region having a higher oxygen content than at least one of the insulator 280a and the insulator 280c. In particular, the insulator 280b preferably includes a region having a higher oxygen content than each of the insulator 280a and the insulator 280c. When the oxygen content of the insulator 280b is increased, an i-type region can be easily formed in a region of the oxide semiconductor 230 that is in contact with the insulator 280b and in the vicinity of the region.

It is further preferable that a film from which oxygen is released by heating be used as the insulator 280b. When the insulator 280b releases oxygen by being heated during the manufacturing process of the transistor 200, the oxygen can be supplied to the oxide semiconductor 230. Supply of oxygen from the insulator 280b to the oxide semiconductor 230, particularly to the channel formation region of the oxide semiconductor 230, can reduce oxygen vacancies and VoH in the oxide semiconductor 230, so that the transistor can have favorable electrical characteristics and high reliability.

For example, the insulator 280b can be supplied with oxygen when heat treatment in an oxygen-containing atmosphere or plasma treatment in an oxygen-containing atmosphere is performed. Alternatively, an oxide film may be deposited over the top surface of the insulator 280b by a sputtering method in an oxygen atmosphere to supply oxygen. After that, the oxide film may be removed.

The insulator 280b is preferably formed by a deposition method such as a sputtering method or a plasma-enhanced chemical vapor deposition (PECVD) method. In particular, a film is deposited by a sputtering method as a deposition method that does not use a hydrogen gas as a deposition gas, so that a film with an extremely low hydrogen content can be formed. Thus, supply of hydrogen to the oxide semiconductor 230 is inhibited and the electrical characteristics of the transistor 200 can be stabilized.

In the case where the channel length of the transistor 200 is short, oxygen vacancies and VoH in the channel formation region greatly affect electrical characteristics and reliability. Supplying oxygen from the insulator 280b to the oxide semiconductor 230 can inhibit oxygen vacancies and VoH from increasing at least in a region of the oxide semiconductor 230 that is in contact with the insulator 280b. Accordingly, the transistor with a short channel length can have favorable electrical characteristics and high reliability.

For each of the insulator 280a and the insulator 280c, any of the insulators having a barrier property against oxygen described in the later-described section [Insulator] is preferably used. Accordingly, oxygen contained in the insulator 280b can be inhibited from diffusing to the substrate side through the insulator 280a and to the insulator 250 side through the insulator 280c by heating. In other words, when the insulator 280b is sandwiched between the insulator 280a and the insulator 280c that do not easily allow diffusion of oxygen, from the upper and lower sides, oxygen contained in the insulator 280b can be enclosed. Thus, oxygen can be effectively supplied to the oxide semiconductor 230.

In the case of using an insulator having a barrier property against oxygen as the insulator 280c, the amount of oxygen supplied from the insulator 280 to a region of the oxide semiconductor 230 that is in contact with the insulator 250 through the insulator 250 is reduced when heat treatment or the like is performed. At this time, as illustrated in FIG. 17A and FIG. 17B, the region 230na and the region 230nb extend toward the insulator 250 in some cases.

The conductor 120 and the conductor 240 are oxidized by oxygen contained in the insulator 280b and have high resistance in some cases. Providing the insulator 280a between the insulator 280b and the conductor 120 can inhibit the conductor 120 from being oxidized and having high resistance. Furthermore, providing the insulator 280c between the insulator 280b and the conductor 240 can inhibit the conductor 240 from being oxidized and having high resistance. Along with this, the amount of oxygen supplied from the insulator 280b to the oxide semiconductor 230 is increased, so that oxygen vacancies in the oxide semiconductor 230 can be reduced.

A region of the oxide semiconductor 230 that is in contact with the insulator 280a and a region of the oxide semiconductor 230 that is in contact with the insulator 280c are supplied with a smaller amount of oxygen than a region of the oxide semiconductor 230 that is in contact with the insulator 280b. Thus, the region of the oxide semiconductor 230 that is in contact with the insulator 280a and the region of the oxide semiconductor 230 that is in contact with the insulator 280c each have a low resistance in some cases. That is, by adjusting the thickness of the insulator 280a, the range of the region 230na functioning as one of the source region and the drain region can be controlled. Similarly, by adjusting the thickness of the insulator 280c, the range of the region 230nb functioning as the other of the source region and the drain region can be controlled.

As described above, the source region and the drain region are controlled by the thicknesses of the insulator 280a and the insulator 280c; thus, the thicknesses of the insulator 280a and the insulator 280c can be set as appropriate in accordance with characteristics required for the transistor 200.

For example, as illustrated in FIG. 17A and FIG. 17B, the thickness of the insulator 280c and the thickness of the insulator 280a may be equal or substantially equal to each other. Alternatively, as illustrated in FIG. 17C and FIG. 17D, the thickness of the insulator 280a may be larger than that of the insulator 280c, for example. With the structure illustrated in FIG. 17C and FIG. 17D, the region 230na can be closer to the bottom portion of the conductor 260 in the opening portion 290. This structure can be regarded as a structure in which the area of the region 230i is narrowed. Thus, the on-state current of the transistor 200 can be increased.

Although FIG. 17C and FIG. 17D illustrate the structure in which the insulator 280c is provided over the planarized insulator 280b, the present invention is not limited to the structure. For example, the insulator 280c may be formed without performing planarization treatment on the insulator 280b. By not performing planarization treatment, manufacturing cost can be reduced and production yield can be increased. The insulator 280a, the insulator 280b, and the insulator 280c can be successively formed without exposure to the air. By the formation without exposure to the air, impurities or moisture from the atmospheric environment can be prevented from being attached onto the insulator 280a to the insulator 280c, so that the vicinity of the interface between the insulator 280a and the insulator 280b and the vicinity of the interface between the insulator 280b and the insulator 280c can be kept clean.

For each of the insulator 280a and the insulator 280c, any of insulators having a barrier property against hydrogen described in the later-described section [Insulator] is preferably used. Thus, hydrogen can be inhibited from diffusing from outside the transistor to the oxide semiconductor 230 through the insulator 280a or the insulator 280c. A silicon nitride film and a silicon nitride oxide film can be suitably used for the insulator 280a and the insulator 280c because the silicon nitride film and the silicon nitride oxide film release fewer impurities (e.g., water and hydrogen) and are less likely to transmit oxygen and hydrogen. For the insulator 280a and the insulator 280c, the same material or different materials may be used.

For the insulator 280a, any of insulators having a function of capturing or fixing hydrogen described in the later-described [Insulator] is preferably used. With this structure, diffusion of hydrogen into the oxide semiconductor 230 from below the insulator 280a can be inhibited, and hydrogen in the oxide semiconductor 230 can be captured or fixed, whereby the hydrogen concentration in the oxide semiconductor 230 can be reduced. Furthermore, diffusion of hydrogen into the insulator 130 from above the insulator 280a can be inhibited, and hydrogen in the insulator 130 can be captured or fixed, so that the hydrogen concentration in the insulator 130 can be reduced. For the insulator 280a, magnesium oxide, aluminum oxide, hafnium oxide, or the like can be used. Alternatively, for example, a stacked-layer film of aluminum oxide and silicon nitride over the aluminum oxide may be used as the insulator 280a.

The thickness of the insulator 280a is preferably smaller than the thickness of the insulator 280b. The thickness of the insulator 280c is preferably smaller than the thickness of the insulator 280b. The thicknesses of the insulator 280a and the insulator 280c are each preferably greater than or equal to 1 nm and less than or equal to 15 nm, further preferably greater than or equal to 2 nm and less than or equal to 10 nm, still further preferably greater than or equal to 3 nm and less than or equal to 7 nm, yet still further preferably greater than or equal to 3 nm and less than or equal to 5 nm. The thickness of the insulator 280b is preferably greater than or equal to 3 nm and less than or equal to 30 nm, further preferably greater than or equal to 5 nm and less than or equal to 20 nm, still further preferably greater than or equal to 7 nm and less than or equal to 15 nm. When the thicknesses of the insulator 280a to the insulator 280c are within any of the above ranges, oxygen vacancies in the oxide semiconductor 230, especially in the channel formation region, can be reduced.

For example, it is preferable that silicon nitride be used for the insulator 280a and the insulator 280c, and silicon oxide be used for the insulator 280b. In that case, each of the insulator 280a and the insulator 280c contains at least silicon and nitrogen. The insulator 280b contains at least silicon and oxygen.

Although FIG. 17A and FIG. 17B illustrate the structure in which the insulator 280 has a stacked-layer structure of three layers, one embodiment of the present invention is not limited to the structure. The insulator 280 may have a stacked-layer structure of two layers or four or more layers.

As the insulator 283, any of the insulators having a barrier property against hydrogen described in the later-described section [Insulator] is preferably used. In that case, hydrogen can be inhibited from being diffused from outside of the transistor to the oxide semiconductor 230 through the insulator 250. A silicon nitride film and a silicon nitride oxide film can be suitably used for the insulator 283 because the silicon nitride film and the silicon nitride oxide film release fewer impurities (e.g., water and hydrogen) and are less likely to transmit oxygen and hydrogen.

For the insulator 283, any of the insulators having a function of capturing or fixing hydrogen described in the later-described [Insulator] is preferably used. With this structure, diffusion of hydrogen into the oxide semiconductor 230 from above the insulator 283 can be inhibited, and hydrogen in the oxide semiconductor 230 can be captured or fixed, whereby the hydrogen concentration in the oxide semiconductor 230 can be reduced. As the insulator 283, magnesium oxide, aluminum oxide, hafnium oxide, or the like can be used. Alternatively, for example, a stacked-layer film of aluminum oxide and silicon nitride over the aluminum oxide may be used as the insulator 283.

Although FIG. 1B and FIG. 1C illustrate a structure including a region where the top surface of the conductor 120 and the bottom surface of the oxide semiconductor 230 are in contact with each other, the present invention is not limited thereto. For example, a conductor may be provided between the conductor 120 and the oxide semiconductor 230.

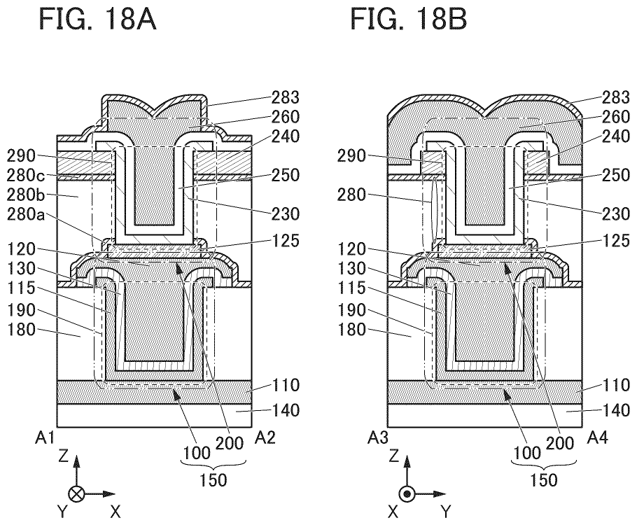

For example, as illustrated in FIG. 18A and FIG. 18B, a structure may be employed in which the conductor 125 is provided between the conductor 120 and the oxide semiconductor 230. As the conductor 125, any of conductive materials containing oxygen described in the later-described section [Conductor] is preferably used. When a conductive material containing oxygen is used as the conductor 125, the conductor 125 can maintain its conductivity even when absorbing oxygen. In addition, diffusion of oxygen in the oxide semiconductor 230 into the conductor 120 can be inhibited. As the conductor 125, a single layer or stacked layers of indium tin oxide, indium tin oxide to which silicon is added, indium zinc oxide, or the like can be used, for example.

In addition, as illustrated in FIG. 18A and FIG. 18B, a structure may be employed in which the side end portion of the insulator 130 and the side end portion of the conductor 115 are aligned with each other. This structure enables the insulator 130 and the conductor 115 to be formed using the same mask, so that the manufacturing process of the memory device can be simplified.

FIG. 1B and FIG. 1C illustrate a structure in which the oxide semiconductor 230 includes a region in contact with the side surface of the conductor 240 in the opening portion 290 and a region in contact with part of the top surface of the conductor 240. Note that the present invention is not limited thereto.

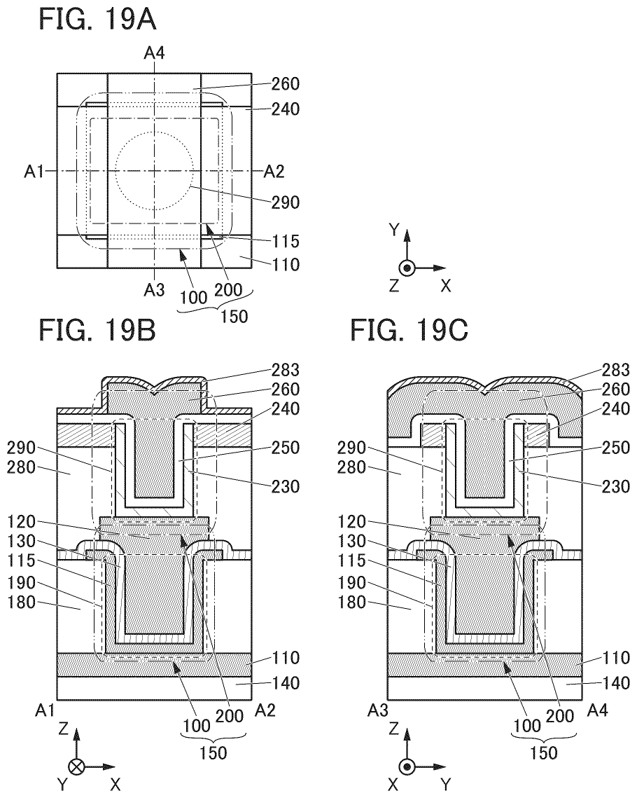

For example, as illustrated in FIG. 19B and FIG. 19C, the oxide semiconductor 230 may include a region in contact with the conductor 240 in the opening portion 290. In this case, the top surface of the oxide semiconductor 230 is level with the top surface of the conductor 240. With such a structure, the distance between the side end portion of the conductor 240 in the Y direction and the interface between the conductor 240 and the oxide semiconductor 230 in the opening portion 290 can be made small. Thus, the width of the conductor 240 in the Y direction can be small, and the interval at which the conductors 240 are placed can be small. Thus, miniaturization and high integration of the memory device can be achieved. Note that FIG. 19A is a plan view of the memory device illustrated in FIG. 19B and FIG. 19C.

FIG. 1B and FIG. 1C illustrate a structure in which the conductor 240 is provided over the insulator 280. In addition, a region of the insulator 250 that does not overlap with the conductor 240 includes a region in contact with the top surface of the insulator 280. Note that the present invention is not limited thereto.

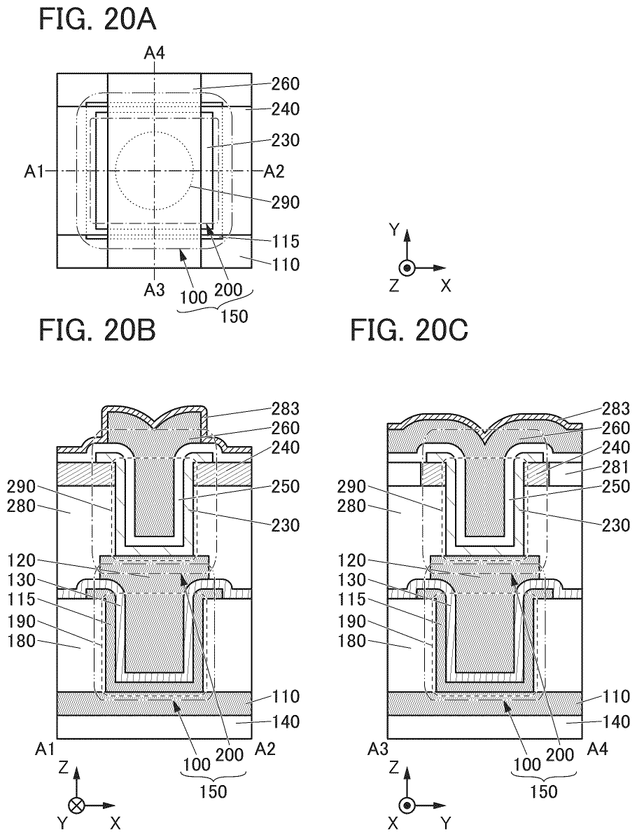

For example, as illustrated in FIG. 20B and FIG. 20C, an insulator 281 may be provided over the insulator 280, and the conductor 240 may be provided to be embedded in the insulator 281. In that case, the top surface of the conductor 240 and the top surface of the insulator 281 are preferably level with each other. With such a structure, the physical distance from the conductor 260 to the conductor 240 (specifically, the side end portion of the conductor 240) can be increased, so that a short circuit between the conductor 260 and the conductor 240 can be prevented. Note that FIG. 20A is a plan view of the memory device illustrated in FIG. 20B and FIG. 20C.

The insulator 281 functions as an interlayer film and thus is preferably formed using a material having low relative permittivity. When a material with low relative permittivity is used for an interlayer film, parasitic capacitance generated between wirings can be reduced. As the insulator 281, a single layer or stacked layers of any of insulators each including a material with low relative permittivity described in the later-described section [Insulator] can be used.

Note that as illustrated in FIG. 1A and FIG. 1C, the conductor 260 is extended to function as a wiring as well. The conductor 260 is shared by a plurality of transistors. However, without limitation to this, a structure in which a conductor functioning as a wiring is provided above the conductor 260 may be employed.

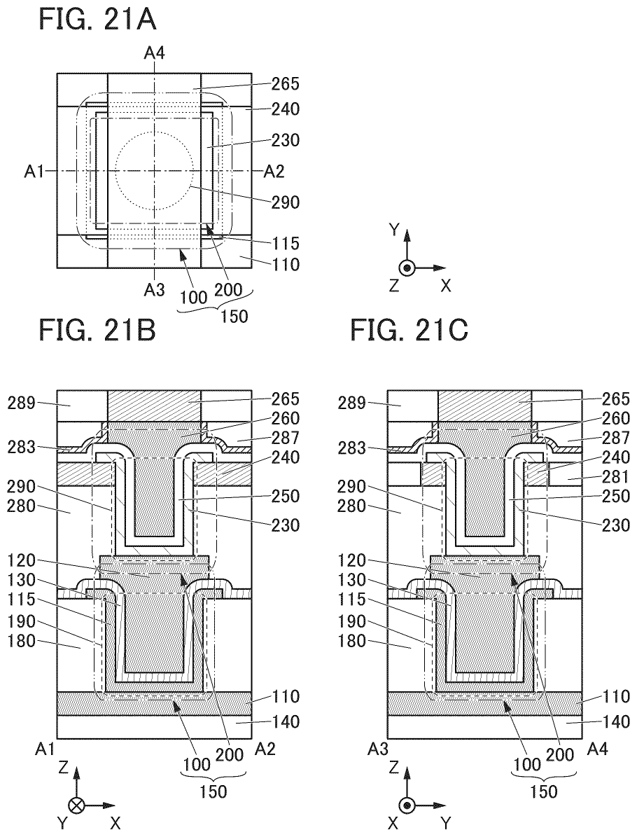

For example, as illustrated in FIG. 21A to FIG. 21C, a conductor 265 may be provided over the conductor 260. Note that in FIG. 21A to FIG. 21C, the conductor 260 is provided in each transistor. Note that the conductor 260 is not necessarily provided in each transistor. The conductor 260 may be shared by a plurality of transistors, for example.

In the above structure, the conductor 260 is preferably provided to be embedded in an insulator 287. In that case, the top surface of the conductor 260 and the top surface of the insulator 287 are preferably level with each other. This structure can prevent a short circuit between the conductor 260 and the conductor 240.

The conductor 265 functions as the wiring WL electrically connected to a gate of the transistor 200. As the conductor 265, a single layer or stacked layers of any of the conductors described in the above-described section [Conductor] can be used. For example, a conductive material with high conductivity such as tungsten can be used for the conductor 265, for example.

The conductor 265 is preferably provided to be embedded in the insulator 289. In that case, the top surface of the conductor 265 and the top surface of the insulator 289 are preferably level with each other.

The insulator 287 and the insulator 289 function as interlayer films and thus are preferably formed using materials with low relative permittivity. When a material with low relative permittivity is used for an interlayer film, parasitic capacitance generated between wirings can be reduced. As the insulator 287 and the insulator 289, a single layer or stacked layers of insulators containing any of the materials with low relative permittivity described in the above-described section [Insulator] can be used.

Although the side end portion of the conductor 265 is aligned with the side end portion of the conductor 260 in FIG. 21B, the present invention is not limited thereto. For example, the side end portion of the conductor 265 may be positioned outward from the side end portion of the conductor 260 or inward from the side end portion of the conductor 260.

### <Component Material of Memory Device>

Component materials that can be used for the memory device are described below.

### [Substrate]

As a substrate where the transistor 200 and the capacitor 100 are formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate containing silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a material with low relative permittivity is used for the insulator functioning as an interlayer film, parasitic capacitance generated between wirings can be reduced. Thus, a material is preferably selected in accordance with the function of the insulator. Note that the material with low relative permittivity is a material with high dielectric strength.

Examples of the material with high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with low relative permittivity include silicon oxide to which fluorine is added, silicon oxide to which carbon is added, and silicon oxide to which carbon and nitrogen are added. Another example is porous silicon oxide. These silicon oxides may contain nitrogen.

When a transistor including a metal oxide is surrounded by an insulator having a function of inhibiting passage of oxygen and impurities, the transistor can have stable electrical characteristics. As the insulator having a function of inhibiting passage of oxygen and impurities, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of oxygen and impurities, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor layer or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, oxygen vacancies in the semiconductor layer can be reduced. Examples of an insulator in which a region containing excess oxygen is easily formed include silicon oxide, silicon oxynitride, and porous silicon oxide.

Examples of an insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of an insulator having a barrier property against hydrogen include aluminum oxide, magnesium oxide, hafnium oxide, gallium oxide, indium gallium zinc oxide, silicon nitride, and silicon nitride oxide.

An insulator having a barrier property against oxygen and an insulator having a barrier property against hydrogen can each be regarded as an insulator having a barrier property against one or both of oxygen and hydrogen.

Examples of the insulator having a function of capturing or fixing hydrogen include an oxide containing magnesium and an oxide containing one or both of aluminum and hafnium. These oxides preferably have an amorphous structure. In such an oxide having an amorphous structure, an oxygen atom has a dangling bond and sometimes has a property of capturing or fixing hydrogen with the dangling bond. Note that such a metal oxide preferably has an amorphous structure, but may include a crystal region that is partly formed.

In this specification and the like, a barrier insulating film refers to an insulating film having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Moreover, a function of capturing or fixing (also referred to as gettering) a target substance can be rephrased as a barrier property. In addition, hydrogen described as a target substance refers to at least one of a hydrogen atom, a hydrogen molecule, and a substance bonded to hydrogen, such as a water molecule or OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom, an oxygen molecule, and the like. Specifically, a barrier property against oxygen refers to a property that does not easily allow diffusion of at least one of an oxygen atom, an oxygen molecule, and the like.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may also be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide sometimes includes a lattice defect. Examples of a lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor may cause unstable electrical characteristics of the transistor. Hence, a metal oxide used in a semiconductor layer of a transistor preferably has a small number of lattice defects.

A transistor using a metal oxide is likely to change its electrical characteristics especially in the case where oxygen vacancies (Vo) and impurities are present in a region of the metal oxide where a channel is formed, which may degrade the reliability in some cases. In some cases, a defect (VoH) that is an oxygen vacancy into which hydrogen in the vicinity of the oxygen vacancy has entered is formed, which generates an electron serving as a carrier. Thus, when the channel formation region in the metal oxide includes oxygen vacancies, the transistor is likely to have normally-on characteristics. Therefore, oxygen vacancies and impurities are preferably reduced as much as possible in the channel formation region in the metal oxide. In other words, it is preferable that the channel formation region in the metal oxide have a reduced carrier concentration and be of an i-type (intrinsic) or substantially i-type.

The kind of a lattice defect that is likely to be present in a metal oxide and the number of lattice defects that are present there vary depending on the structure of the metal oxide, a method for forming the metal oxide, or the like.

The structure of a metal oxide is classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, a transistor with high reliability can be achieved.

For the channel formation region of a transistor, a metal oxide that increases the on-state current of the transistor is preferably used. To increase the on-state current of the transistor, the carrier mobility of the metal oxide used for the transistor is increased. To increase the carrier mobility of the metal oxide, the transfer of carriers (electrons in the case of an n-channel transistor) needs to be facilitated or scattering factors that affect the carrier transfer need to be reduced. The carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS.

The c-axis of the above crystal is preferably aligned in the normal direction with respect to the surface over which the metal oxide is formed or the film surface of the metal oxide. This enables the plurality of layers to be placed parallel or substantially parallel to the surface over which the metal oxide is formed or the film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valences of the one or plurality of metal elements contained in the first layer are preferably equal to the valences of the one or plurality of metal elements contained in the second layer. The first layer and the second layer may contain the same metal element. The valences of the one or plurality of metal elements contained in the first layer are preferably different from the valences of the one or plurality of metal elements contained in the third layer.

The above structure can increase the crystallinity of the metal oxide, which leads to an increase in the carrier mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M contained in the metal oxide is gallium, the metal oxide in one embodiment of the present invention preferably contains one or more selected from indium, gallium, and zinc. In this specification and the like, a metal element and a metalloid element may be collectively referred to as a “metal element”, and a “metal element” in this specification and the like may include a metalloid element.

For example, for the metal oxide semiconductor of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table of the elements. Alternatively, the metal oxide may contain, in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Incidentally, lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, atomic layers are preferably deposited one by one. Since an ALD method is employed as the deposition method of the metal oxide in one embodiment of the present invention, a metal oxide having the layered crystal structure is easily formed.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. The use of plasma in a PEALD method is sometimes preferable because it enables deposition at a lower temperature. Note that a precursor used in an ALD method sometimes contains an element such as carbon or chlorine. Thus, in some cases, a film provided by an ALD method contains a larger amount of an element such as carbon or chlorine than a film provided by another formation method. Note that these elements can be quantified by XPS or secondary ion mass spectrometry (SIMS). The formation method of the metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a deposition method in which particles ejected from a target or the like are deposited, an ALD method is a deposition method in which a film is formed by reaction at a surface of an object. Thus, the ALD method is a deposition method that enables good step coverage almost regardless of the shape of an object to be processed. In particular, an ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as a sputtering method or a CVD method, in some cases. A method in which a sputtering method is used to deposit the first metal oxide and an ALD method is used to deposit the second metal oxide over the first metal oxide is given as an example. For example, in the case where the first metal oxide has a crystal part, crystal growth occurs in the second metal oxide with the use of the crystal part as a nucleus.

When an ALD method is employed, the composition of a film to be formed can be controlled with the amount of introduced source gases. For example, a film with an arbitrary composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film having a continuously-changed composition can be deposited. In the case where the film is deposited while the source gas is changed, as compared to the case where a film is deposited using a plurality of deposition chambers, the time taken for the deposition can be shortened because the time taken for transfer and pressure adjustment is omitted. Thus, the productivity of the memory device can be increased in some cases.

### [[Transistor Including Metal Oxide]]

Next, the case where a metal oxide (oxide semiconductor) is used for a transistor will be described. Hereinafter, a transistor with a semiconductor layer of an oxide semiconductor is sometimes referred to as an OS transistor, and a transistor with a semiconductor layer of silicon is sometimes referred to as a Si transistor.

When the metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length of greater than or equal to 2 nm and less than or equal to 30 nm can be manufactured.

An oxide semiconductor having a low carrier concentration is preferably used for a channel formation region of a transistor. For example, the carrier concentration in an oxide semiconductor in the channel formation region is lower than or equal to 1×10¹⁸ cm⁻³, preferably lower than or equal to 1×10¹⁷ cm⁻³, further preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. For this reason, it is difficult to miniaturize the Si transistor. One factor that causes the short-channel effect is a small band gap of silicon. By contrast, the OS transistor includes an oxide semiconductor that is a semiconductor material having a wide band gap, and thus can inhibit the short-channel effect. In other words, the OS transistor is a transistor in which the short-channel effect does not appear or hardly appears.

Note that the short-channel effect refers to degradation of electrical characteristics which becomes apparent along with miniaturization of a transistor (a decrease in channel length). Specific examples of the short-channel effect include a decrease in threshold voltage, an increase in subthreshold swing value (sometimes also referred to as S value), and an increase in a leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of a potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Thus, the OS transistor has higher resistance to the short-channel effect than the Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region may decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source and drain regions become n⁺-type regions.

The OS transistor with the above structure can have favorable electrical characteristics even when a memory device is miniaturized or highly integrated. For example, favorable electrical characteristics can be obtained even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, the OS transistor can be suitably used as a transistor having a short channel length as compared with the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

### [Impurity in Metal Oxide]

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Thus, the concentration of nitrogen in the channel formation region in the oxide semiconductor, which is obtained by SIMS, is set lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor that is obtained by SIMS is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor that is obtained by SIMS is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, stable electrical characteristics can be given.

### [Other Semiconductor Materials]

The oxide semiconductor 230 can be rephrased as a semiconductor layer including a channel formation region of the transistor. A semiconductor material that can be used for the semiconductor layer is not limited to the above metal oxides. The semiconductor material that has a band gap (a semiconductor material that is not a zero-gap semiconductor) may be used for the semiconductor layer. For example, a single element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. As silicon that can be used for the semiconductor layer, single crystal silicon, polycrystalline silicon, microcrystalline silicon, and amorphous silicon can be given. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered material contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a memory device with a high on-state current to be provided.

### <Example 1 of Method for Manufacturing Memory Device>

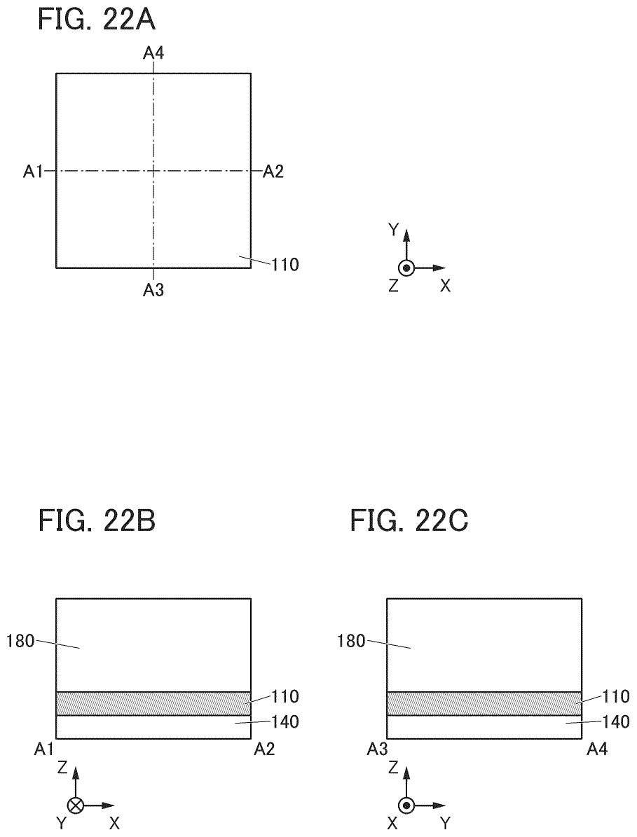

Next, a method for manufacturing the memory device of one embodiment of the present invention illustrated in FIG. 1A to FIG. 1C is described with reference to FIG. 22A to FIG. 32C.

In FIG. 22A to FIG. 32C, A of each drawing is a plan view. Moreover, B of each drawing is a cross-sectional view corresponding to a portion indicated by the dashed-dotted line A1-A2 in A of each drawing. Furthermore, C of each drawing is a cross-sectional view corresponding to a portion indicated by the dashed-dotted line A3-A4 in A of each drawing. Note that for the sake of clarity of the drawing, some components are omitted in the plan view of A of each drawing.

Hereinafter, an insulating material for forming an insulator, a conductive material for forming a conductor, or a semiconductor material for forming a semiconductor can be deposited by a sputtering method, a CVD method, a molecular beam epitaxy (MBE) method, a pulsed laser deposition (PLD) method, an ALD method, and the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is deposited, and a DC sputtering method is mainly used in the case where a metal conductive film is deposited. A pulsed DC sputtering method is mainly used in the case where a film of a compound such as an oxide, a nitride, or a carbide is deposited by a reactive sputtering method.

In addition, CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a deposition method that does not use plasma and thus enables less plasma damage to an object. For example, a wiring, an electrode, an element (a transistor, a capacitor, or the like), or the like included in a memory device may be charged up by receiving charge from plasma. In that case, accumulated charge may break the wiring, the electrode, the element, or the like included in the memory device. In contrast, such plasma damage is not caused in the case of a thermal CVD method, which does not use plasma, and thus the yield of the memory device can be increased. In addition, a thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, a CVD method and an ALD method are less likely to be influenced by the shape of an object to be processed and thus enable favorable step coverage. In particular, an ALD method enables excellent step coverage and excellent thickness uniformity and thus is suitable for covering a surface of an opening portion with a high aspect ratio, for example. On the other hand, an ALD method has a relatively low deposition rate, and thus is preferably used in combination with another deposition method with a high deposition rate, such as a CVD method, in some cases.

By a CVD method, a film with an arbitrary composition can be deposited depending on the flow rate ratio of the source gases. For example, by a CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the memory device can be increased in some cases.

By an ALD method, a film with an arbitrary composition can be deposited by concurrently introducing different kinds of precursors. Alternatively, in the case where different kinds of precursors are introduced, a film with an arbitrary composition can be deposited by controlling the number of cycles for each of the precursors.

First, a substrate (not illustrated) is prepared, and the insulator 140 is formed over the substrate (see FIG. 22A to FIG. 22C). Any of the above-described insulating materials can be used as the insulator 140 as appropriate. The insulator 140 can be deposited by a sputtering method, a CVD method, an MBE method, a PLD method, an ALD method, or the like as appropriate.

Then, the conductor 110 is formed over the insulator 140. Any of the above-described conductive materials can be used as the conductor 110 as appropriate. The conductor 110 can be deposited by a sputtering method, a CVD method, an MBE method, a PLD method, an ALD method, or the like as appropriate. For example, as the conductor 110, a stacked-layer film in which tungsten and titanium nitride are deposited in this order by a CVD method may be formed.

Note that the conductor 110 may be processed to have a shape extending in the X direction or the Y direction. For the processing of the conductor 110, a lithography method can be employed. A dry etching method or a wet etching method can be used for the processing. Processing by a dry etching method is suitable for microfabrication. By the processing, the side end portion of the conductor 110 is covered with the insulator 130 to be formed later.

In the lithography method, first, a resist is exposed to light through a mask. Next, a region exposed to light is removed or left using a developing solution, so that a resist mask is formed. Then, etching process through the resist mask is conducted, whereby a conductor, a semiconductor, an insulator, or the like can be processed into a desired shape. The resist mask may be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. The resist mask can be removed by dry etching treatment such as ashing, wet etching treatment, wet etching treatment after dry etching treatment, or dry etching treatment after wet etching treatment.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

Next, the insulator 180 is formed over the conductor 110 (see FIG. 22A to FIG. 22C). Any of the above-described insulating materials can be used as the insulator 180 as appropriate. The insulator 180 can be deposited by a sputtering method, a CVD method, an MBE method, a PLD method, an ALD method, or the like as appropriate. A silicon oxide film may be deposited as the insulator 180 by a sputtering method, for example. The top surface of the deposited insulator 180 is preferably planarized by CMP (chemical mechanical polishing) treatment. In addition, the CMP treatment may be skipped in some cases. In that case, the top surface of the insulator 180 has an upward-convex curved top surface shape. By not performing planarization treatment, manufacturing cost can be reduced and production yield can be increased.

Here, the thickness of the insulator 180 corresponds to the capacitance of the capacitor 100 and thus is set as appropriate depending on the design value of the capacitance of the capacitor 100.

By using a sputtering method that does not need to use a molecule containing hydrogen as a deposition gas for the insulator 180, the hydrogen concentration in the insulator 180 can be reduced.

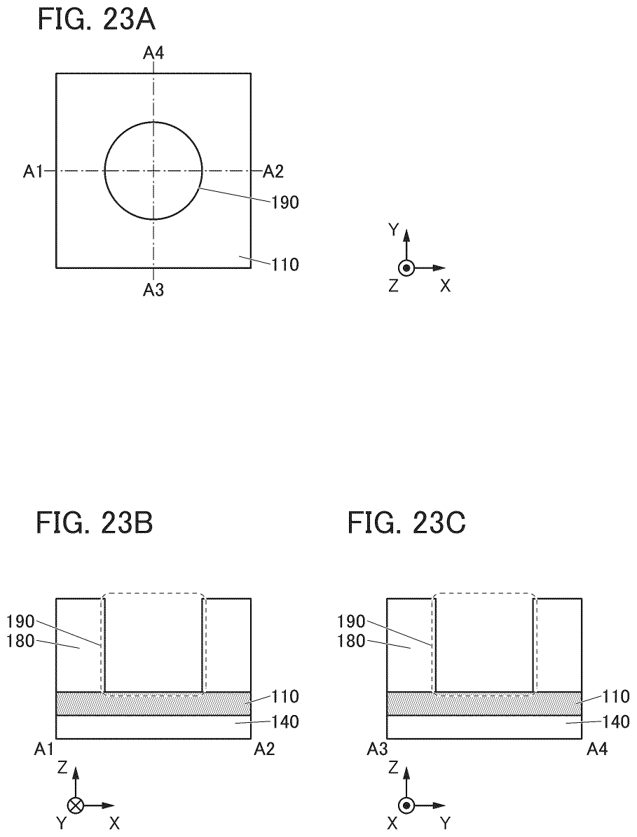

Then, part of the insulator 180 is processed to form the opening portion 190 reaching the conductor 120 (see FIG. 23A to FIG. 23C). The opening portion 190 may be formed by a lithography method. Note that the opening portion 190 has a circular shape in the plan view; however, the shape is not limited to the circular shape. For example, the shape of the opening portion 190 in the plan view may be a substantially circular shape such as an elliptical shape, a polygonal shape such as a quadrangular shape, or a polygonal shape such as a quadrangular shape with rounded corners.

As described above, the sidewall of the opening portion 190 is preferably perpendicular to the top surface of the conductor 110. With the structure, the memory device can be miniaturized or highly integrated. The sidewall of the opening portion 190 may be tapered. When the sidewall of the opening portion 190 has a tapered shape, coverage with a conductive film to be the conductor 115 described later or the like can be improved, so that defects such as a void can be reduced.

The maximum width of the opening portion 190 (the maximum diameter in the case where the opening portion 190 is circular in the plan view) is preferably small. For example, the maximum width of the opening portion 190 is preferably less than or equal to 100 nm, less than or equal to 60 nm, less than or equal to 50 nm, less than or equal to 40 nm, or less than or equal to 30 nm and greater than or equal to 5 nm or greater than or equal to 10 nm. In order to process the opening portion 190 finely, a lithography method using an electron beam or short-wavelength light such as EUV light is preferably used.

Since the opening portion 190 has a high aspect ratio, part of the insulator 180 is preferably processed by anisotropic etching. Processing by a dry etching method is particularly preferable because it is suitable for microfabrication.

As described above, the maximum width of the opening portion 190 is larger than the maximum width of the opening portion 290; thus, in the case where the opening portion 190 and the opening portion 290 are formed by anisotropic etching, it is difficult to use the same mask. In view of this, the opening portion 190 may be formed by processing part of the insulator 180 by anisotropic etching to form an opening portion and widening the width of the opening portion by isotropic etching. When the opening portion 190 is formed in such a process, the same mask can be used for anisotropic etching in forming the opening portion 190 and the opening portion 290. Thus, the number of masks can be reduced, and the cost of the memory device can be reduced.

Next, the conductive film to be the conductor 115 is formed in contact with the bottom portion and the sidewall of the opening portion 190 and at least part of the top surface of the insulator 180. Any of the conductors usable for the conductor 115 can be used for the conductive film as appropriate. The conductive film may be deposited by a sputtering method, a CVD method, an MBE method, a PLD method, an ALD method, or the like as appropriate. Here, the conductive film is preferably formed in contact with the bottom portion and the side wall of the opening portion 190 with a high aspect ratio. Thus, the conductive film is preferably formed by a formation method enabling favorable coverage, and is further preferably formed by a CVD method, an ALD method, or the like. For example, a titanium nitride film may be deposited by a CVD method as the conductive film.

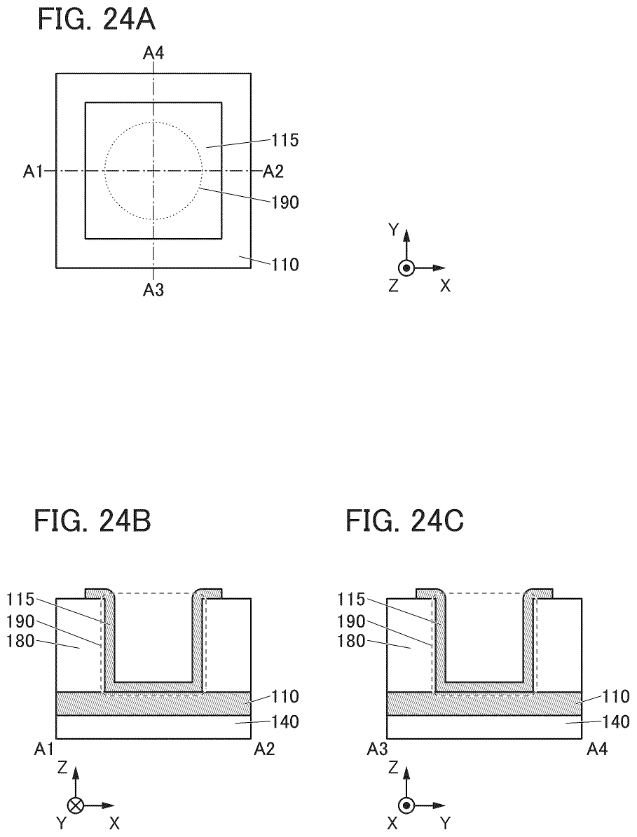

Next, the conductive film to be the conductor 115 is processed by a lithography method to form the conductor 115 (see FIG. 24A to FIG. 24C). Accordingly, part of the conductor 115 is formed in the opening portion 190. The conductor 115 is in contact with the side surface and part of the top surface of the insulator 180.

Note that in the case of manufacturing the memory device illustrated in FIG. 7A to FIG. 7C, the formed conductive film to be the conductor 115 is preferably subjected to the CMP treatment. With the CMP treatment, the conductor 115 whose top surface is level with the top surface of the insulator 180 can be formed.

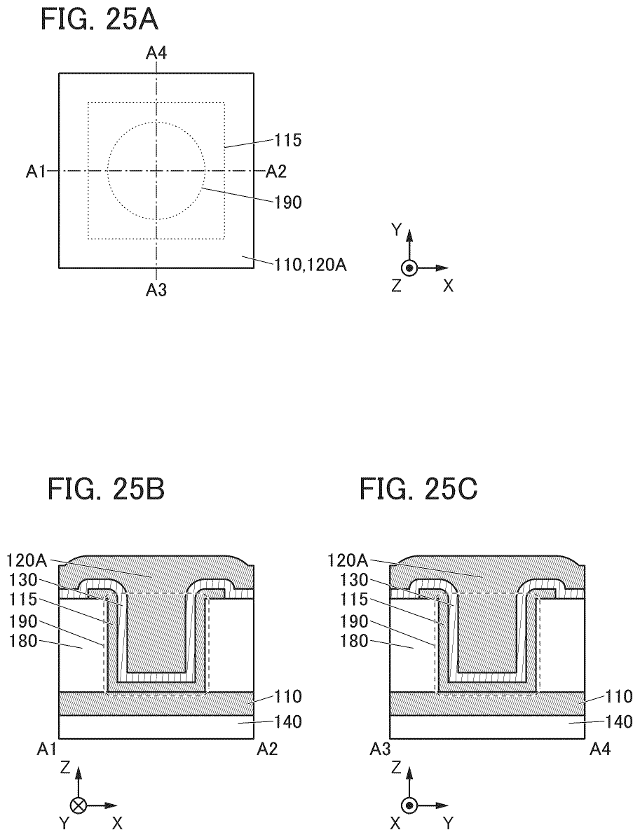

Next, the insulator 130 is formed over the conductor 115 and the insulator 180 (see FIG. 25A to FIG. 25C). Any of the above-described high-k materials or materials that can have ferroelectricity can be used as appropriate for the insulator 130. The insulator 130 can be deposited by a sputtering method, a CVD method, an MBE method, a PLD method, an ALD method, or the like as appropriate. For example, a stacked-layer film in which a zirconium oxide, an aluminum oxide, and a zirconium oxide are deposited in this order by an ALD method may be formed as the insulator 130.

Then, a conductive film 120A is formed over the insulator 130 (see FIG. 25A to FIG. 25C). The conductive film 120A can be formed using any of the above conductive materials. The conductive film 120A can be deposited by a sputtering method, a CVD method, an MBE method, a PLD method, an ALD method, or the like as appropriate. For example, as the conductive film 120A, a stacked film in which titanium nitride and tantalum nitride are deposited in this order by a CVD method may be used. Alternatively, for example, a stacked film in which titanium nitride and tungsten are deposited in this order by a CVD method may be used as the conductive film 120A.

Note that the top surface of the conductive film 120A may be planarized by a CMP method or the like. When the conductive film 120A is subjected to the planarization treatment, the top surface of the conductor 120, which is formed by processing the conductive film 120A, is planarized, so that the transistor 200 can be favorably formed over the capacitor 100.

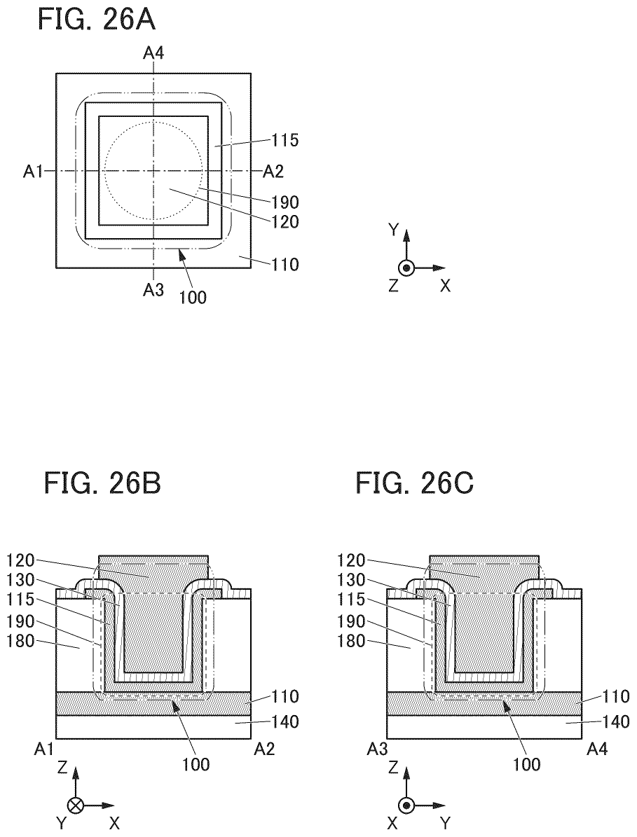

Next, the conductive film 120A is processed to form the conductor 120 (see FIG. 26A to FIG. 26C). The conductor 120 can be formed by a lithography method. For the processing of the conductive film 120A, a dry etching method or a wet etching method can be employed. Processing by a dry etching method is suitable for microfabrication.

In the above manner, the capacitor 100 including the conductor 115, the insulator 130, and the conductor 120 can be formed.

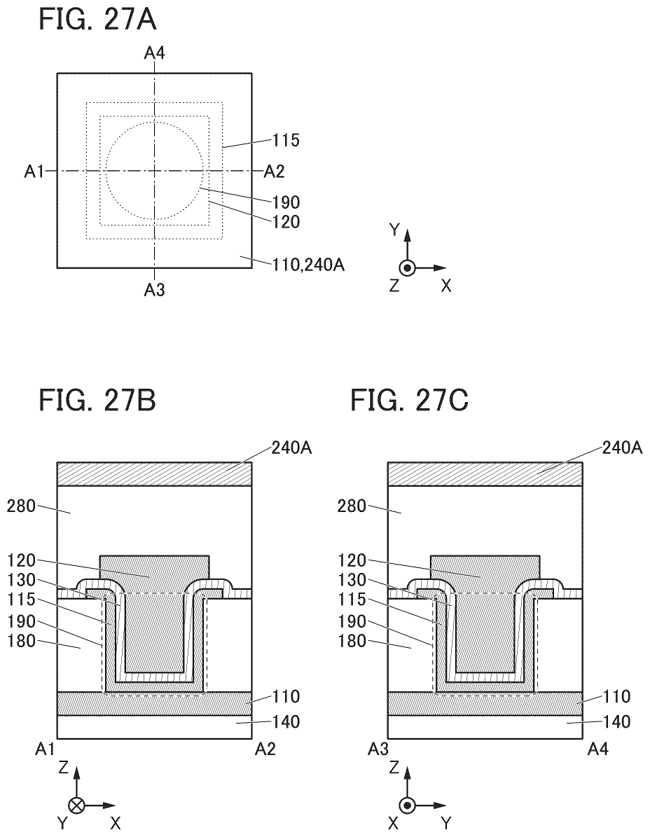

Next, the insulator 280 is formed over the insulator 130 and the conductor 120 (see FIG. 27A to FIG. 27C). Any of the above-described insulating materials can be used as the insulator 280 as appropriate. The insulator 280 can be deposited by a sputtering method, a CVD method, an MBE method, a PLD method, an ALD method, or the like as appropriate .. A silicon oxide film may be deposited as the insulator 280 by a sputtering method, for example. The top surface of the deposited insulator 280 is preferably planarized by the CMP treatment. The planarization treatment for the insulator 280 enables favorable formation of the conductor 240 functioning as a wiring. For example, after aluminum oxide is deposited over the insulator 280 by a sputtering method, the aluminum oxide may be subjected to the CMP treatment until the insulator 280 is reached. The CMP treatment can planarize and smooth the surface of the insulator 280. When the CMP treatment is performed on the aluminum oxide provided over the insulator 280, it is easy to detect the endpoint of the CMP treatment.

In addition, the CMP treatment may be skipped in some cases. In that case, the top surface of the insulator 280 has an upward-convex curved top surface shape. By not performing planarization treatment, manufacturing cost can be reduced and production yield can be increased.

Since the thickness of the insulator 280 over the conductor 120 corresponds to the channel length of the transistor 200, the thickness of the insulator 280 is set as appropriate depending on the design value of the channel length of the transistor 200.

When the insulator 280 is deposited by a sputtering method in an oxygen-containing atmosphere, the insulator 280 containing excess oxygen can be formed. By using a sputtering method that does not need to use a molecule containing hydrogen as a deposition gas, the hydrogen concentration in the insulator 280 can be reduced. When the insulator 280 is deposited in this manner, oxygen can be supplied from the insulator 280 to the channel formation region of the oxide semiconductor 230, so that oxygen vacancies and VoH therein can be reduced.

Then, a conductive film 240A is deposited over the insulator 280 (see FIG. 27A to FIG. 27C). Any of the above-described conductive materials can be used for the conductive film 240A as appropriate. The conductive film 240A can be deposited by a sputtering method, a CVD method, an MBE method, a PLD method, an ALD method, or the like as appropriate.

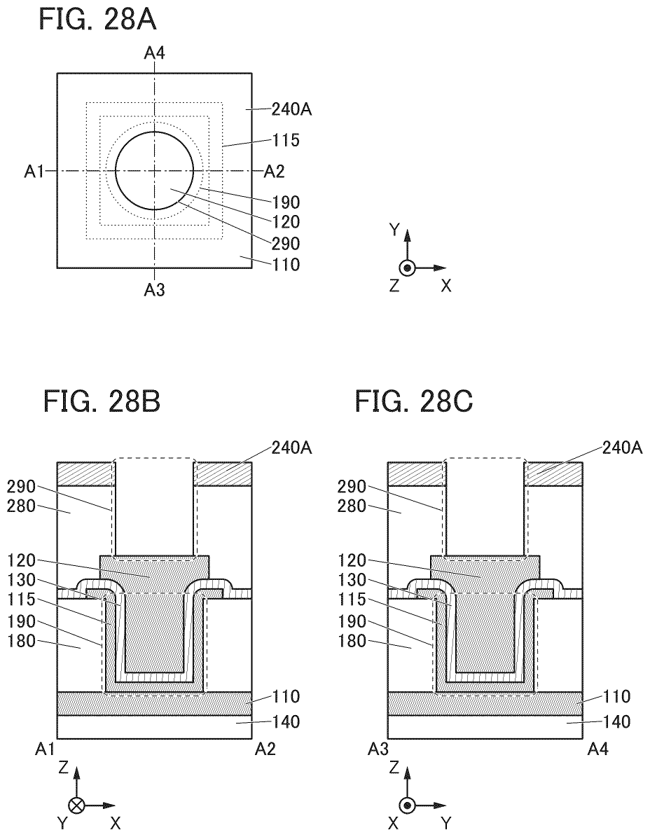

Then, part of the conductive film 240A and part of the insulator 280 are processed to form the opening portion 290 reaching the conductor 120 (see FIG. 28A to FIG. 28C). As illustrated in FIG. 28A, the opening portion 290 is preferably formed to include a region overlapping with the opening portion 190. The opening portion 290 may be formed by a lithography method. The opening portion 290 in FIG. 28A has a circular shape in the plan view; however, the shape is not limited thereto. For example, the opening portion 290 in the plan view may have a substantially circular shape such as an elliptical shape, a polygonal shape such as a quadrangular shape, or a polygonal shape such as a quadrangular shape with rounded corners.

As described above, the sidewall of the opening portion 290 is preferably perpendicular to the top surface of the conductor 120. With the structure, the memory device can be miniaturized or highly integrated. Alternatively, the sidewall of the opening portion 290 may have a tapered shape. When the sidewall of the opening portion 290 has a tapered shape, the coverage with a later-described oxide semiconductor film to be the oxide semiconductor 230, and the like can be improved, so that defects such as voids can be reduced.

The maximum width of the opening portion 290 (the maximum diameter in the case where the opening portion 290 is circular in the plan view) is preferably small. For example, the maximum width of the opening portion 290 is preferably less than or equal to 60 nm, less than or equal to 50 nm, less than or equal to 40 nm, less than or equal to 30 nm, or less than or equal to 20 nm and greater than or equal to 1 nm or greater than or equal to 5 nm. In order to process the opening portion 290 finely, a lithography method using an electron beam or short-wavelength light such as EUV light is preferably used.

Since the opening portion 290 has a high aspect ratio, part of the conductive film 240A and part of the insulator 280 are preferably processed by anisotropic etching. Processing by a dry etching method is particularly preferable because it is suitable for microfabrication. The processing may be performed under different conditions. Depending on the conditions for processing part of the conductive film 240A and part of the insulator 280, the inclination of the side surface of the conductor 240 in the opening portion 290 may be different from the inclination of the side surface of the insulator 280 in the opening portion 290 as described above.

Next, heat treatment may be performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere. By the above-described heat treatment, impurities such as water contained in the insulator 280 or the like can be reduced before formation of the later-described oxide semiconductor film to be the oxide semiconductor 230.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the insulator 280 and the like as much as possible.

Next, the oxide semiconductor film to be the oxide semiconductor 230 is formed in contact with the bottom portion and the sidewall of the opening portion 290 and at least part of the top surface of the conductive film 240A. For the oxide semiconductor film, a metal oxide usable for the oxide semiconductor 230 is used as appropriate. The oxide semiconductor film can be deposited by a sputtering method, a CVD method, an MBE method, a PLD method, an ALD method, or the like as appropriate. Here, the oxide semiconductor film is preferably formed in contact with the bottom portion and the sidewall of the opening portion 290 with a high aspect ratio. Thus, the oxide semiconductor film is preferably formed by a formation method with favorable coverage, and is further preferably formed by a CVD method, an ALD method, or the like. For example, an In-Ga-Zn oxide may be deposited by an ALD method as the oxide semiconductor film.

As the precursor containing indium, an organic precursor such as trimethylindium, triethylindium, tris(2,2,6,6-tetramethyl-3,5-heptanedionato)indium, cyclopentadienylindium, indium(III) acetylacetonate, or (3-(dimethylamino)propyl)dimethylindium can be used.

As the gallium-containing precursor, an organic precursor such as trimethylgallium, triethylgallium, tris(dimethylamido)gallium, gallium(III) acetylacetonate, tris(2,2,6,6-tetramethyl-3,5-heptanedionato)gallium, dimethylchlorogallium, diethylchlorogallium, or dimethyl gallium isopropoxide can be used.

An organic precursor such as dimethylzinc, diethylzinc, bis(2,2,6,6-tetramethyl-3,5-heptanedionato)zinc, or zinc acetate can be used as the precursor containing zinc.

In order to perform deposition by an ALD method while the substrate is being heated, the decomposition temperature of a precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, an inorganic precursor not including hydrocarbon is preferably used. In general, an inorganic precursor tends to have a higher decomposition temperature than an organic precursor, so that even when deposition is performed while the substrate is being heated as described above, the precursor is hardly decomposed.

As an inorganic precursor containing indium, a halogen-based indium compound such as indium trichloride, indium tribromide, or indium triiodide can be used. As an inorganic precursor containing gallium, a halogen-based gallium compound such as gallium trichloride, gallium tribromide, or gallium triiodide can be used. As an inorganic precursor containing zinc, a halogen-based zinc compound such as zinc dichloride, zinc dibromide, or zinc diiodide can be used.

Some of the above-described precursors each containing the metal element further contain one or both of carbon and chlorine. A film that is formed using a precursor containing carbon may contain carbon. A film that is formed using a precursor containing halogen such as chlorine may contain halogen such as chlorine.

Ozone, oxygen, water, or the like can be used as the oxidizer.

Note that in the case where the sidewall of the opening portion 290 has a tapered shape, the method for forming the oxide semiconductor film to be the oxide semiconductor 230 is not limited to a CVD method or an ALD method. For example, a sputtering method may be employed.

In the case where the oxide semiconductor 230 has a stacked-layer structure as illustrated in FIG. 16A and FIG. 16B, the layers included in the oxide semiconductor 230 may be formed by the same method or different methods. For example, in the case where the oxide semiconductor 230 has a stacked-layer structure of two layers, the lower oxide semiconductor film may be deposited by a sputtering method and the upper oxide semiconductor film may be deposited by an ALD method. An oxide semiconductor film deposited by a sputtering method is likely to have crystallinity. Thus, when an oxide semiconductor film having crystallinity is provided as the lower oxide semiconductor film, the crystallinity of the upper oxide semiconductor film can be increased. Thus, even when a pinhole, disconnection, or the like is generated in the lower oxide semiconductor film deposited by a sputtering method, a portion overlapping with the pinhole, disconnection, or the like can be filled with the upper oxide semiconductor film that is deposited by an ALD method and has excellent coverage.

Here, the oxide semiconductor film to be the oxide semiconductor 230 is preferably formed in contact with the top surface of the conductor 120 in the opening portion 290, the side surface of the insulator 280 in the opening portion 290, the side surface of the conductor 240 in the opening portion 290, and the top surface of the conductor 240. When the oxide semiconductor film is formed in contact with the conductor 120, the conductor 120 functions as one of the source electrode and the drain electrode of the transistor 200. When the oxide semiconductor film is formed in contact with the conductor 240, the conductor 240 functions as the other of the source electrode and the drain electrode of the transistor 200.

Next, heat treatment is preferably performed. The heat treatment can be performed in a temperature range where the oxide semiconductor film does not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the oxide semiconductor film and the like as much as possible.

Here, the above-described heat treatment is preferably performed in the state where the insulator 280 containing excess oxygen is in contact with the oxide semiconductor film. By the heat treatment performed in that manner, oxygen is supplied from the insulator 280 to the channel formation region of the oxide semiconductor 230, whereby oxygen vacancies and VoH can be reduced.

In the case where the oxide semiconductor film is formed by an ALD method, impurities such as hydrogen or carbon contained in the oxide semiconductor film can be removed by the heat treatment. For example, carbon in the oxide semiconductor film can be released as CO₂ and CO, and hydrogen in the oxide semiconductor film can be released as H₂O. Furthermore, metal atoms and oxygen atoms are rearranged concurrently with removal of the impurity, which can improve crystallinity. Thus, the oxide semiconductor 230 having a layered crystal structure with high crystallinity can be formed.

Although the heat treatment is performed after the formation of the oxide semiconductor film in the above, the present invention is not limited thereto. The heat treatment may be performed in a later step.

After the formation of the oxide semiconductor film, microwave treatment is preferably performed in an oxygen-containing atmosphere so that the impurity concentration in the oxide semiconductor film can be reduced. Specific examples of the impurity include hydrogen and carbon. Here, the microwave treatment refers to, for example, treatment using an apparatus including a power source that generates high-density plasma with the use of a microwave.

The microwave treatment in an oxygen-containing atmosphere can convert an oxygen gas into plasma using a high-frequency wave such as a microwave or RF and activate the oxygen plasma. Oxygen that acts on the oxide semiconductor film has any of a variety of forms such as an oxygen atom, an oxygen molecule, an oxygen ion, and an oxygen radical (also referred to as O radical, which is an atom, a molecule, or an ion having an unpaired electron). Note that the oxygen that acts on the oxide semiconductor film has any one or more of the above forms, particularly suitably an oxygen radical.

The above-described microwave treatment in an oxygen-containing atmosphere is preferably performed while the substrate is heated, in which case the impurity concentration in the oxide semiconductor film can be further reduced. The substrate heating temperature is higher than or equal to 100° C. and lower than or equal to 650° C., preferably higher than or equal to 200° C. and lower than or equal to 600° C., and further preferably higher than or equal to 300° C. and lower than or equal to 450° C.

When the microwave treatment in an oxygen-containing atmosphere is performed while the substrate is heated, the carbon concentration in the metal oxide, which is measured by SIMS, can be lower than 1×10²⁰ atoms/cm³, preferably lower than 1×10¹⁹ atoms/cm³, further preferably lower than 1×10¹⁸ atoms/cm³.

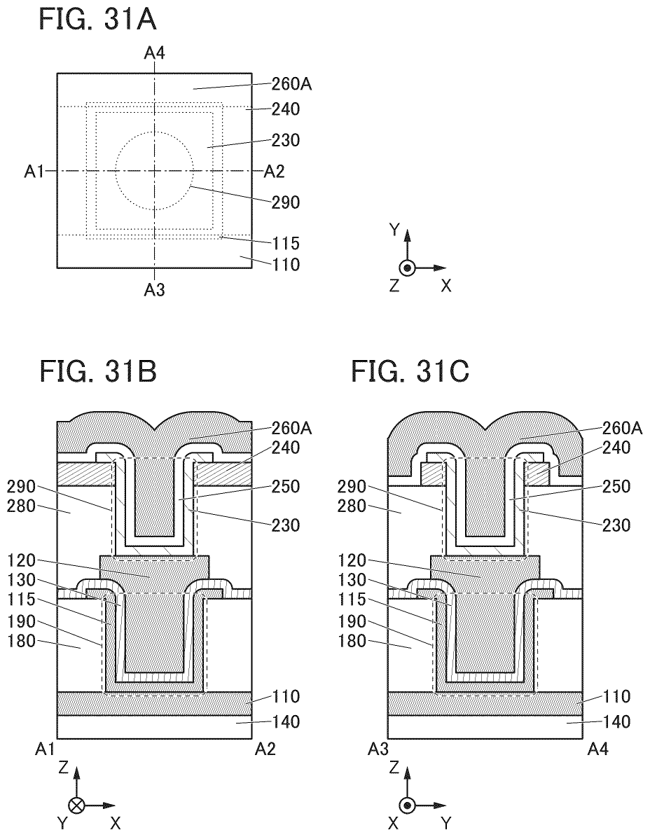

Although the microwave treatment in an oxygen-containing atmosphere is performed on the oxide semiconductor film in the above-described example, one embodiment of the present invention is not limited thereto. For example, the microwave treatment in an oxygen-containing atmosphere may be performed on an insulating film, specifically a silicon oxide film, which is positioned in the vicinity of the oxide semiconductor. For example, in the later-described step illustrated in FIG. 31, microwave treatment may be performed after the insulator 250 is formed. When the silicon oxide film is subjected to microwave treatment in an oxygen-containing atmosphere, hydrogen contained in the silicon oxide film can be released as H₂O to the outside. Release of hydrogen from the silicon oxide film positioned in the vicinity of the oxide semiconductor enables formation of a highly reliable memory device.

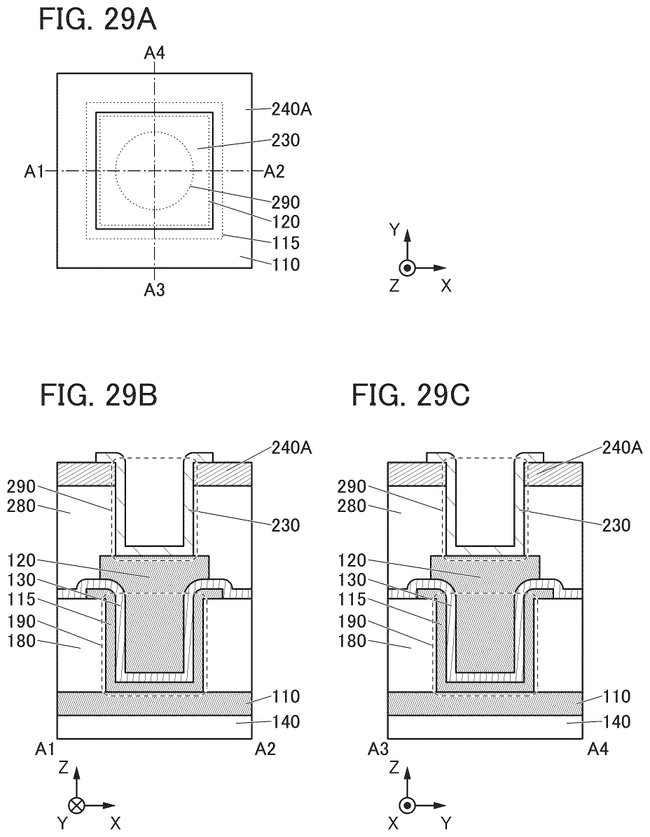

Next, the oxide semiconductor film to be the oxide semiconductor 230 is processed by a lithography method to form the oxide semiconductor 230 (see FIG. 29A to FIG. 29C). Accordingly, part of the oxide semiconductor 230 is formed in the opening portion 290. The oxide semiconductor 230 is in contact with the side surface and part of the top surface of the conductor 240. Accordingly, the area of a region where the oxide semiconductor 230 is in contact with the conductor 240 can be increased.

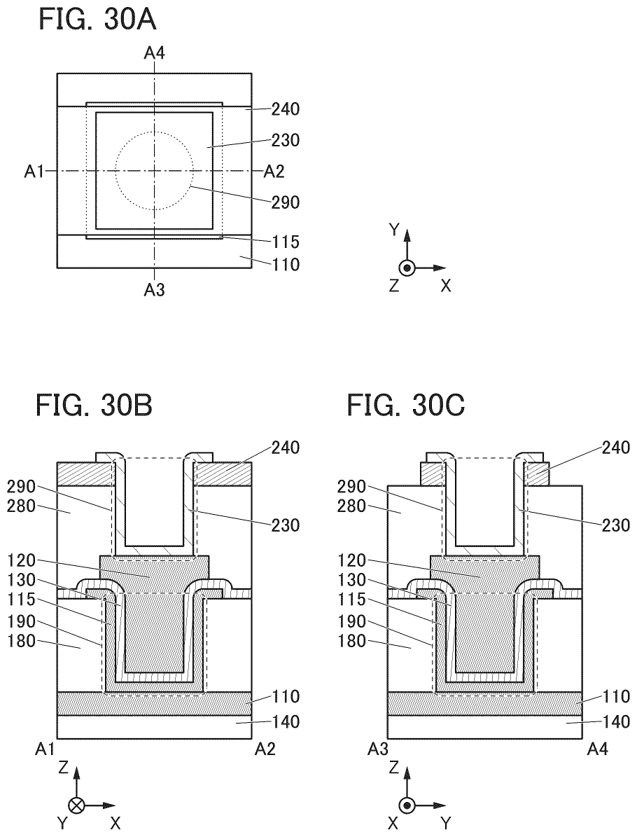

Next, the conductive film 240A is processed to form the conductor 240 (see FIG. 30A to FIG. 30C). The conductor 240 can be formed by a lithography method. For the processing of the conductive film 240A, a dry etching method or a wet etching method can be employed. Processing by a dry etching method is suitable for microfabrication.

Here, a method that is different from the above-described formation method of the conductor 240 and the oxide semiconductor 230 is described.

The steps up to and including the formation of the conductive film 240A illustrated in FIG. 27A to FIG. 27C are performed in a manner similar to the above-described method.

Next, the conductive film 240A is processed to form the conductor 240. The above description can be referred to for the formation method and the like of the conductor 240.

Next, part of the conductor 240 and part of the insulator 280 are processed to form the opening portion 290 reaching the conductor 120. The above description can be referred to for the method and the like for forming the opening portion 290.

Next, heat treatment may be performed. The above description can be referred to for conditions and the like of the heat treatment.

Next, the oxide semiconductor film to be the oxide semiconductor 230 is formed in contact with the bottom portion and the sidewall of the opening portion 290 and at least part of the top surface of the conductor 240. In this case, the oxide semiconductor film includes a region in contact with the top surface of the insulator 280. For example, the above description can be referred to for the formation method and the like of the oxide semiconductor film.

Next, heat treatment is preferably performed. The above description can be referred to for conditions and the like of the heat treatment.

Next, the oxide semiconductor film to be the oxide semiconductor 230 is processed by a lithography method to form the oxide semiconductor 230 (see FIG. 30A to FIG. 30C).

The following steps for manufacturing the memory device are common to both of the methods.

Next, the insulator 250 is formed over the oxide semiconductor 230, the conductor 240, and the insulator 280 (see FIG. 31A to FIG. 31C). Any of the above-described insulating materials can be used as the insulator 250 as appropriate. The insulator 250 can be deposited by a sputtering method, a CVD method, an MBE method, a PLD method, an ALD method, or the like as appropriate. The insulator 250 is preferably formed in contact with the oxide semiconductor 230 that is provided in the opening portion 290 having a high aspect ratio. Thus, the insulator 250 is preferably formed by a formation method enabling favorable coverage, and is further preferably formed by a CVD method, an ALD method, or the like. For example, silicon oxide may be deposited as the insulator 250 by an ALD method.

In the case where the sidewall of the opening portion 290 has a tapered shape, the method for forming the insulator 250 is not limited to a CVD method or an ALD method. For example, a sputtering method may be employed.

When the insulator 250 is formed after the formation of the oxide semiconductor 230, the side end portion of the oxide semiconductor 230 is covered with the insulator 250. Thus, a short circuit between the oxide semiconductor 230 and the conductor 260 can be prevented. Furthermore, in the above-described structure, the side end portion of the conductor 240 is covered with the insulator 250. Thus, a short circuit between the conductor 240 and the conductor 260 can be prevented.

Next, a conductive film 260A is formed to fill the depressed portion of the insulator 250 (see FIG. 31A to FIG. 31C). Any of the above-described conductive materials can be used for the conductive film 260A as appropriate. The conductive film 260A can be deposited by a sputtering method, a CVD method, an MBE method, a PLD method, an ALD method, or the like as appropriate. Here, the conductive film 260A is preferably formed in contact with the insulator 250 provided in the opening portion 290 with a high aspect ratio. Thus, the conductive film 260A is preferably formed by a deposition method providing favorable coverage or a good filling property, and is further preferably deposited by a CVD method, an ALD method, or the like. For example, titanium nitride may be deposited by a CVD method or an ALD method as the conductive film 260A.

In the case where the conductive film 260A is deposited by a CVD method, the average surface roughness of the top surface of the conductive film 260A is sometimes increased. In this case, the conductive film 260A is preferably planarized by a CMP method. At this time, before the CMP treatment, a silicon oxide film or a silicon oxynitride film may be deposited over the conductive film 260A and the CMP treatment may be performed until the silicon oxide film or the silicon oxynitride film is removed.

Although the conductive film 260A is provided to fill the opening portion 290 in the above description, the present invention is not limited thereto. For example, a depressed portion reflecting the shape of the opening portion 290 is formed in a center portion of the conductive film 260A in some cases. The depressed portion may be filled with an inorganic insulating material or the like.

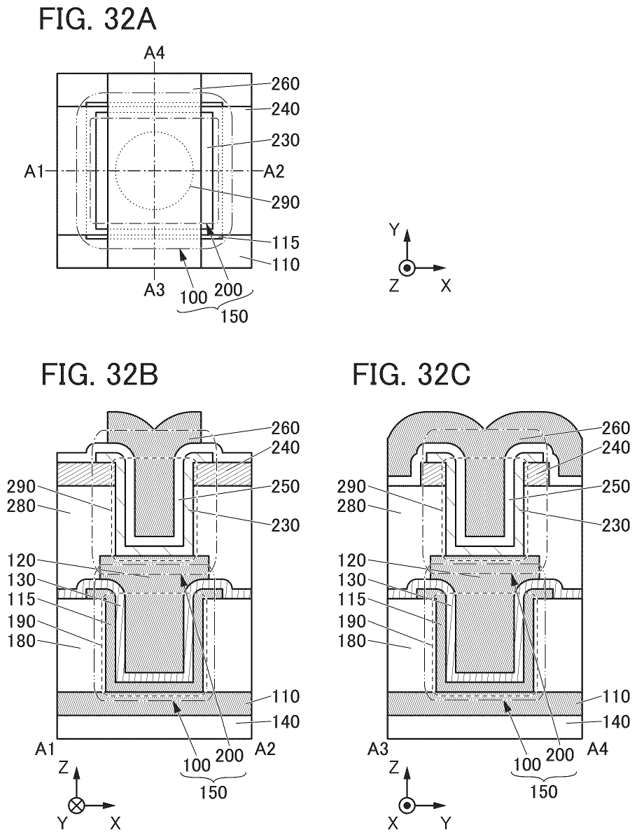

Next, the conductive film 260A is processed to form the conductor 260 (see FIG. 32A to FIG. 32C). The conductor 260 may be formed by a lithography method. A dry etching method or a wet etching method can be used for the processing. Processing by a dry etching method is suitable for microfabrication.

Here, as illustrated in FIG. 1A and FIG. 1B, the side end portion of the conductor 260 is preferably positioned inward from the side end portion of the oxide semiconductor 230 in the plan view. This can prevent a short circuit between the conductor 260 and the oxide semiconductor 230.

In the above manner, the transistor 200 including the conductor 120, the conductor 240, the oxide semiconductor 230, the insulator 250, and the conductor 260 can be formed.

Next, the insulator 283 is formed to cover the conductor 260 and the insulator 250. Any of the above-described insulating materials can be used as the insulator 283 as appropriate. The insulator 283 can be deposited by a sputtering method, a CVD method, an MBE method, a PLD method, an ALD method, or the like as appropriate.

Through the above process, the memory device including the memory cell 150 illustrated in FIG. 1A to FIG. 1D can be manufactured. In addition, the memory device including the transistor 200 and the capacitor 100 illustrated in FIG. 1A to FIG. 1D can be manufactured.

### <Example 2 of Method for Manufacturing Memory Device>

Next, a method for manufacturing the memory device of one embodiment of the present invention illustrated in FIG. 10A to FIG. 10C is described. For the steps up to and including the formation of the insulator 180, the description in <Example 1 of method for manufacturing memory device> above can be referred to.

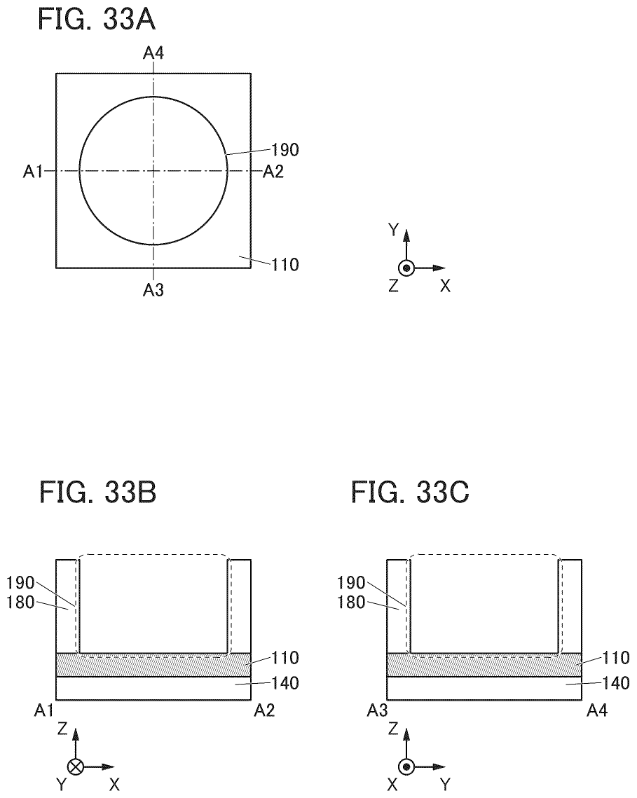

Then, part of the insulator 180 is processed to form the opening portion 190 reaching the conductor 120 (see FIG. 33A to FIG. 33C). The above description can be referred to for the method and the like for forming the opening portion 190.

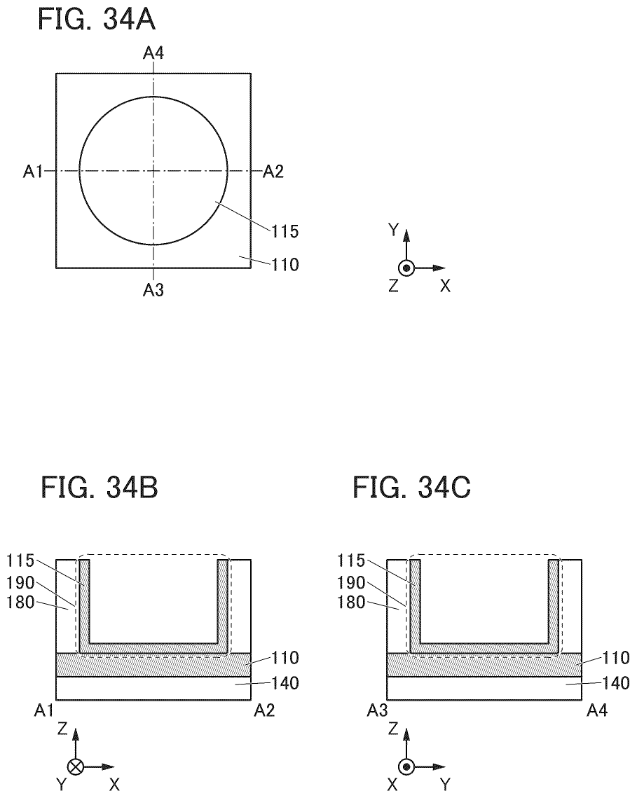

Next, a conductive film to be the conductor 115 is formed in contact with the bottom portion and the sidewall of the opening portion 190 and at least part of the top surface of the insulator 180. The above description can be referred to for the formation method and the like of the conductive film. After the conductive film is formed, the CMP treatment is performed. By performing the CMP treatment, the conductor 115 can be formed (see FIG. 34A to FIG. 34C). In this case, the top surface of the conductor 115 and the top surface of the insulator 180 are level with each other.

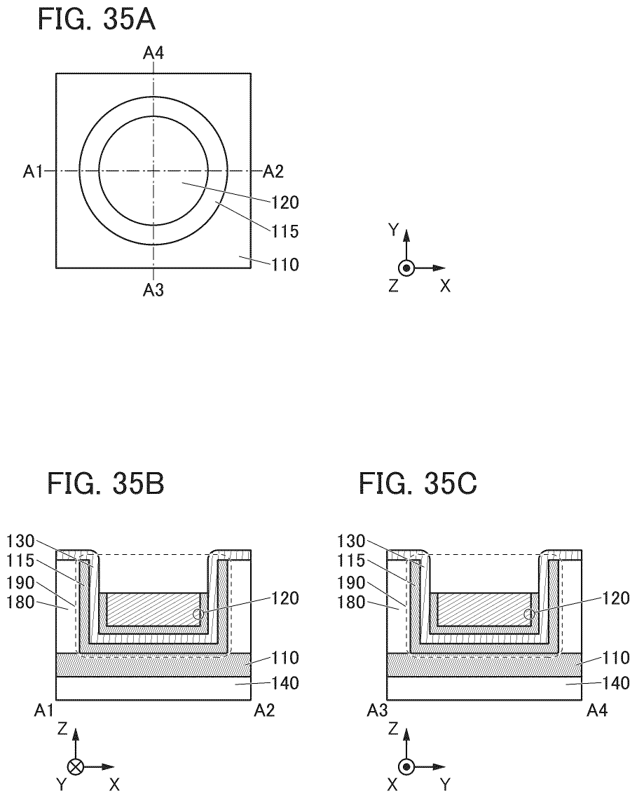

Next, the insulator 130 is formed over the conductor 115 and the insulator 180 (see FIG. 35A to FIG. 35C). The above description can be referred to for the formation method and the like of the insulator 130.

Then, a conductive film to be the conductor 120 is formed over the insulator 130. The above description of the conductive film 120A can be referred to for the formation method and the like of the conductive film. For example, a stacked film in which titanium nitride and tungsten are formed in this order by a CVD method may be used as the conductive film.

Next, the CMP treatment is performed to remove a part of the conductive film to be the conductor 120, so that the insulator 130 is exposed. As a result, the conductor 120 remains only in the opening portion 190. Note that part of the insulator 130 is removed by the CMP treatment in some cases. Note that part of the conductive film to be the conductor 120 may be removed by a method other than the CMP treatment.

Next, the upper portion of the conductor 120 is removed by etching (see FIG. 35A to FIG. 35C). Thus, the level of the top surface of the conductor 120 is lower than the level of the top surface of the insulator 130. Dry etching or wet etching can be used for the etching of the conductor 120, and dry etching is preferably used for microfabrication.

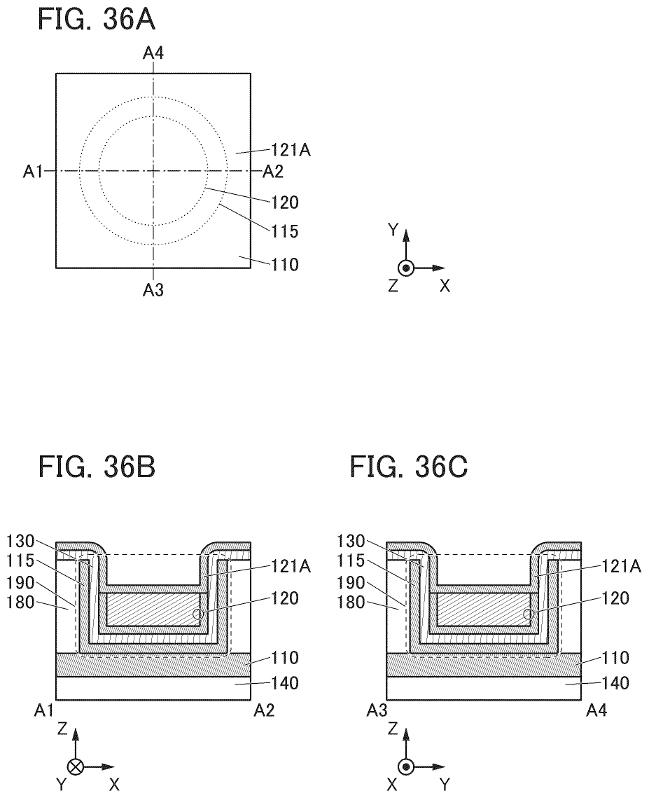

Next, a conductive film 121A is formed over the insulator 130 and the conductor 120 (see FIG. 36A to FIG. 36C). For example, titanium nitride is deposited by a CVD method or an ALD method as the conductive film 121A.

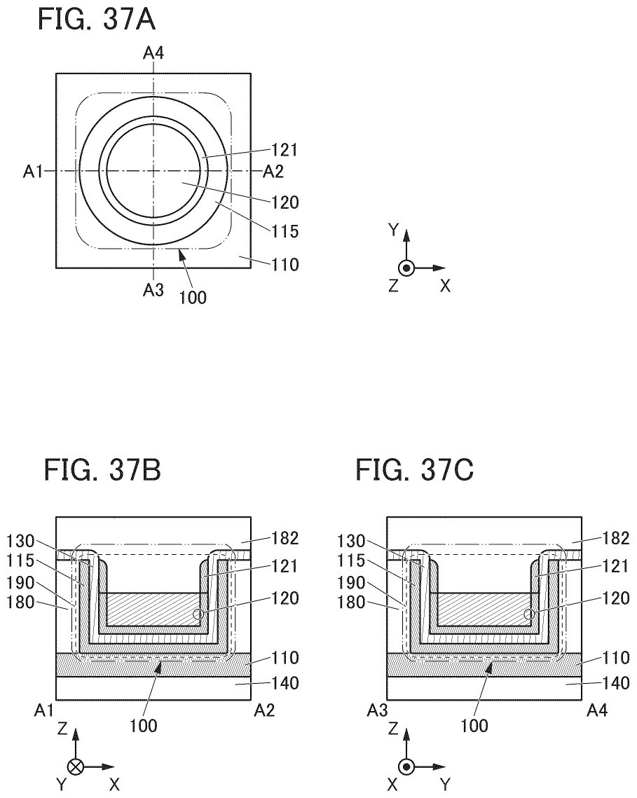

Next, anisotropic etching is performed on the conductive film 121A to form the conductor 121 in contact with the side surface of the insulator 130 in the opening portion 190 (see FIG. 37A to FIG. 37C). For the anisotropic etching of the conductive film 121A, a dry etching method may be employed, for example. Note that in the case where the lower layer of the conductor 120 and the conductor 121 are formed using the same material, the boundaries between the lower layer of the conductor 120 and the conductor 121 are difficult to detect clearly in some cases.

In the above manner, the capacitor 100 including the conductor 115, the insulator 130, the conductor 120, the conductor 121 can be formed.

Next, the insulator 182 is formed over the insulator 130, the conductor 121, and the conductor 120 (see FIG. 37A to FIG. 37C). Any of the above-described insulating materials can be used as the insulator 182 as appropriate. The insulator 182 can be deposited by a sputtering method, a CVD method, an MBE method, a PLD method, an ALD method, or the like as appropriate. A silicon oxide film may be deposited as the insulator 182 by a sputtering method, for example. The top surface of the deposited insulator 182 is preferably planarized by the CMP treatment.

Next, an opening reaching the conductor 120 is formed in the insulator 182. The opening can be formed by a lithography method. A dry etching method or a wet etching method can be used for the etching of the opening. Processing by a dry etching method is suitable for microfabrication.

Next, a conductive film to be the conductor 122 is formed to fill the opening formed in the insulator 182. Any of the above-described conductive materials can be used for the conductive film as appropriate. The conductive film may be deposited by a sputtering method, a CVD method, an MBE method, a PLD method, an ALD method, or the like as appropriate. For example, a stacked film in which tantalum nitride and tungsten are deposited in this order by a sputtering method may be formed as the conductive film.

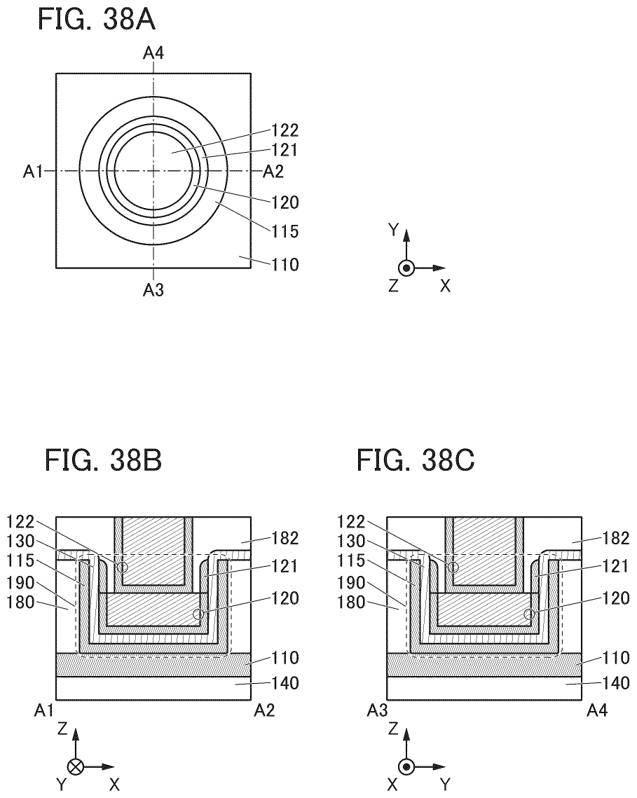

Next, part of the conductive film to be the conductor 122 over the insulator 182 is removed, and the conductor 122 is formed inside the opening of the insulator 182 (see FIG. 38A to FIG. 38C). For the formation of the conductor 122, the conductive film may be subjected to the CMP treatment until the top surface of the insulator 182 is exposed.

Next, the insulator 280 is formed over the insulator 182 and the conductor 120. The above description can be referred to for the formation method and the like of the insulator 280.

For steps subsequent to the formation of the insulator 280 (steps subsequent to and including the formation of the conductive film 240A), the description in <Example 1 of method for manufacturing memory device> above can be referred to.

Through the above process, the memory device including the memory cell 150 illustrated in FIG. 10A to FIG. 10C can be manufactured. In addition, the memory device including the transistor 200 and the capacitor 100 illustrated in FIG. 10A to FIG. 10C can be manufactured.

### <Example 3 of Method for Manufacturing Memory Device>

Next, a method for manufacturing the memory device of one embodiment of the present invention illustrated in FIG. 20A to FIG. 20C is described. For the steps up to and including the formation of the insulator 280, the description in <Example 1 of method for manufacturing memory device> above can be referred to.

The insulator 281 is formed over the insulator 280. Any of the above-described insulating materials can be used as the insulator 281 as appropriate. The insulator 281 can be deposited by a sputtering method, a CVD method, an MBE method, a PLD method, an ALD method, or the like as appropriate. A silicon oxide film can be deposited by a sputtering method as the insulator 281, for example. The top surface of the deposited insulator 281 is preferably planarized by the CMP treatment.

Then, an opening to reach the insulator 280 is formed in the insulator 281. Since the conductor 240 functioning as a wiring is formed inside the opening, the opening is preferably provided to extend in the X direction. The opening can be formed by a lithography method. A dry etching method or a wet etching method can be used for the etching of the opening. Processing by a dry etching method is suitable for microfabrication.

Note that the insulator 280 may have a stacked-layer structure, and an insulator functioning as an etching stopper film may be provided on the uppermost surface of the insulator 280. The insulator corresponds to the insulator 280c in the structures illustrated in FIG. 17. For example, in the case where silicon oxide or silicon oxynitride is used for the insulator 281 in which the opening is to be formed, silicon nitride, aluminum oxide, hafnium oxide, or the like is preferably used as the etching stopper film.

Next, a conductive film to be the conductor 240 is formed to fill the opening formed in the insulator 281. Any of the above-described conductive materials can be used for the conductive film as appropriate. The conductive film may be deposited by a sputtering method, a CVD method, an MBE method, a PLD method, an ALD method, or the like as appropriate. For example, a stacked film in which tantalum nitride and tungsten are deposited in this order by a sputtering method may be formed as the conductive film.

Next, part of the conductive film to be the conductor 240 over the insulator 281 is removed, and the conductor 240 is formed inside the opening of the insulator 281. For the formation of the conductor 240, the conductive film may be subjected to the CMP treatment until the top surface of the insulator 281 is exposed.

For steps subsequent to the formation of the conductor 240 (steps subsequent to and including the formation of the opening portion 290), the description in <Example 1 of method for manufacturing memory device> above can be referred to.

Through the above process, the memory device including the memory cell 150 illustrated in FIG. 20A to FIG. 20C can be manufactured. In addition, the memory device including the transistor 200 and the capacitor 100 illustrated in FIG. 20A to FIG. 20C can be manufactured.

According to one embodiment of the present invention, a novel transistor, a novel semiconductor device, and a novel memory device can be provided. A memory device that can be miniaturized or highly integrated can be provided. A memory device with favorable frequency characteristics can be provided. A memory device with high operation speed can be provided. A memory device with high reliability can be provided. A memory device with low power consumption can be provided. A memory device including a transistor with a high on-state current can be provided. A memory device with a small variation in transistor characteristics can be provided. A memory device with favorable electrical characteristics can be provided.

The memory cell 150 including the transistor 200 and the capacitor 100 described in this embodiment can be used as a memory cell of the memory device. The transistor 200 is a transistor in which a channel is formed in a semiconductor layer containing an oxide semiconductor. Since the transistor 200 has a low off-state current, a memory device that uses the transistor 200 can retain stored contents for a long time. In other words, such a memory device does not require refresh operation or has extremely low frequency of the refresh operation, which leads to a sufficient reduction in power consumption of the memory device. The transistor 200 also has high frequency characteristics and thus enables high-speed reading and writing of the memory device.

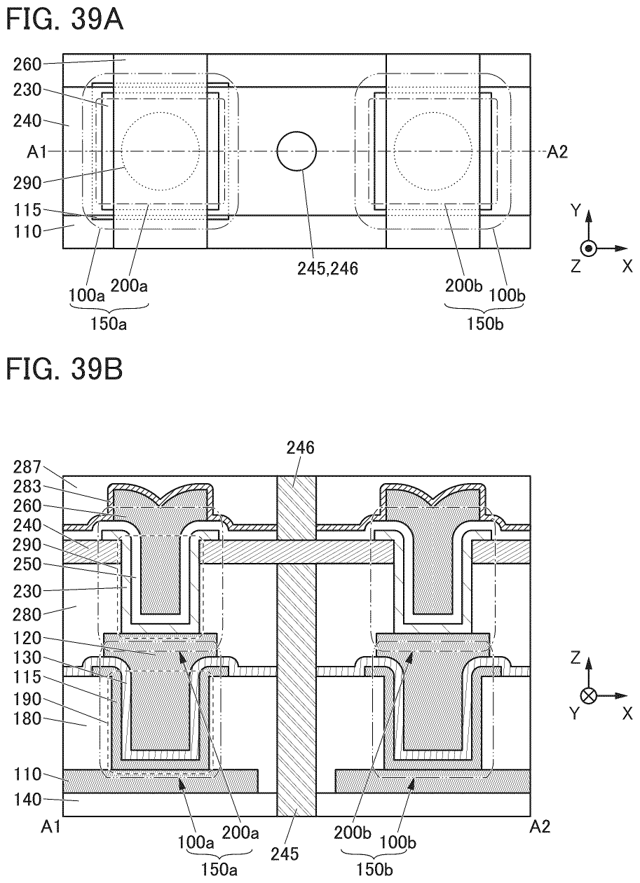

An example of a memory device in which two memory cells 150 (hereinafter referred to as a memory cell 150a and a memory cell 150b) are connected to a common wiring is described with reference to FIG. 39A and FIG. 39B. FIG. 39A is a plan view of the memory device. FIG. 39B is a cross-sectional view of a portion indicated by the dashed-dotted line A1-A2 in FIG. 39A. For the sake of clarity of the drawing, some components are omitted in the plan view of FIG. 39A.

Here, the memory cell 150a and the memory cell 150b illustrated in FIG. 39A and FIG. 39B each have a structure similar to that of the memory cell 150. The memory cell 150a includes a capacitor 100a and a transistor 200a, and the memory cell 150b includes a capacitor 100b and a transistor 200b. Thus, in the memory device illustrated in FIG. 39A and FIG. 39B, components having the same functions as the components of the memory device illustrated in FIG. 1 are denoted by the same reference numerals. In addition, the materials described in detail in <Structure example of memory device> can be used as component materials of the memory devices also in this section.

As illustrated in FIG. 39A and FIG. 39B, the conductor 260 functioning as the wiring WL is provided in each of the memory cell 150a and the memory cell 150b. The conductor 240 functioning as part of the wiring BL is provided to be shared by the memory cell 150a and the memory cell 150b. That is, the conductor 240 is in contact with the oxide semiconductor 230 of the memory cell 150a and the oxide semiconductor 230 of the memory cell 150b.

Here, the memory device illustrated in FIG. 39A and FIG. 39B includes a conductor 245 and a conductor 246 functioning as plugs (also can be referred to as connection electrodes) electrically connected to the memory cell 150a and the memory cell 150b. The conductor 245 is placed in an opening formed in the insulator 180, the insulator 130, the insulator 280, and the insulator 140 and is in contact with the bottom surface of the conductor 240. The conductor 246 is placed in an opening portion formed in the insulator 287, the insulator 283, and the insulator 250 and is in contact with the top surface of the conductor 240. In addition, a conductive material or the like usable for the conductor 240 can be used for the conductor 245 and the conductor 246.

The insulator 287 functions as an interlayer film and thus preferably has low relative permittivity. When a material with low relative permittivity is used for an interlayer film, parasitic capacitance generated between wirings can be reduced. As the insulator 287, a single layer or stacked layers of the insulators containing any of the materials with low relative permittivity described in the above-described section [Insulator] can be used.

The concentration of impurities such as water and hydrogen in the insulator 287 is preferably reduced. This can inhibit entry of impurities such as water and hydrogen into the channel formation region of the oxide semiconductor 230.

Here, the conductor 245 and the conductor 246 function as plugs or wirings for electrically connecting the memory cell 150a and the memory cell 150b to a circuit element such as a switch, a transistor, a capacitor, an inductor, a resistor, or a diode, a wiring, an electrode, or a terminal. For example, the conductor 245 can be electrically connected to a sense amplifier (not illustrated) provided below the memory device illustrated in FIG. 39, and the conductor 246 can be electrically connected to a similar memory device (not illustrated) provided above the memory device illustrated in FIG. 39. In that case, the conductor 245 and the conductor 246 function as part of the wiring BL. When the memory device or the like is provided above or below the memory device illustrated in FIG. 39 in this manner, the memory capacity per unit area can be increased.

The memory cell 150a and the memory cell 150b have a line-symmetric structure with a perpendicular bisector of the dashed-dotted line A1-A2 as the symmetric axis. Thus, the transistor 200a and the transistor 200b are also placed line-symmetrically with the conductor 245 and the conductor 246 therebetween. Here, the conductor 240 has a function of the other of the source electrode and the drain electrode of the transistor 200a and a function of one of a source electrode and a drain electrode of the transistor 200b. The transistor 200a and the transistor 200b share the conductor 245 and the conductor 246 functioning as plugs. With the above connection structure between the two transistors and the plugs, a memory device that can be miniaturized or highly integrated can be provided.

Note that the conductor 110 functioning as the wiring PL may be provided in each of the memory cell 150a and the memory cell 150b or may be provided to be shared by the memory cell 150a and the memory cell 150b. However, as illustrated in FIG. 39B, the conductor 110 is provided to be apart from the conductor 245 so that the conductor 110 and the conductor 245 are not short-circuited.

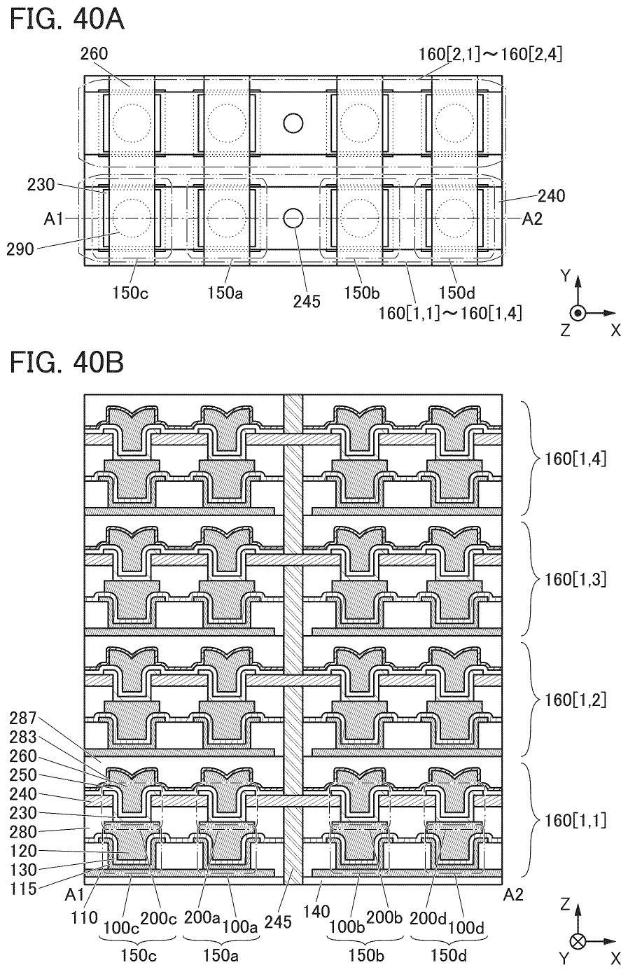

Note that the memory cells 150 can be three-dimensionally arranged in a matrix to form a memory cell array. As an example of the memory cell array, FIG. 40A and FIG. 40B illustrate an example of a memory device in which 4×2×4 memory cells 150 are arranged in the X direction, the Y direction, and the Z direction. FIG. 40A is a plan view of the memory device. In addition, FIG. 40B is a cross-sectional view of a portion indicated by the dashed-dotted line A1-A2 in FIG. 40A. For the sake of clarity of the drawing, some components are omitted in the plan view in FIG. 40A.

Here, the memory cell 150a to a memory cell 150d illustrated in FIG. 40A and FIG. 40B each have a structure similar to that of the memory cell 150. The memory cell 150a includes the capacitor 100a and the transistor 200a, the memory cell 150b includes the capacitor 100b and the transistor 200b, the memory cell 150c includes a capacitor 100c and a transistor 200c, and the memory cell 150d includes a capacitor 100d and a transistor 200d. Thus, in the memory device illustrated in FIG. 40A and FIG. 40B, components having the same functions as the components of the memory device illustrated in FIG. 1 are denoted by the same reference numerals. In addition, the materials described in detail in <Structure example of memory device> can be used as component materials of the memory devices also in this section.

Hereinafter, a memory device including the memory cell 150a to the memory cell 150d is referred to as a memory unit. The memory device illustrated in FIG. 40A and FIG. 40B each include a memory unit 160[1,1] to a memory unit 160[2,4]. Hereinafter, the memory unit 160[1,1] to the memory unit 160[2,4] are collectively referred to as a memory unit 160 in some cases. The memory unit 160[1,2] is provided over the memory unit 160[1,1], the memory unit 160[1,3] is provided over the memory unit 160[1,2], and the memory unit 160[1,4] is provided over the memory unit 160[1,3]. The memory unit 160[2,1] is provided to be adjacent to the memory unit 160[1,1] in the Y direction. The memory unit 160[2,2] is provided over the memory unit 160[2,1], the memory unit 160[2,3] is provided over the memory unit 160[2,2], and the memory unit 160[2,4] is provided over the memory unit 160[2,3].

In the memory unit 160, as illustrated in FIG. 40B, with the conductor 245 as the center the memory cell 150c is placed outwardly from the memory cell 150a, and the memory cell 150d is placed outwardly from the memory cell 150b. In other words, the memory unit 160 can be regarded as a memory device in which the memory cell 150c is provided adjacent to the memory cell 150a and the memory cell 150d is provided adjacent to the memory cell 150b in the memory device illustrated in FIG. 39.

As illustrated in FIG. 40A and FIG. 40B, the conductor 260 functioning as the wiring WL is shared by the memory cells 150 adjacent to each other in the Y direction. The conductor 240 functioning as part of the wiring BL is shared in the same memory unit. That is, the conductor 240 is in contact with the oxide semiconductor 230 of each of the memory cell 150a to the memory cell 150d.

The conductor 245 is provided between the conductors 240 included in the memory units adjacent to each other in the Z direction. For example, as illustrated in FIG. 40B, the conductor 245 is provided in contact with the top surface of the conductor 240 of the memory unit 160[1,1] and the bottom surface of the conductor 240 of the memory unit 160[1,2]. In this manner, the conductor 240 and the conductor 245 provided in the memory unit 160 form the wiring BL. The conductor 245 is electrically connected to a sense amplifier (not illustrated) provided below the memory device illustrated in FIG. 40. As described above, when a plurality of memory units are stacked in the memory device illustrated in FIG. 40, the memory capacity per unit area can be increased.

The memory cell 150a and the memory cell 150c are line-symmetrical to the memory cell 150b and the memory cell 150d with a perpendicular bisector of the dashed-dotted line A1-A2 as the symmetric axis. Thus, the transistor 200a and the transistor 200c are also arranged line-symmetrically to the transistor 200b and the transistor 200d with the conductor 245 therebetween. Here, the conductor 240 serves as the other of the source electrode and the drain electrode of each of the transistor 200a to the transistor 200d. The transistor 200a to the transistor 200d share the conductor 245 functioning as a plug. Accordingly, when the four transistors are connected to the plug as described above, a memory device that can be miniaturized or highly integrated can be provided.

When a plurality of memory cells are stacked as illustrated in FIG. 40, cells can be integrally placed without increasing the area occupied by the memory cell array. In other words, a 3D memory cell array can be formed. Although FIG. 40 illustrate the structure in which four layers each including two memory units are stacked, the present invention is not limited to the structure. The memory device may include one layer including at least one the memory cell 150 or may include two or more stacked layers each including at least one the memory cell 150.

FIG. 40 illustrates a structure in which the conductor 245 functioning as a plug is placed between the memory cells 150. In other words, the conductor 245 functioning as a plug is placed inside the memory unit 160. Note that the present invention is not limited thereto. The conductor 245 may be placed outside the memory unit.

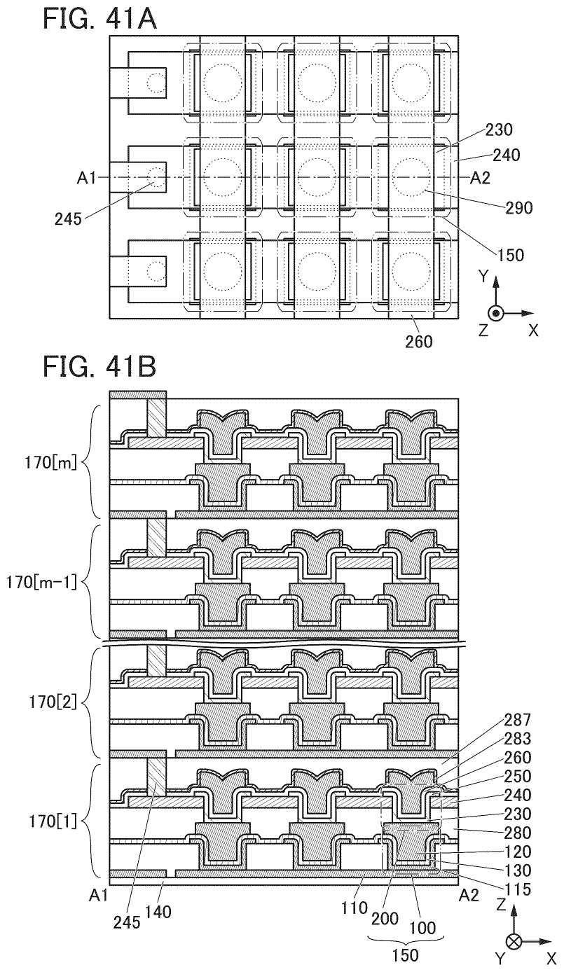

As an example of the memory cell array, FIG. 41A and FIG. 41B illustrate an example of a memory device in which 3×3×4 memory cells 150 are arranged in the X direction, the Y direction, and the Z direction. FIG. 41A is a plan view of the memory device. In addition, FIG. 41B is a cross-sectional view of a portion indicated by the dashed-dotted line A1-A2 in FIG. 41A. Note that for the sake of clarity of the drawing, some components are omitted in the plan view of FIG. 41A.

The memory device illustrated in FIG. 41A and FIG. 41B has a structure in which m layers (m is an integer greater than or equal to 2) each including the memory cells 150 are stacked. Here, in FIG. 41B, the layer provided in the first layer (the lowermost layer) is referred to as a layer 170[1], the layer provided in the second layer is referred to as a layer 170[2], the layer provided in the (m−1)-th layer is referred to as a layer 170[m−1], and the layer provided in the m-th layer (the uppermost layer) is referred to as a layer 170[m]. In other words, the memory device of one embodiment of the present invention may include a plurality of layers including memory cells 150 and have a structure in which the plurality of layers are stacked.

As illustrated in FIG. 41A and FIG. 41B, the conductor 245 may be provided outside the memory unit. The conductor 245 may be electrically connected to a wiring provided in a layer above the layer including the conductor 245. For example, the conductor 245 provided in the layer 170[1] is electrically connected to a wiring provided in the layer 170[2]. In addition, the wiring provided in the layer 170[2] is provided in the same layer as the lower electrode (the conductor 110) of the memory cell 150 included in the layer 170[2]. That is, the wiring can be formed in the same step as the conductor 110.

Although FIG. 41 illustrates a structure in which the conductor 245 is electrically connected to a wiring provided in a layer above the layer including the conductor 245, the present invention is not limited thereto. For example, the conductor 245 may be electrically connected to a wiring provided in the layer including the conductor 245. For example, the conductor 245 provided in the layer 170[1] may be electrically connected to a wiring provided in the layer 170[1]. The wiring provided in the layer 170[1] is provided in the same layer as the lower electrode (the conductor 110) of the memory cell 150 included in the layer 170[1]. That is, the wiring can be formed in the same step as the conductor 110.

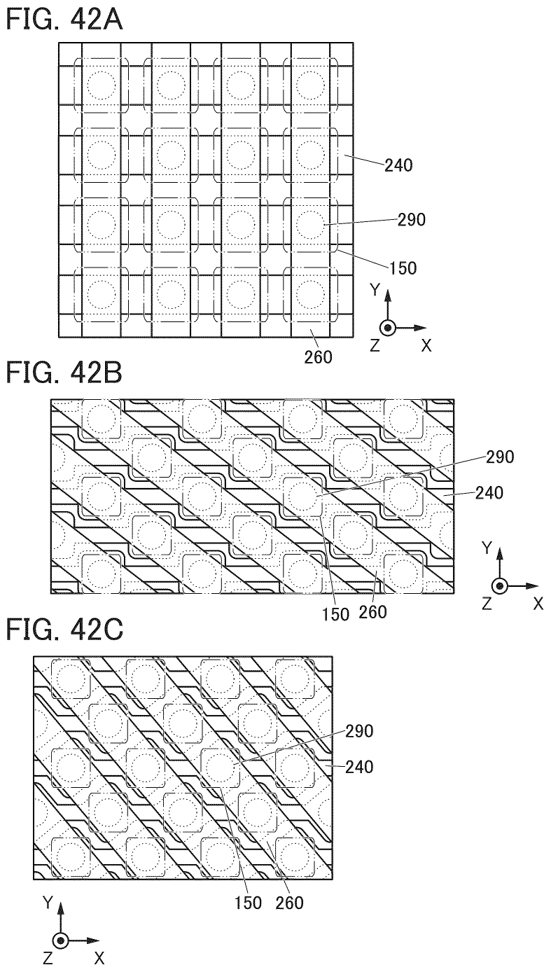

Here, FIG. 42A illustrates a planar layout of the memory device illustrated in FIG. 41A. Specifically, the planar layout in FIG. 42A illustrates a region including 4×4 memory cells 150. In addition, the conductor 260 functioning as the wiring WL, the conductor 240 functioning as the wiring BL, and the opening portion 290 are illustrated. Each of the memory cells 150 is provided in a region where the conductor 260, the conductor 240, and the opening portion 290 overlap with each other. In other words, the opening portion 290 is provided in a region of the conductor 240 where the conductor 240 and the conductor 260 intersect with each other.

FIG. 42A illustrates a structure in which the memory cells 150 are arranged in a matrix. In addition, the opening portions 290 are arranged in a matrix. In addition, the conductor 260 is provided to extend in the Y direction and the conductor 240 is provided to extend in the X direction. In other words, the conductor 260 and the conductor 240 are orthogonal to each other. In addition, the width of the conductor 260 is uniform in the direction (X direction) perpendicular to the extending direction of the conductor 260, and the width of the conductor 240 is uniform in the direction (Y direction) perpendicular to the extending direction of the conductor 240. Note that the present invention is not limited thereto.

FIG. 42B is another example of a planar layout of the memory device. In the planar layout of FIG. 42B, the conductor 260, the conductor 240, the memory cell 150, and the opening portion 290 are illustrated as in FIG. 42A. The memory device illustrated in FIG. 42B is different from the memory device illustrated in FIG. 42A mainly in the arrangement of the memory cells 150 (the opening portions 290), the shape of the conductor 240, and the extending direction of the conductor 260.

As illustrated in FIG. 42B, the memory cells 150 (the opening portions 290) may be arranged to be shifted by half of the repeating unit between the odd-numbered columns and the even-numbered columns. The memory cells 150 (the opening portions 290) are arranged to be shifted by half of the repeating unit between the odd-numbered columns and the even-numbered columns.

In FIG. 42B, a memory cell adjacent to a first memory cell in the X direction is referred to as a second memory cell, and a memory cell adjacent to the first memory cell and the second memory cell in the Y direction is referred to as a third memory cell. For example, it is preferable that the center of the third memory cell be positioned on a straight line that is parallel to the Y direction and passes midway between the first memory cell and the second memory cell. In this case, it can be said that the third memory cell is positioned at a position shifted by half in the X direction from the first memory cell and the second memory cell.

As illustrated in FIG. 42B, the conductor 240 includes a first region and a second region. The first region is a region including the opening portion 290 and the vicinity thereof, and the width in the Y direction of the first region is referred to as a first width. In the plan view, the first region can be regarded as having a quadrangular shape with rounded corners. The second region is a region between the adjacent opening portions 290 in one the conductor 240, and the width in the Y direction of the second region is referred to as a second width. In this case, the second width is preferably smaller than the first width. Such a structure enables the physical distance between the conductors 240 to be reduced in the case where the memory cells 150 (opening portions 290) are arranged to be shifted by half of the repeating unit between the odd-numbered columns and the even-numbered columns. Accordingly, miniaturization and high integration of the memory device can be achieved.

In FIG. 42B, the extending direction of the conductor 260 is inclined relative to the Y direction. That is, the extending direction of the conductor 260 is not orthogonal to the extending direction of the conductor 240 in some cases depending on the arrangement of the memory cells 150 (the opening portions 290). In other words, the conductor 260 preferably intersects with the conductor 240.

FIG. 42C is another example of a planar layout of the memory device. In the planar layout in FIG. 42C, the conductor 260, the conductor 240, the memory cell 150, and the opening portion 290 are illustrated as in FIG. 42B. The memory device illustrated in FIG. 42C is different from the memory device illustrated in FIG. 42B mainly in the shape of the first region of the conductor 240.

The first region of the conductor 240 illustrated in FIG. 42B has a quadrangular shape with rounded corners in the plan view, and one side of the quadrangular shape is parallel to the X direction or the Y direction. Meanwhile, the first region of the conductor 240 illustrated in FIG. 42C has a quadrangular shape with rounded corners in the plan view, and the diagonal of the quadrangular shape is parallel to the X direction or the Y direction. Such a structure enables the physical distance between the conductors 240 to be reduced in the case where the memory cells 150 (opening portions 290) are arranged to be shifted by half of the repeating unit between the odd-numbered columns and the even-numbered columns. Accordingly, miniaturization and high integration of the memory device can be achieved.

Although FIG. 42B and FIG. 42C each illustrate an example in which the first region of the conductor 240 has a quadrangular shape with rounded corners in the plan view, the present invention is not limited thereto.

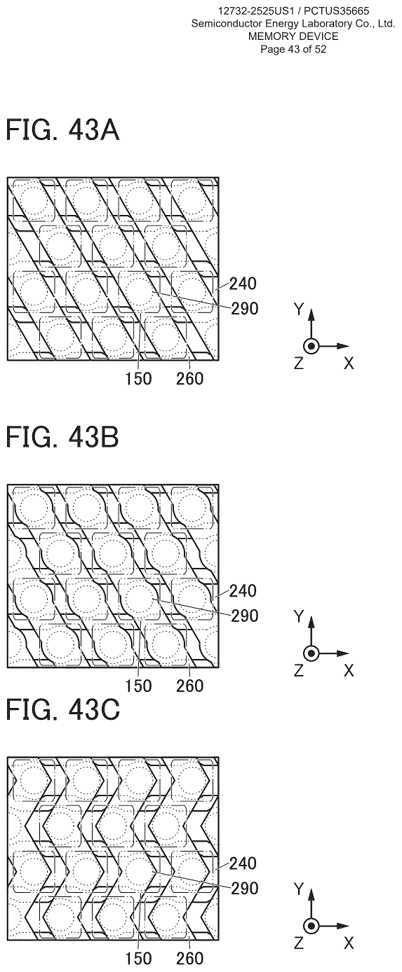

FIG. 43A is another example of a planar layout of the memory device. In the planar layout of FIG. 43A, the conductor 260, the conductor 240, the memory cell 150, and the opening portion 290 are illustrated as in FIG. 42B. The memory device illustrated in FIG. 43A is different from the memory device illustrated in FIG. 42B or FIG. 42C mainly in the shape of the first region of the conductor 240.

The first region of the conductor 240 illustrated in FIG. 43A has a circular shape in the plan view. Such a structure enables the physical distance between the conductors 240 to be reduced in the case where the memory cells 150 (opening portions 290) are arranged to be shifted by half of the repeating unit between the odd-numbered columns and the even-numbered columns. Accordingly, miniaturization and high integration of the memory device can be achieved.

Note that the shape of the first region of the conductor 240 in the plan view is not limited to the above-described shapes. For example, the first region of the conductor 240 in the plan view may have a substantially circular shape such as an elliptical shape, a polygonal shape such as a quadrangular shape, or a polygonal shape such as a quadrangular shape with rounded corners. Although FIG. 43A illustrates the structure in which the width of the conductor 260 is uniform in the direction perpendicular to the extending direction of the conductor 260, the present invention is not limited to the structure.

FIG. 43B is another example of a planar layout of the memory device. In the planar layout of FIG. 43B, the conductor 260, the conductor 240, the memory cell 150, and the opening portion 290 are illustrated as in FIG. 43A. The memory device illustrated in FIG. 43B is different from the memory device illustrated in FIG. 43A mainly in the shape of the conductor 260.

Like the conductor 240, the conductor 260 illustrated in FIG. 43B includes a first region and a second region. The first region is a region including the opening portion 290 and the vicinity thereof and has a circular shape in the plan view. The second region is a region between adjacent opening portions 290 in one the conductor 260. The first region of the conductor 260 overlaps with the first region of the conductor 240. Such a structure enables the physical distance between the conductors 240 to be reduced in the case where the memory cells 150 (opening portions 290) are arranged to be shifted by half of the repeating unit between the odd-numbered columns and the even-numbered columns. Accordingly, miniaturization and high integration of the memory device can be achieved.

FIG. 43C is another example of a planar layout of the memory device. In the planar layout of FIG. 43C, the conductor 260, the conductor 240, the memory cell 150, and the opening portion 290 are illustrated as in FIG. 43A. The memory device illustrated in FIG. 43C is different from the memory device illustrated in FIG. 43A mainly in the shape and the extending direction of the conductor 260.

The conductor 260 illustrated in FIG. 43C has a serpentine shape like a triangular-wave in the plan view and is provided to extend in the Y direction. Such a structure enables the physical distance between the conductors 240 to be reduced in the case where the memory cells 150 (opening portions 290) are arranged to be shifted by half of the repeating unit between the odd-numbered columns and the even-numbered columns. Accordingly, miniaturization and high integration of the memory device can be achieved. Note that the conductor 260 in the plan view is not limited to the above, and may have a meander shape or the like.

The above structure can shorten one or both of the physical distance between the conductors 260 and the physical distance between the conductors 240, in which case the memory device can be miniaturized and highly integrated.

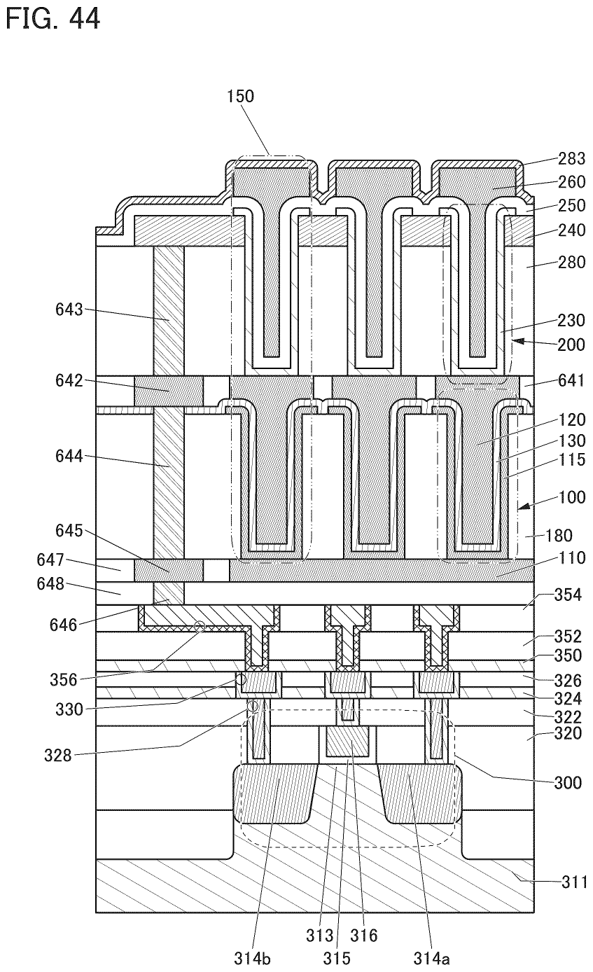

FIG. 44 illustrates a cross-sectional structure example of a memory device where a layer including a memory cell is stacked over a layer including a driver circuit provided with a sense amplifier.

In the memory device illustrated in FIG. 44, the capacitor 100 is provided above a transistor 300, and the transistor 200 is provided above the transistor 300 and the capacitor 100.

The transistor 300 is one of the transistors included in the sense amplifier.

The structure of the memory cell 150 (the transistor 200 and the capacitor 100) illustrated in FIG. 44 are as described above.

When the sense amplifier is provided to overlap with the memory cell 150 as illustrated in FIG. 44, the bit line can be shortened. This reduces bit line capacitance, which can reduce the storage capacitance of the memory cell.

When the transistor 200 is provided above the capacitor 100, the transistor 200 is not affected by heat treatment in manufacturing the capacitor 100. Thus, in the transistor 200, degradation of the electrical characteristics such as variation in threshold voltage or an increase in parasitic resistance, and an increase in variation in electrical characteristics due to the degradation of the electrical characteristics can be inhibited.

The memory device illustrated in FIG. 44 can correspond to a memory device 80 described in Embodiment 2. Specifically, the transistor 300 corresponds to a transistor included in a sense amplifier 46 in the memory device 80. The memory cell 150 corresponds to a memory cell 32, the transistor 200 corresponds to a transistor 37, and the capacitor 100 corresponds to a capacitor 38.

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 44, the semiconductor region 313 (part of the substrate 311) where a channel is formed has a protruding shape. Furthermore, the conductor 316 is provided to cover the side surface and top surface of the semiconductor region 313 with the insulator 315 therebetween. Note that the conductor 316 may be formed using a material for adjusting the work function. Such a transistor 300 is also referred to as a FIN-type transistor because it utilizes the protruding portion of the semiconductor substrate. Note that an insulator functioning as a mask for forming the protruding portion may be included in contact with an upper portion of the protruding portion. Although the case where the protruding portion is formed by processing part of the semiconductor substrate is described here, a semiconductor film having a protruding shape may be formed by processing an SOI substrate.

Note that the transistor 300 illustrated in FIG. 44 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with the design. Here, a plurality of conductors functioning as a plug or a wiring are collectively denoted by the same reference numeral in some cases. Moreover, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 300 as an interlayer film. A conductor 328 is embedded in the insulator 320 and the insulator 322, and a conductor 330 is embedded in the insulator 324 and the insulator 326. Note that the conductor 328 and the conductor 330 function as a plug or a wiring.

The insulator functioning as an interlayer film may function as a planarization film that covers an uneven shape thereunder. For example, the top surface of the insulator 322 may be planarized through planarization treatment using a CMP method or the like to increase the level of planarity.

A wiring layer may be provided over the insulator 326 and the conductor 330. For example, in FIG. 44, an insulator 350, an insulator 352, and an insulator 354 are stacked in this order. Furthermore, a conductor 356 is formed in the insulator 350, the insulator 352, and the insulator 354. The conductor 356 functions as a plug or a wiring.

As the insulator 352, the insulator 354, and the like functioning as interlayer films, the above-described insulator that can be used for the memory device can be used.

As the conductor functioning as a plug or a wiring, such as the conductor 328, the conductor 330, and the conductor 356, a conductor described above in [Conductor] can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

The conductor 240 included in the transistor 200 is electrically connected to the low-resistance region 314b functioning as a source region or a drain region of the transistor 300 through a conductor 643, a conductor 642, a conductor 644, a conductor 645, a conductor 646, the conductor 356, the conductor 330, and the conductor 328.

The conductor 643 is embedded in the insulator 280. The conductor 642 is provided over the insulator 130 and is embedded in an insulator 641. The conductor 642 and the conductor 120 can be formed using the same material in the same step. The conductor 644 is embedded in the insulator 180 and the insulator 130. The conductor 645 is embedded in an insulator 647. The conductor 645 and the conductor 110 can be formed using the same material in the same step. The conductor 646 is embedded in an insulator 648. The transistor 300 and the conductor 110 are electrically insulated from each other by the insulator 648.

According to one embodiment of the present invention, a novel transistor, a novel semiconductor device, and a novel memory device can be provided. Alternatively, a transistor, a semiconductor device, and a memory device that are capable of being miniaturized or highly integrated can be provided. Alternatively, a transistor, a semiconductor device, and a memory device that have high reliability can be provided. Alternatively, a transistor having a high on-state current and a semiconductor device and a memory device that include the transistor can be provided. Alternatively, a semiconductor device and a memory device that have a small variation in transistor characteristics can be provided. Alternatively, a transistor with favorable electrical characteristics and a semiconductor device and a memory device that include the transistor can be provided. Alternatively, a semiconductor device and a memory device that have low power consumption can be provided. A memory device with favorable frequency characteristics can be provided. A memory device with high operation speed can be provided.

This embodiment can be combined with the other embodiments and the examples as appropriate.

### EMBODIMENT 2

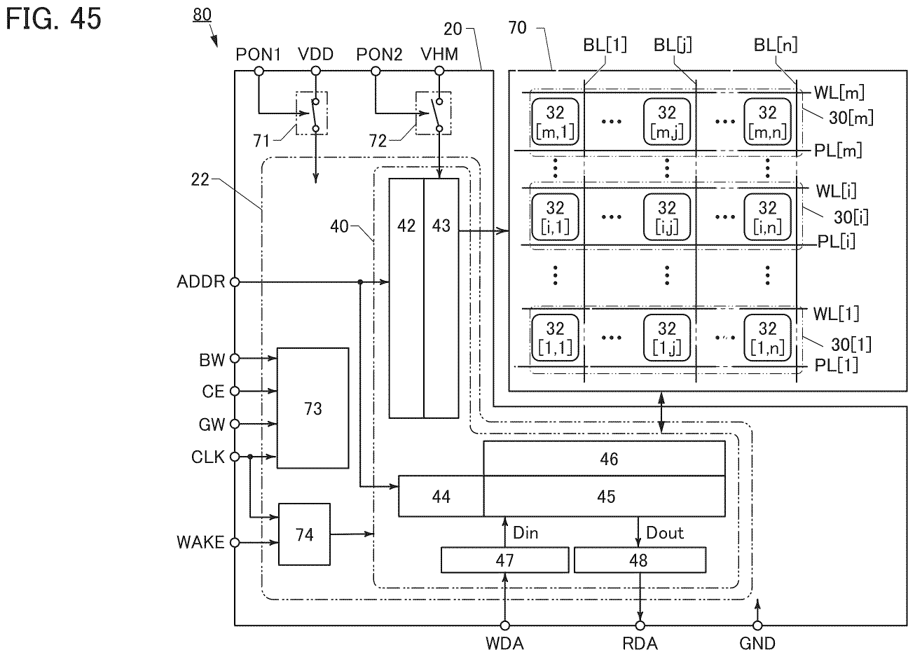

In this embodiment, a memory device of one embodiment of the present invention will be described with reference to FIG. 45 to FIG. 48. This embodiment describes a structure example of a memory device in which a layer including a memory cell is stacked over a layer including a driver circuit including a sense amplifier.

### <Structure Example 3 of Memory Device>

FIG. 45 is a block diagram illustrating a structure example of the memory device 80 of one embodiment of the present invention. The memory device 80 illustrated in FIG. 45 includes a layer 20 and a stacked layer 70.

The layer 20 is a layer including Si transistors. In the stacked layer 70, element layers 30[1] to 30[m] (m is an integer greater than or equal to 2) are stacked. The element layers 30[1] to 30[m] each include an OS transistor. The layer 70 in which the layers including OS transistors are stacked can be stacked over the layer 20.

Elements such as the OS transistor and the capacitor included in each of the element layers 30[1] to 30[m] form a memory cell. FIG. 45 illustrates an example in which the element layers 30[1] to 30[m] include a plurality of the memory cells 32 arranged in a matrix of m rows and n columns (n is an integer greater than or equal to 2).

In FIG. 45, the memory cell 32 in the first row and the first column is denoted as a memory cell 32[1,1], and the memory cell 32 in the m-th row and the n-th column is denoted as a memory cell 32[m, n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 32 in the i-th row and the j-th column is denoted as a memory cell 32[i] . In this embodiment and the like, “i+α” (α is a positive or negative integer) is not below 1 and does not exceed m. Similarly, “j+α” is not below 1 and does not exceed n.

FIG. 45 illustrates m wirings WL extending in the row direction, m wirings PL extending in the row direction, and n wirings BL extending in the column direction, for example. In this embodiment and the like, the first (first row) wiring WL is referred to as a wiring WL[1] and the m-th (m-th row) wiring WL is referred to as a wiring WL[m]. Similarly, the first (first row) wiring PL is referred to as a wiring PL[1] and the m-th (m-th row) wiring PL is referred to as a wiring PL[m]. Similarly, the first (first column) wiring BL is referred to as a wiring BL[1] and the n-th (n-th column) wiring BL is referred to as a wiring BL[n]. Note that the number of the element layers 30[1] to 30[m] is not necessarily the same as the number of the wirings WL (and the wirings PL).

A plurality of memory cells 32 provided in the i-th row are electrically connected to the wiring WL in the i-th row (wiring WL[i]) and the wiring PL in the i-th row (wiring PL[i]). A plurality of memory cells 32 provided in the j-th column are electrically connected to the wiring BL in the j-th column (wiring BL[j]).

The wiring BL functions as a bit line for writing and reading data. The wiring WL functions as a word line for controlling on or off (a conduction state or a non-conduction state) of the access transistor serving as a switch. The wiring PL has a function of a constant potential line connected to a capacitor. Note that a wiring CL (not illustrated) can be separately provided as a wiring for transmitting the back gate potential.

The memory cell 32 included in each of the element layers 30[1] to 30[m] is connected to the sense amplifier 46 through the wiring BL. The wirings BL can be provided in the direction horizontal and the direction perpendicular to the surface of the substrate provided with the element layer 20. When the wirings BL provided to extend from the memory cells 32 included in the element layers 30[1] to 30[m] are formed of the wiring provided in the direction perpendicular to the substrate surface in addition to the wiring provided in the direction horizontal to the substrate surface, the length of the wiring between the element layer 30 and the sense amplifier 46 can be reduced. The signal transmission distance between the memory cell and the sense amplifier can be reduced, and the resistance and parasitic capacitance of the bit line can be significantly reduced, so that power consumption and signal delays can be reduced. Accordingly, power consumption and signal delays of the memory device 80 can be reduced. Moreover, operation is possible even when the capacitance of the capacitors included in the memory cells 32 is reduced. Accordingly, the memory device 80 can be downsized.

The element the layer 20 includes a PSW 71 (power switch), a PSW 72, and the peripheral circuit 22. The peripheral circuit 22 includes a driver circuit 40, a control circuit 73, and a voltage generation circuit 74. Each of the circuits included in the layer 20 is a circuit including a Si transistor.

In the memory device 80, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 73.

The control circuit 73 is a logic circuit having a function of controlling the entire operation of the memory device 80. For example, the control circuit performs a logical operation on the signal CE, the signal GW, and the signal BW to determine an operation mode (e.g., a writing operation or a reading operation) of the memory device 80. Alternatively, the control circuit 73 generates a control signal for the driver circuit 40 so that the operation mode is executed.

The voltage generation circuit 74 has a function of generating a negative voltage. The signal WAKE has a function of controlling the input of the signal CLK to the voltage generation circuit 74. For example, when an H-level signal is supplied as the signal WAKE, the signal CLK is input to the voltage generation circuit 74, and the voltage generation circuit 74 generates a negative voltage.

The driver circuit 40 a circuit for writing and reading data to/from the memory cells 32. The driver circuit 40 includes the above-described sense amplifier 46 in addition to a row decoder 42, a column decoder 44, a row driver 43, a column driver 45, an input circuit 47, and an output circuit 48.

The row decoder 42 and the column decoder 44 have a function of decoding the signal ADDR. The row decoder 42 is a circuit for addressing a row to be accessed, and the column decoder 44 is a circuit for addressing a column to be accessed. The row driver 43 has a function of selecting the wiring WL addressed by the row decoder 42. The column driver 45 has a function of writing data to the memory cells 32, a function of reading data from the memory cells 32, a function of retaining the read data, and the like.

The input circuit 47 has a function of retaining the signal WDA. Data retained by the input circuit 47 is output to the column driver 45. Data output from the input circuit 47 is data (Din) to be written to the memory cells 32. Data (Dout) read from the memory cells 32 by the column driver 45 is output to the output circuit 48. The output circuit 48 has a function of retaining Dout. In addition, the output circuit 48 has a function of outputting Dout to the outside of the memory device 80. Data output from the output circuit 48 is the signal RDA.

The PSW 71 has a function of controlling supply of VDD to the peripheral circuit 22. The PSW 72 has a function of controlling supply of VHM to the row driver 43. Here, in the memory device 80, a high power supply voltage is VDD and a low power supply voltage is GND (a ground potential). In addition, VHM is a high power supply voltage used to set a word line at a high level and is higher than VDD. The on/off state of the PSW 71 is controlled by the signal PON1, and the on/off state of the PSW 72 is controlled by the signal PON2. The number of power domains to which VDD is supplied is one in the peripheral circuit 22 in FIG. 45 but can be more than one. In that case, a power switch can be provided for each power domain.

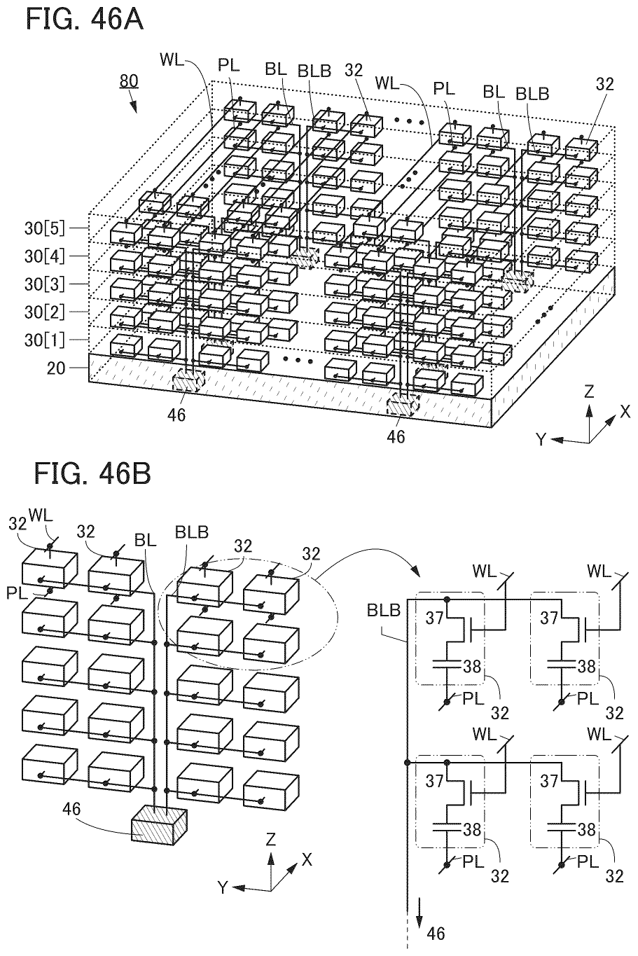

The element layers 30[1] to 30[m] can be provided over the element layer 20 to overlap with the element layer 20. FIG. 46A is a perspective view of the memory device 80 in which five element layers 30[1] to 30[5] (m=5) are provided over the element layer 20 to overlap with the element layer 20.

In FIG. 46A, the element layer 30 provided in the first layer is denoted as an element layer 30[1], the element layer 30 provided in the second layer is denoted as an element layer 30[2], and the element layer 30 provided in the fifth layer is denoted as an element layer 30[5]. FIG. 46A also illustrates the wiring WL and the wiring PL provided to extend in the X direction and the wiring BL and a wiring BLB provided to extend in the Y direction and the Z direction (the directions perpendicular to the surface of the substrate provided with the driver circuit). The wiring BLB is an inverted bit line. For easy viewing of the drawing, some of the wirings WL and the wirings PL included in the element layers 30 are not illustrated.

FIG. 46B is a schematic view illustrating a structure example of the sense amplifier 46 connected to the wiring BL and the wiring BLB illustrated in FIG. 46A, and the memory cells 32 included in the element layers 30[1] to 30[5], which are connected to the wiring BL and the wiring BLB. A structure in which a plurality of memory cells (the memory cells 32) are electrically connected to the wiring BL and the wiring BLB is referred to as a “memory string”.

FIG. 46B illustrates an example of a circuit structure of the memory cells 32 connected to the wiring BLB. The memory cell 32 includes the transistor 37 and the capacitor 38. As for the transistor 37, the capacitor 38, and the wirings (BL, WL, and the like), for example, the wiring BL[1] and the wiring WL[1] are referred to as the wiring BL and the wiring WL in some cases. As the memory cell 32, the memory cell 150 described in the above embodiment can be used, for example. That is, the transistor 200 can be used as the transistor 37, and the capacitor 100 can be used as the capacitor 38. As the transistor included in the sense amplifier 46, the transistor 300 (see FIG. 44) can be used.

In the memory cell 32, one of a source and a drain of the transistor 37 is connected to the wiring BL. The other of the source and the drain of the transistor 37 is connected to one electrode of the capacitor 38. The other electrode of the capacitor 38 is connected to the wiring PL. A gate of the transistor 37 is connected to the wiring WL.

The wiring PL is a wiring for supplying a fixed potential for retaining a potential of the capacitor 38. When a plurality of wirings PL are connected to each other as one wiring, the number of wirings can be reduced.

In one embodiment of the present invention, OS transistors are provided in stacked layers and a wiring functioning as a bit line is provided in the direction perpendicular to the surface of the substrate provided with the layer 20. In addition, the transistor 37 and the capacitor 38 included in the memory cell 32 are arranged in the direction perpendicular to the surface of the substrate provided with the layer 20. When the elements and the wirings are provided in the direction perpendicular to the substrate surface, the length of the wirings between the element layers can be shortened and the density of the elements provided per unit area can be increased. Accordingly, the memory device can have high memory capacity and low power consumption.

### [Structure Example of Memory Cell 32 and Sense Amplifier 46]

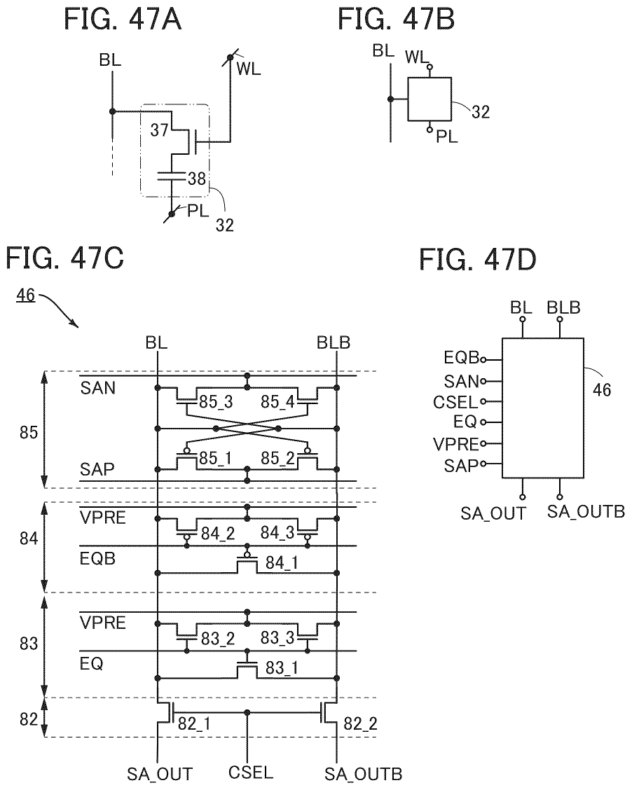

FIG. 47A and FIG. 47B are respectively a circuit diagram corresponding to the above-described memory cell 32 and a diagram illustrating a circuit block corresponding to the circuit diagram. As illustrated in FIG. 47A and FIG. 47B, the memory cell 32 is sometimes illustrated as a block in a drawing or the like. Moreover, in the case where the wiring BL illustrated in FIG. 47A and FIG. 47B is replaced with the wiring BLB, the wiring BLB can be illustrated in a manner similar to that of the wiring BL illustrated in FIG. 47A and FIG. 47B.

FIG. 47C and FIG. 47D are respectively a circuit diagram corresponding to the above-described sense amplifier 46 and a diagram illustrating a circuit block corresponding to the circuit diagram. As the sense amplifier 46, a switch circuit 82, a precharge circuit 83, a precharge circuit 84, and an amplifier circuit 85 are illustrated. In addition, a wiring SA_OUT and a wiring SA_OUTB each of which outputs a read signal are illustrated in addition to the wiring BL and the wiring BLB.

The switch circuit 82 includes, for example, n-channel transistors 82_1 and 82_2, as illustrated in FIG. 47C. The transistors 82_1 and 82_2 switch electrical continuity between the wiring SA_OUT and the wiring BL and between the wiring SA_OUTB and the wiring BLB in response to a signal CSEL; the wiring SA_OUT and the wiring SA_OUTB form a wiring pair and the wiring BL and the wiring BLB form a wiring pair.

The precharge circuit 83 is composed of n-channel transistors 83_1 to 83 3 as illustrated in FIG. 47C. The precharge circuit 83 is a circuit for precharging the wiring BL and the wiring BLB to an intermediate potential VPRE, which corresponds to half of the potential VDD in response to a signal EQ.

The precharge circuit 84 is composed of p-channel transistors 84_1 to 84 3 as illustrated in FIG. 47C. The precharge circuit 84 is a circuit for precharging the wiring BL and the wiring BLB to the intermediate potential VPRE, which corresponds to half of the potential VDD, in response to a signal EQB.

The amplifier circuit 85 is composed of p-channel transistors 85_1 and 85_2 and n-channel transistors 85 3 and 85_4 that are connected to a wiring SAP or a wiring SAN, as illustrated in FIG. 47C. The wiring SAP or the wiring SAN is a wiring having a function of supplying VDD or VSS. The transistors 85_1 to 85 4 are transistors that form an inverter loop.

FIG. 47D illustrates a circuit block corresponding to the sense amplifier 46 described with reference to FIG. 47C and the like. As illustrated in FIG. 47D, the sense amplifier 46 is illustrated as a block in the drawing and the like in some cases.

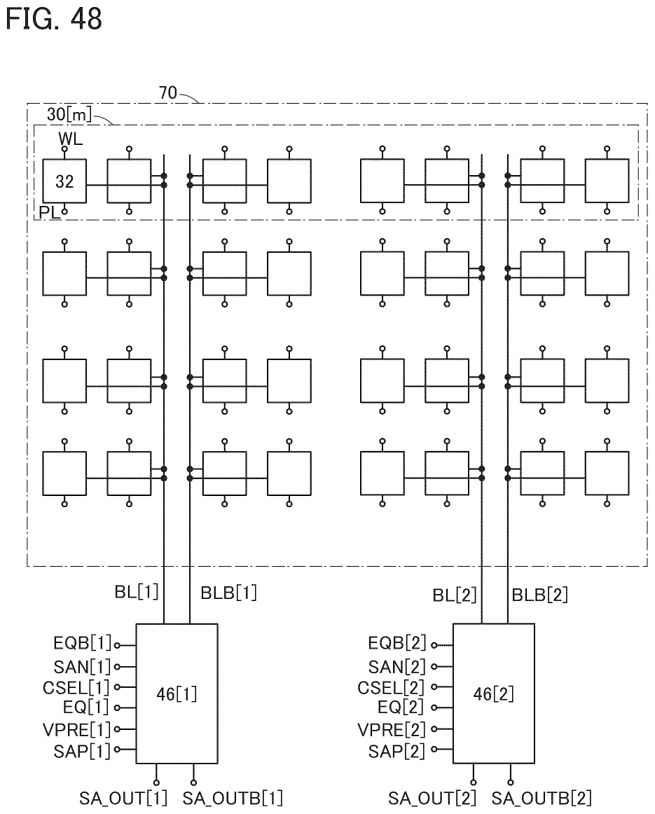

FIG. 48 is a circuit diagram of the memory device 80 in FIG. 45. In FIG. 48, the circuit block illustrated in FIG. 47A and FIG. 47D is used.

As illustrated in FIG. 48, the layer 70 including the element layer 30[m] includes the memory cells 32. The memory cells 32 illustrated in FIG. 48 are connected to a pair of wirings BL[1] and BLB[1] or a pair of wirings BL[2] and BLB[2], for example. The memory cells 32 connected to the wiring BL are memory cells to/from which data is written or read.

The wiring BL[1] and the wiring BLB[1] are connected to a sense amplifier 46[1], and the wiring BL[2] and the wiring BLB[2] are connected to a sense amplifier 46[2]. The sense amplifier 46[1] and the sense amplifier 46[2] can read data in accordance with the various signals described with reference to FIG. 47C.

This embodiment can be combined with the other embodiments and the examples as appropriate.

### EMBODIMENT 3

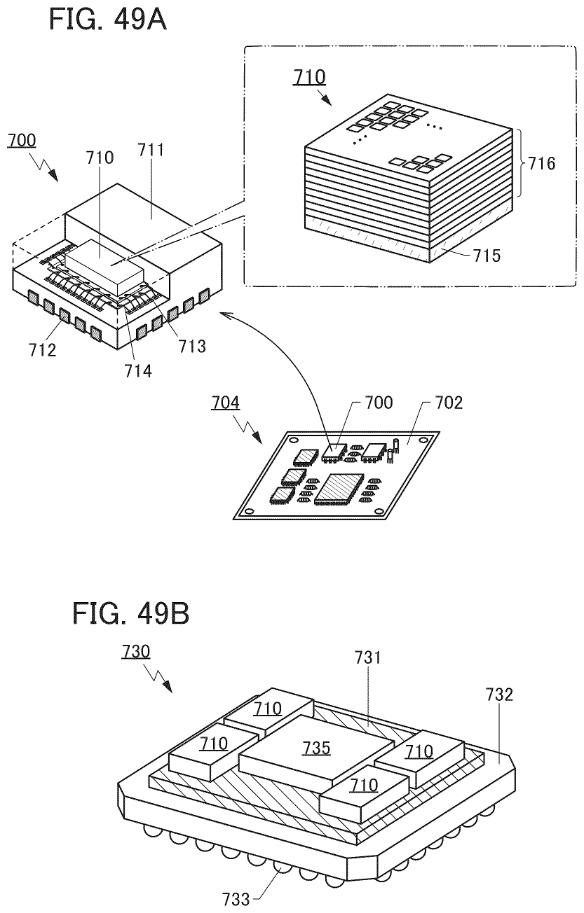

In this embodiment, application examples of the semiconductor device of one embodiment of the present invention is described with reference to FIG. 49 to FIG. 52. The semiconductor device of one embodiment of the present invention can be used for an electronic component, an electronic device, a large computer, space equipment, and a data center (also referred to as DC), for example. An electronic component, an electronic device, a large computer, space equipment, and a data center each using the semiconductor device according to one embodiment of the present invention are effective in achieving high performance, e.g., reducing power consumption.

### [Electronic Component]

FIG. 49A is a perspective view of a substrate (a mounting board 704) on which an electronic component 700 is mounted. The electronic component 700 illustrated in FIG. 49A includes a semiconductor device 710 in a mold 711. FIG. 49A omits part of the electronic component to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the mounting board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that a bandwidth refers to a data transfer volume per unit time, and access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

Next, FIG. 49B illustrates a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU, a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings have a single-layer structure or a multilayer structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 and be used for electrically connecting the integrated circuit and the package substrate 732 in some cases. Moreover, in the case of using a silicon interposer, a TSV can also be used as the through electrode.

An HBM needs to be connected to many wirings to achieve a wide memory bandwidth. Thus, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. In particular, a silicon interposer is preferably used for a 2.5D package (2.5-dimensional packaging) in which a plurality of integrated circuits are arranged side by side on the interposer.

Meanwhile, in the case where a plurality of integrated circuits with different terminal pitches are connected using a silicon interposer, a TSV, and the like, a space for the width of the terminal pitch and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

A heat sink (radiator plate) may be provided to overlap with the electronic component 730. In the case of providing a heat sink, integrated circuits provided on the interposer 731 are preferably level with each other. For example, in the electronic component 730 described in this embodiment, the semiconductor device 710 and the semiconductor device 735 are preferably level with each other.

An electrode 733 may be provided on the bottom portion of the package substrate 732 to mount the electronic component 730 on another substrate. FIG. 49B illustrates an example where the electrode 733 is formed of a solder ball. By providing solder balls in a matrix on the bottom portion of the package substrate 732, BGA (Ball Grid Array) packaging can be achieved. Alternatively, the electrode 733 may be formed of a conductive pin. When conductive pins are provided in a matrix on the bottom portion of the package substrate 732, PGA (Pin Grid Array) packaging can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

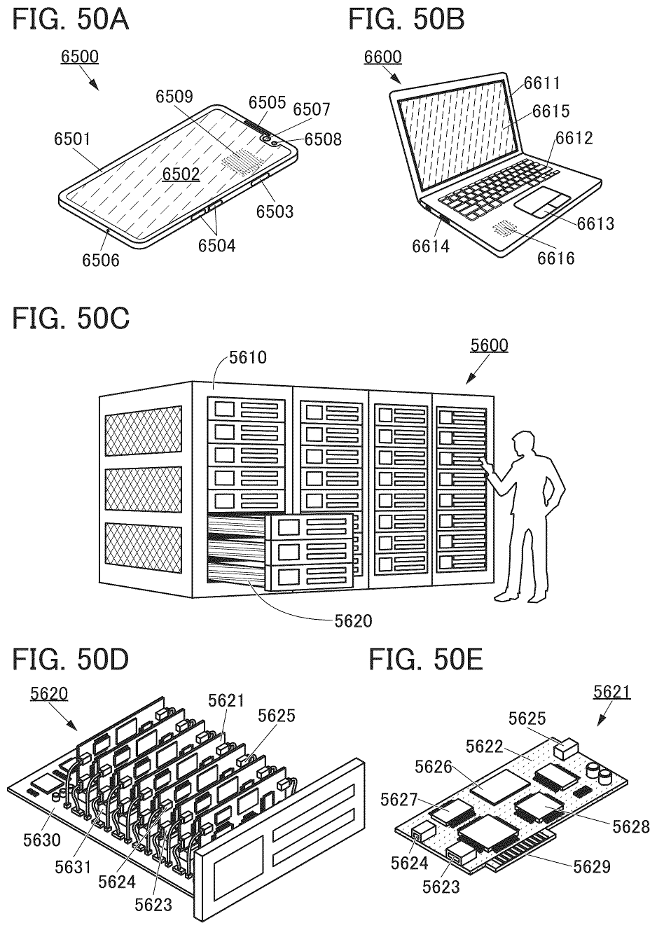

FIG. 50A is a perspective view of an electronic device 6500. The electronic device 6500 illustrated in FIG. 50A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The semiconductor device of one embodiment of the present invention can be used for the display portion 6502, the control device 6509, and the like.

An electronic device 6600 illustrated in FIG. 50B is an information terminal that can be used as a notebook personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a memory device, for example. The semiconductor device of one embodiment of the present invention can be used for the display portion 6615, the control device 6616, and the like. Note that the semiconductor device of one embodiment of the present invention is suitably used for the control device 6509 and the control device 6616, in which case power consumption can be reduced.

### [Large Computer]

FIG. 50C is a perspective view of a large computer 5600. In the large computer 5600 illustrated in FIG. 50C, a plurality of rack mount computers 5620 are stored in a rack 5610. Note that the large computer 5600 may be referred to as a supercomputer.

The computer 5620 can have a structure in a perspective view of FIG. 50D, for example. In FIG. 50D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 50E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 50E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment.

The semiconductor device of one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, the OS transistor can be suitably used in outer space. Specifically, the OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space in this specification may also include one or more of the thermosphere, mesosphere, and stratosphere.

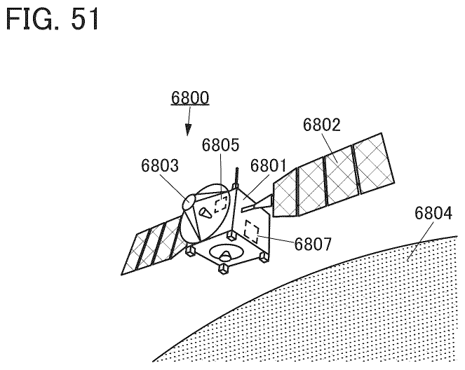

FIG. 51 illustrates an artificial satellite 6800 as an example of space equipment. The artificial satellite 6800 includes a body 6801, a solar panel 6802, an antenna 6803, a secondary battery 6805, and a control device 6807. Note that in FIG. 51, a planet 6804 in outer space is illustrated as an example.

Although not illustrated in FIG. 51, the secondary battery 6805 may be provided with a battery management system (also referred to as a BMS) or a battery control circuit. An OS transistor is suitably used in the battery management system or the battery control circuit because low power consumption and high reliability even in outer space are achieved.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Such a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device that is one embodiment of the present invention and includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can have a function of an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, the OS transistor has excellent effects of achieving wide memory bandwidth and being highly resistant to radiation as compared with the Si transistor.

### [Data Center]

The semiconductor device of one embodiment of the present invention can be suitably used for a storage system in a data center, for example. Long-term management of data, such as guarantee of data immutability, is required for the data center. The management of long-term data needs an increase in building size owing to installation of storages and servers for storing an enormous amount of data, stable electric power for data retention, cooling equipment necessary for data retention, and the like.

With the use of the semiconductor device of one embodiment of the present invention for the storage system used in the data center, electric power required for data retention can be reduced and a semiconductor device retaining data can be downsized. Thus, downsizing of the storage system, downsizing of the power supply for data retention, downscaling of the cooling equipment, and the like can be achieved. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

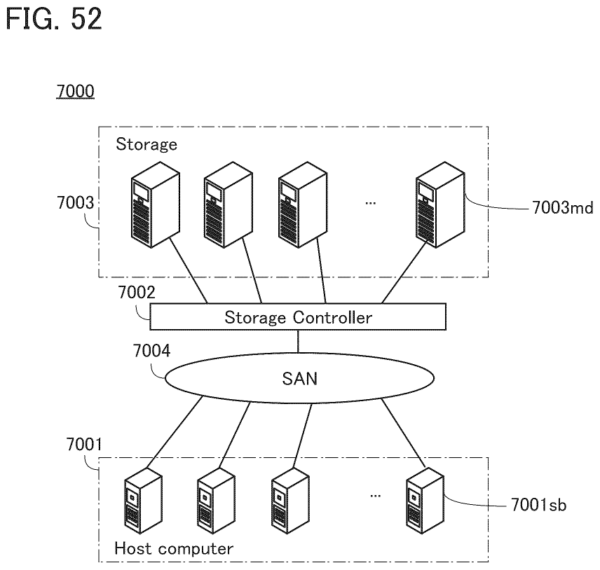

FIG. 52 illustrates a storage system that can be used in a data center. A storage system 7000 shown in FIG. 52 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another the host 7001 through a network.

The data access speed, i.e., the time taken for storing and outputting data, of the storage 7003 is shortened by using a flash memory, but is considerably longer than the data access speed of a DRAM that can be used as a cache memory in the storage. In the storage system, in order to solve the problem of low access speed of the storage 7003, a cache memory is usually provided in the storage to shorten the time taken for storing and outputting data.

The above-described cache memory is used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

With a structure in which an OS transistor is used as a transistor for storing data in the cache memory to retain a potential based on data, the frequency of refreshing can be decreased, so that power consumption can be reduced. Furthermore, downsizing is possible by stacking memory cell arrays.

Note that the use of the semiconductor device of one embodiment of the present invention for one or more selected from an electronic component, an electronic device, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO2) can be reduced with the use of the semiconductor device of one embodiment of the present invention. The semiconductor device of one embodiment of the present invention can be effectively used as one of the global warming countermeasures because of its low power consumption.

This embodiment can be combined with any of the other embodiments as appropriate.

### REFERENCE NUMERALS

BL: wiring, PL: wiring, Tr: transistor, WL: wiring, 20: layer, 22: peripheral circuit, 30: element layer, 32: memory cell, 37: transistor, 38: capacitor, 40: driver circuit, 42: row decoder, 43: row driver, 44: column decoder, 45: column driver, 46[1]: sense amplifier, 46[2]: sense amplifier, 46: sense amplifier, 47: input circuit, 48: output circuit, 70: layer, 71: PSW, 72: PSW, 73: control circuit, 74: voltage generation circuit, 80: memory device, 82_1: transistor, 82_2: transistor, 82: switch circuit, 83_1: transistor, 83_3: transistor, 83: precharge circuit, 84_1: transistor, 84_3: transistor, 84: precharge circuit, 85_1: transistor, 85_2: transistor, 85_3: transistor, 85_4: transistor, 85: amplifier circuit, 100a: capacitor, 100b: capacitor, 100c: capacitor, 100d: capacitor, 100p: capacitor, 100q: capacitor, 100r: capacitor, 100s: capacitor, 100: capacitor, 110: conductor, 115: conductor, 120A: conductive film, 120: conductor, 121A: conductive film, 121: conductor, 122: conductor, 125: conductor, 130: insulator, 135: insulator, 140: insulator, 150a: memory cell, 150b: memory cell, 150c: memory cell, 150d: memory cell, 150: memory cell, 160[1,1]: memory unit, 160[1,2]: memory unit, 160[1,3]: memory unit, 160[1,4]: memory unit, 160[2,1]: memory unit, 160[2,2]: memory unit, 160[2,3]: memory unit, 160[2,4]: memory unit, 160: memory unit, 170[1]: layer, 170[2]: layer, 170[m−1]: layer, 170[m]: layer, 180a: insulator, 180b: insulator, 180: insulator, 182: insulator, 185: insulator, 190p: opening portion, 190q: opening portion, 190r: opening portion, 190s: opening portion, 190: opening portion, 200a: transistor, 200b: transistor, 200c: transistor, 200d: transistor, 200p: transistor, 200q: transistor, 200r: transistor, 200s: transistor, 200: transistor, 230a: oxide semiconductor, 230b: oxide semiconductor, 230i: region, 230na: region, 230nb: region, 230: oxide semiconductor, 240A: conductive film, 240: conductor, 245: conductor, 246: conductor, 250a: insulator, 250b: insulator, 250c: insulator, 250: insulator, 260a: conductor, 260A: conductive film, 260b: conductor, 260: conductor, 265: conductor, 280a: insulator, 280b: insulator, 280c: insulator, 280: insulator, 281: insulator, 283: insulator, 287: insulator, 289: insulator, 290p: opening portion, 290q: opening portion, 290r: opening portion, 290s: opening portion, 290: opening portion, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 641: insulator, 642: conductor, 643: conductor, 644: conductor, 645: conductor, 646: conductor, 647: insulator, 648: insulator, 700: electronic component, 702: printed circuit board, 704: mounting board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage, 7004: storage area network

1. A memory device comprising:
a first memory cell, a second memory cell, a first insulator, and a second insulator over the first insulator,
wherein the first memory cell comprises a first capacitor and a first transistor over the first capacitor,
wherein the second memory cell comprises a second capacitor and a second transistor over the second capacitor,
wherein the first insulator comprises a first opening portion and a second opening portion,
wherein at least part of the first capacitor is placed in the first opening portion,
wherein at least part of the second capacitor is placed in the second opening portion,
wherein the second insulator comprises a third opening portion and a fourth opening portion,
wherein at least part of the first transistor is placed in the third opening portion,
wherein at least part of the second transistor is placed in the fourth opening portion,
wherein the first opening portion comprises a region overlapping with the third opening portion,
wherein the second opening portion comprises a region overlapping with the fourth opening portion,
wherein a distance between a center of the first opening portion and a center of the second opening portion is equal to a distance between a center of the third opening portion and a center of the fourth opening portion,
wherein a maximum width of the first opening portion is different from a maximum width of the third opening portion, and
wherein a maximum width of the second opening portion is different from a maximum width of the fourth opening portion.

2. The memory device according to claim 1,
wherein the maximum width of the first opening portion is larger than the maximum width of the third opening portion, and
wherein the maximum width of the second opening portion is larger than the maximum width of the fourth opening portion.

3. The memory device according to claim 1,
wherein a channel length of the first transistor is smaller than a channel width of the first transistor, and
wherein a channel length of the second transistor is smaller than a channel width of the second transistor.

4. The memory device according to claim 1,
wherein each of the first transistor and the second transistor comprises an oxide semiconductor in a semiconductor layer, and
wherein the oxide semiconductor comprises one or more selected from In, Ga, and Zn.

5. The memory device according to claim 1,
wherein each of the first capacitor and the second capacitor comprises a first conductor, a third insulator over the first conductor, and a second conductor over the third insulator, and
wherein the third insulator comprises a first zirconium oxide, an aluminum oxide over the first zirconium oxide, and a second zirconium oxide over the aluminum oxide.

6. The memory device according to claim 1, further comprising:
a plurality of layers each comprising the first memory cell and the second memory cell, and
wherein the plurality of layers are stacked.

7. A memory device comprising:
a first conductor, a memory cell over the first conductor, a first insulator over the first conductor, and a second insulator,
wherein the memory cell comprises a capacitor and a transistor over the capacitor,
wherein the capacitor comprises a second conductor, a third insulator over the second conductor, and a third conductor over the third insulator,
wherein a first opening portion reaching the first conductor is placed in the first insulator,
wherein at least part of the second conductor, at least part of the third insulator, and at least part of the third conductor are placed in the first opening portion,
wherein the second insulator is placed over the second conductor, the third insulator, and the third conductor,
wherein the transistor comprises the third conductor, a fourth conductor over the second insulator, an oxide semiconductor, a fourth insulator, and a fifth conductor,
wherein a second opening portion reaching the third conductor is placed in the second insulator and the fourth conductor,
wherein at least part of the oxide semiconductor is placed in the second opening portion,
wherein the oxide semiconductor comprises a region in contact with a top surface of the third conductor in the second opening portion, a region in contact with a side surface of the fourth conductor in the second opening portion, and a region in contact with at least part of a top surface of the fourth conductor,
wherein the fourth insulator is placed over the oxide semiconductor,
wherein at least part of the fourth insulator is placed in the second opening portion,
wherein the fifth conductor is placed over the fourth insulator,
wherein at least part of the fifth conductor is placed in the second opening portion, and
wherein a maximum width of the first opening portion is different from a maximum width of the second opening portion.

8. The memory device according to claim 7,
wherein the maximum width of the first opening portion is larger than the maximum width of the second opening portion.

9. The memory device according to claim 7,
wherein the second opening portion comprises a region overlapping with the first opening portion.

10. The memory device according to claim 7,
wherein a channel length of the transistor is smaller than a channel width of the transistor.

11. The memory device according to claim 7,
wherein the third insulator comprises a first zirconium oxide, an aluminum oxide over the first zirconium oxide, and a second zirconium oxide over the aluminum oxide.

12. The memory device according to claim 7,
wherein the oxide semiconductor comprises one or more selected from In, Ga, and Zn.

13. The memory device according to claim 7,
wherein the fifth conductor extends in a first direction,
wherein the fourth conductor extends in a second direction, and
wherein the first direction and the second direction are orthogonal to each other.

14. The memory device according to claim 13, further comprising:
a plurality of layers each comprising the memory cell, and
wherein the plurality of layers are stacked.
